(19) United States
(12) Patent Application Publication
(10) Pub. No.: US 2021/0148004 A1
(43) Pub. Date: May 20, 2021

(54) METHOD FOR FABRICATING EPITAXIAL HALIDE PEROVSKITE FILMS AND DEVICES

(71) Applicant: BOARD OF TRUSTEES OF MICHIGAN STATE UNIVERSITY, East Lansing, MI (US)

(72) Inventors: Richard R. LUNT, III, Williamston, MI (US); Lili WANG, Beijing (US); Pei CHEN, Lansing, MI (US)

(73) Assignee: BOARD OF TRUSTEES OF MICHIGAN STATE UNIVERSITY, East Lansing, MI (US)

(21) Appl. No.: 16/622,763

(22) PCT Filed: Jun. 13, 2018
(86) PCT No.: PCT/US2018/037220

§ 371 Date: Dec. 13, 2019

Related U.S. Application Data
(60) Provisional application No. 62/518,808, filed on Jun. 13, 2017.

(51) Int. Cl. C30B 25/16; C23C 14/06; C23C 16/30; C30B 25/18; H01L 21/02; C30B 29/12; C30B 29/54

(52) U.S. Cl. CPC C30B 25/165; C23C 14/0694; C23C 16/30; C30B 25/183; B82Y 20/00; H01L 21/02194; C30B 29/12; C30B 29/54; H01L 21/02186

(57) ABSTRACT

A method of fabricating a semiconductor structure is provided. The method includes evaporating at least one precursor and depositing an epitaxial film containing a halide perovskite derived from the at least one precursor on a single crystal substrate. Semiconductor structures made by the method are also provided.

### CROSS-REFERENCE TO RELATED APPLICATIONS

This application claims the benefit of U.S. Provisional Application No. 62/518,808, filed on Jun. 13, 2017. The entire disclosure of the above application is incorporated herein by reference.

### GOVERNMENT RIGHTS

This invention was made with government support under DE-SC0010472 awarded by the U.S. Department of Energy. The government has certain rights in the invention.

### FIELD

The present disclosure relates to methods of fabricating epitaxial films and quantum wells of halide perovskites and their use in optoelectronic devices. Halide perovskite epitaxy is enabled by vapor deposition onto single crystals.

### BACKGROUND

This section provides background information related to the present disclosure which is not necessarily prior art.

Hybrid halide perovskites are a new class of semiconductors for solar harvesting, light emission, lasing, quantum dots, water splitting, and thin film electronics. Although efficiencies of solar cells based on hybrid organic-inorganic lead halide perovskites have exceeded 22%, the toxicity of lead devices and lead manufacturing combined with the instability of organic components are two key barriers to its widespread application. Tin-based inorganic halide perovskites, such as CsSnX₃ (X=Cl, Br, and I), have been considered promising substitutes for their lead analogues because Sn is over 100 times less toxic than Pb and Cs has similar toxicity to Na or K. However, current research on photovoltaic and electronic applications of CsSnBr₃ and CsSnI₃ has, to date, been less encouraging, with solar cell efficiencies of less than 5% likely limited in large part by the low degree of crystalline ordering. Indeed, the degree of ordering has been linked to a) carrier transport, where mobilities increase from amorphous-Si (1 cm²/V-s) to single crystalline Si (1,400 cm²/V-s), b) recombination rates, where unpassivated grain boundaries act as quenching sites for charge carriers and excited states, and c) quantum confinement, which can make even Si a good near infrared (NIR) emitter with luminescent efficiency of greater than 50%. Thus, one of the main challenges for enhancing the properties of all-inorganic perovskites for opto-electronic applications is to obtain highly crystalline films with minimal defects that can also be integrated into heteroepitaxial structures. In regard to oxide perovskites, numerous phases can be derived from a perovskite structure with even minor changes in elemental compositions. For example, by removing one-sixth of the oxygen atoms, phase transitions can occur from perovskite to brownmillerite structures. Therefore, it is key to gain precise control over the crystal phase, crystalline order, orientation, and quantum confinement for the optimization of halide perovskite based optoelectronics.

While there has been significant research into the epitaxial growth of oxide perovskites, epitaxy has yet to be accomplished for halide perovksites. Such epitaxial growth has likely been hindered in large part due to alack of single crystalline substrates with suitable lattice constants and bonding interactions. Accordingly, a route to the epitaxial growth of halide perovskites that is enabled by lattice matching on a single crystal alkali halide salt substrates is desired. A platform demonstrating precise control in the fabrication of quantum well multilayer structures will guide new opportunities in emergent phenomena with halide perovskites.

### SUMMARY

This section provides a general summary of the disclosure, and is not a comprehensive disclosure of its full scope or all of its features.

The current technology provides a method of fabricating a semiconductor structure. The method includes evaporating at least one precursor, and depositing an epitaxial film including a halide perovskite derived from the at least one precursor on a single crystal substrate.

In one variation, the evaporating and the depositing are performed by vapor deposition selected from the group consisting of molecular beam epitaxy, atomic layer deposition (ALD), thermal evaporation, sputtering, pulsed laser deposition, electron beam evaporation, chemical vapor deposition cathodic arc deposition, and electrohydrodynamic deposition.

In one variation, the at least one precursor includes a first precursor corresponding to the formula AX, A′X, A′X₂, or a combination thereof, and a second precursor corresponding to the formula BX₂, B′X₄, CX₃, DX, or a combination thereof, and the method further includes reacting the first precursor with the second precursor to form the halide perovskite, the halide perovskite corresponding to the formula AₘBₙXₘ₊₂ₙ, A_{m′}B′_{n′}X_{m′+4n′}, A_{m″}B_{n″}B′_{n″*}X_{m″+2n″+4n″*}, AₘCₙXₘ₊₃ₙ, AₘCₙDₗXₘ₊₃ₙ₊ₗ, (A′X)ₘBₙXₘ₊₂ₙ, (A′X)ₘB′_{n′}X_{m′+4n′}, (A′X)_{m″}B_{n″}B″_{n″*}X_{m″+2n″+4n″*}, (A′X)ₘCₙXₘ₊₃ₙ, (A′X)ₘCₙDₗXₘ₊₃ₙ₊ₗ, or a combination thereof, wherein A is a 1+alkali metal, a 1+transition metal, a 1+lanthanide, a 1+actinide, a 1+organic cation, or a 1+compound having the formula A′X, wherein A′ is an alkaline earth metal, a 2+transition metal, a 2+lanthanide, a 2+actinide, or a combination thereof; A′ is an alkaline earth metal, a 2+transition metal, a 2+lanthanide, a 2+actinide, or a combination thereof; B is a 2+alkaline earth metal, a 2+transition metal, a 2+crystallogen, a 2+lanthanide, a 2+actinide, or a combination thereof; B′ is a 4+metal or a combination of 4+metals; C is a 3+pnictogen, a 3+icosagen, a 3+transition metal, or a combination thereof; D is silver (Ag), copper (Cu), gold (Au), indium (In I), thallium (Tl I), or a combination thereof; X is an inorganic anion, an organic anion, or a combination thereof; and m, m′, m″, n, n′, n″, n″*, and l are individually integers having a value of 0 or greater.

In one variation, A is cesium (Cs), rubidium (Rb), potassium (K), sodium (Na), lithium (Li), copper (Cu I), methylammonium (MA), formamidinium (FA), organic cation, or a combination thereof; A′ is beryllium (Be), magnesium (Mg), calcium (Ca), strontium (Sr), barium (Ba), iron (Fe II), chromium (Cr II), cobalt (Co II), nickel (Ni II), manganese (Mn II), lead (Pb II), copper (Cu II), vanadium (V II), zinc (Zn II) or a combination thereof; B is tin (Sn), lead (Pb), copper (Cu II), germanium (Ge), or a combination thereof; B′ is tin (Sn), germanium (Ge), lead (Pb), or a combination thereof; C is bismuth (Bi), antimony (Sb), indium (In II), iron (Fe), aluminum (Al) or a combination thereof; and X is an inorganic anion selected from the group consisting of a halogen, an oxalate, a hydroxide, a chlorate, an iodate, a nitrite, a sulfate, a thiosulfate, a phosphate, an antimonite, or a combination thereof, or an organic anion selected from the group consisting of acetate, formate, borate, carborane, phenyl borate, and combinations thereof, or a combination of inorganic anions and organic ions.

In one variation, the halide perovskite is CsSiCl₃, CsSiBr₃, CsSiI₃, RbSiCl₃, RbSiBr₃, KSiCl₃, KSiBr₃, KSiI₃, MASiCl₃, MASiBr₃, MASiI₃, Cs₂SiCl₄, Cs₂SiBr₄, Cs₂SiI₄, MA₂SiCl₄, MA₂SiBr₄, MA₂SiI₄, Rb₂SiCl₄, Rb₂SiBr₄, Rb₂SiI₄, CsSi₂Cl₅, Cs₂SiCl₆, Cs₂Si(II)Si(IV)Cl₈, CsSiI₂Br₅, Cs₂SiBr₆, Cs₂Si(II)Si(IV)Br₈, CsSi₂I₅, Cs₂SiI₆, Cs2Si(II)Si(IV)I₈, RbSi₂Cl₅, Rb₂SiCl₆, Rb₂Si(II)Si(IV)Cl₈, RbSi₂Br₅, Rb₂SiBr₆, Rb₂Si(II)Si(IV)Br₈, RbSi₂I₅, Rb₂SiI₆, Rb₂Si(II)Si(IV)I₈, KSi₂Cl₅, K₂SiCl₆, K₂Si(II)Si(IV)Cl₈, KSi₂Br₅, K₂SiBr₆, K₂Si(II)Si(IV)Br₈, KSi₂I₅, K₂SiI₆, K₂Si(II)Si(IV)I₈, MASi₂Cl₅, MA₂SiCl₆, MA₂Si(II)Si(IV)Cl₈, MASi₂Br₅, MA₂SiBr₆, MA₂Si(II)Si(IV)Br₈, MASi₂I₅, MA₂SiI₆, MA₂Si(II)Si(IV)I₈; CsGeCl₃, CsGeBr₃, CsGeI₃, RbGeCl₃, RbGeBr₃, KGeCl₃, KGeBr₃, KGeI₃, MAGeCl₃, MAGeBr₃, MAGeI₃, Cs₂GeCl₄, Cs₂GeBr₄, Cs₂GeI₄, MA₂GeCl₄, MA₂GeBr₄, MA₂GeI₄, Rb₂GeCl₄, Rb₂GeBr₄, Rb₂GeI₄, CsGe₂Cl₅, Cs₂GeCl₆, Cs₂Ge(II)Ge(IV)Cl₈, CsGe₂Br₅, Cs₂GeBr₆, Cs₂Ge(II)Ge(IV)Br₈, CsGe₂I₅, Cs₂GeI₆, Cs2Ge(II)Ge(IV)I₈, RbGe₂Cl₅, Rb₂GeCl₆, Rb₂Ge(II)Ge(IV)Cl₈, RbGe₂Br₅, Rb₂GeBr₆, Rb₂Ge(II)Ge(IV)Br₈, RbGe₂I₅, Rb₂GeI₆, Rb₂Ge(II)Ge(IV)I₈, KGe₂Cl₅, K₂GeCl₆, K₂Ge(II)Ge(IV)Cl₈, KGe₂Br₅, K₂GeBr₆, K₂Ge(II)Ge(IV)Br₈, KGe₂I₅, K₂GeI₆, K₂Ge(II)Ge(IV)I₈, MAGe₂Cl₅, MA₂GeCl₆, MA₂Ge(II)Ge(IV)Cl₈, MAGe₂Br₅, MA₂GeBr₆, MA₂Ge(II)Ge(IV)Br₈, MAGe₂I₅, MA₂GeI₆, MA₂Ge(II)Ge(IV)I₈; CsSnCl₃, CsSnBr₃, CsSnI₃, RbSnCl₃, RbSnBr₃, KSnCl₃, KSnBr₃, KSn₃, MASnCl₃, MASnBr₃, MASn₃, Cs₂SnCl₄, Cs₂SnBr₄, Cs₂SnI₄, MA₂SnCl₄, MA₂SnBr₄, MA₂SnI₄, Rb₂SnCl₄, Rb₂SnBr₄, Rb₂SnI₄, CsSn₂Cl₅, Cs₂SnCl₆, Cs₂Sn(II)Sn(IV)Cl₈, CsSn₂Br₅, Cs₂SnBr₆, Cs₂Sn(II)Sn(IV)Br₈, CsSn₂I₅, Cs₂SnI₆, Cs₂Sn(II)Sn(IV)I₈, RbSn₂Cl₅, Rb₂SnCl₆, Rb₂Sn(II)Sn(IV)Cl₈, RbSn₂Br₅, Rb₂SnBr₆, Rb₂Sn(II)Sn(IV)Br₈, RbSn₂I₅, Rb₂SnI₆, Rb₂Sn(II)Sn(IV)I₈, KSn₂Cl₅, K₂SnCl₆, K₂Sn(II)Sn(IV)Cl₈, KSn₂Br₅, K₂SnBr₆, K₂Sn(II)Sn(IV)Br₈, KSn₂I₅, K₂SnI₆, K₂Sn(II)Sn(IV)I₈, MASn₂Cl₅, MA₂SnCl₆, MA₂Sn(II)Sn(IV)Cl₈, MASn₂Br₅, MA₂SnBr₆, MA₂Sn(II)Sn(IV)Br₈, MASn₂I₅, MA₂SnI₆, MA₂Sn(II)Sn(IV)I₈, Cs₃Bi₂Cl₉, Cs₃Bi₂Br₉, Cs₃Bi₂I₉, Cs₃Sb₂Cl₉, Cs₃Sb₂Br₉, Cs₃Sb₂I₉; CsPbCl₃, CsPbBr₃, CsPbI₃, RbPbCl₃, RbPbBr₃, KPbCl₃, KPbBr₃, KPbI₃, MAPbCl₃, MAPbBr₃, MAPbI₃, Cs₂PbCl₄, Cs₂PbBr₄, Cs₂PbI₄, MA₂PbCl₄, MA₂PbBr₄, MA₂PbI₄, Rb₂PbCl₄, Rb₂PbBr₄, Rb₂PbI₄, CsPb₂Cl₅, Cs₂PbCl₆, Cs₂Pb(II)Pb(IV)Cl₈, CsPb₂Br₅, Cs₂PbBr₆, Cs₂Pb(II)Pb(IV)Br₈, CsPb₂I₅, Cs₂PbI₆, Cs₂Pb(II)Pb(IV)I₈, RbPb₂Cl₅, Rb₂PbCl₆, Rb₂Pb(II)Pb(IV)Cl₈, RbPb₂Br₅, Rb₂PbBr₆, Rb₂Pb(II)Pb(IV)Br₈, RbPb₂I₅, Rb₂PbI₆, Rb₂Pb(II)Pb(IV)I₈, KPb₂Cl₅, K₂PbCl₆, K₂Pb(II)Pb(IV)Cl₈, KPb₂Br₅, K₂PbBr₆, K₂Pb(II)Pb(IV)Br₈, KPb₂I₅, K₂PbI₆, K₂Pb(II)Pb(IV)I₈, MAPb₂Cl₅, MA₂PbCl₆, MA₂Pb(II)Pb(IV)Cl₈, MAPb₂Br₅, MA₂PbBr₆, MA₂Pb(II)Pb(IV)Br₈, MAPb₂I₅, MA₂PbI₆, MA₂Pb(II)Pb(IV)I₈; Cs₂AgBiCl₆, Cs₂CuBiCl₆, Cs₂InAgCl₆, Cs₂InCuCl₆, Cs₂AgSbCl₆, Cs₂CuSbCl₆, Cs₂AgBiBr₆, Cs₂CuBiBr₆, Cs₂InAgBr₆, Cs₂InCuBr₆, Cs₂AgBiI₆, Cs₂CuBiI₆, Cs₂AgSbBr₆, Cs₂CuSbBr₆, Cs₂AgSbI₆, Cs₂CuSbI₆, Cs₂InAgI₆, Cs₂InCuI₆, Cs₃Bi₂Cl₉, Cs₃Bi₂Br₉, Cs₃Bi₂I₉, Cs₃Sb₂Cl₉, Cs₃Sb₂Br₉, Cs₃Sb₂I₉, Cs₃In₂Cl₉, Cs₃In₂Br₉, Cs₃In₂I₉; K₂AgBiCl₆, K₂CuBiCl₆, K₂InAgCl₆, K₂InCuCl₆, K₂AgSbCl₆, K₂CuSbCl₆, K₂AgBiBr₆, K₂CuBiBr₆, K₂InAgBr₆, K₂InCuBr₆, K₂AgBiI₆, K₂CuBiI₆, K₂AgSbBr₆, K₂CuSbBr₆, K₂AgSbI₆, K₂CuSbI₆, K₂InAgI₆, K₂InCuI₆, K₃Bi₂Cl₉, K₃Bi₂Br₉, K₃Bi₂I₉, K₃Sb₂Cl₉, K₃Sb₂Br₉, K₃Sb₂I₉, K₃In₂Cl₉, K₃In₂Br₉, K₃In₂I₉; Na₂AgBiCl₆, Na₂CuBiCl₆, Na₂InAgCl₆, Na₂InCuCl₆, Na₂AgSbCl₆, Na₂CuSbCl₆, Na₂AgBiBr₆, Na₂CuBiBr₆, Na₂InAgBr₆, Na₂InCuBr₆, Na₂AgBiI₆, Na₂CuBiI₆, Na₂AgSbBr₆, Na₂CuSbBr₆, Na₂AgSbI₆, Na₂CuSbI₆, Na₂InAgI₆, Na₂InCuI₆, Na₃Bi₂Cl₉, Na₃Bi₂Br₉, Na₃Bi₂I₉, Na₃Sb₂Cl₉, Na₃Sb₂Br₉, Na₃Sb₂I₉, Na₃In₂Cl₉, Na₃In₂Br₉, Na₃In₂I₉; Li₂AgBiCl₆, Li₂CuBiCl₆, Li₂InAgCl₆, Li₂InCuCl₆, Li₂AgSbCl₆, Li₂CuSbCl₆, Li₂AgBiBr₆, Li₂CuBiBr₆, Li₂InAgBr₆, Li₂InCuBr₆, Li₂AgBiI₆, Li₂CuBiI₆, Li₂AgSbBr₆, Li₂CuSbBr₆, Li₂AgSbI₆, Li₂CuSbI₆, Li₂InAgI₆, Li₂InCuI₆, Li₃Bi₂Cl₉, Li₃Bi₂Br₉, Li₃Bi₂I₉, Li₃Sb₂Cl₉, Li₃Sb₂Br₉, Li₃Sb₂I₉, Li₃In₂Cl₉, Li₃In₂Br₉, Li₃In₂I₉, (BaF)₂PbCl₄, (BaF)₂PbBr₄, (BaF)₂PbI₄, (BaF)₂SnCl₄, (BaF)₂SnBr₄, (BaF)₂SnI₄, and (BaF)₂PbCl₆, (BaF)₂PbBr₆, (BaF)₂PbI₆, (BaF)₂SnCl₆, (BaF)₂SnBr₆, (BaF)₂SnI₆, or a combination thereof.

In one variation, the at least one precursor includes the halide perovskite, and the evaporating and depositing are performed by evaporating or sputtering of a target including the halide perovskite.

In one variation, there is a lattice misfit of less than or equal to about 10% between the single crystal substrate and the halide perovskite of the film.

In one variation, the at least one precursor includes a dopant.

In one variation, the single crystal substrate includes a halide salt, a halide perovskite, an oxide perovskite, a metal, or a semiconductor.

In one variation, the single crystal substrate includes ionic crystals.

In one variation, the single crystal substrate includes a halide salt selected from the group consisting of a metal halide salt, an alkali metal halide salt, an alkaline earth metal halide salt, a transition metal halide salt, and combinations thereof.

In one variation, the single crystal substrate includes a halide perovskite selected from the group consisting of CsSiCl₃, CsSiBr₃, CsSiI₃, RbSiCl₃, RbSiBr₃, KSiCl₃, KSiBr₃, KSiI₃, MASiCl₃, MASiBr₃, MASiI₃, Cs₂SiCl₄, Cs₂SiBr₄, Cs₂SiI₄, MA₂SiCl₄, MA₂SiBr₄, MA₂SiI₄, Rb₂SiCl₄, Rb₂SiBr₄, Rb₂SiI₄, CsSiI₂Cl₅, Cs₂SiCl₆, Cs₂Si(II)Si(IV)Cl₈, CsSiI₂Br₅, Cs₂SiBr₆, Cs₂Si(II)Si(IV)Br₈, CsSiI₂I₅, Cs₂SiI₆, Cs₂Si(II)Si(IV)I₈, RbSi₂Cl₅, Rb₂SiCl₆, Rb₂Si(II)Si(IV)Cl₈, RbSi₂Br₅, Rb₂SiBr₆, Rb₂Si(II)Si(IV)Br₈, RbSi₂I₅, Rb₂SiI₆, Rb₂Si(II)Si(IV)I₈, KSi₂Cl₅, K₂SiCl₆, K₂Si(II)Si(IV)Cl₈, KSi₂Br₅, K₂SiBr₆, K₂Si(II)Si(IV)Br₈, KSi₂I₅, K₂SiI₆, K₂Si(II)Si(IV)I₈, MASi₂Cl₅, MA₂SiCl₆, MA₂Si(II)Si(IV)Cl₈, MASi₂Br₅, MA₂SiBr₆, MA₂Si(II)Si(IV)Br₈, MASi₂I₅, MA₂SiI₆, MA₂Si(II)Si(IV)I₈; CsGeCl₃, CsGeBr₃, CsGeI₃, RbGeCl₃, RbGeBr₃, KGeCl₃, KGeBr₃, KGeI₃, MAGeCl₃, MAGeBr₃, MAGeI₃, Cs₂GeCl₄, Cs₂GeBr₄, Cs₂GeI₄, MA₂GeCl₄, MA₂GeBr₄, MA₂GeI₄, Rb₂GeCl₄, Rb₂GeBr₄, Rb₂GeI₄, CsGe₂Cl₅, Cs₂GeCl₆, Cs₂Ge(II)Ge(IV)Cl₈, CsGe₂Br₅, Cs₂GeBr₆, Cs₂Ge(II)Ge(IV)Br₈, CsGe₂I₅, Cs₂GeI₆, Cs₂Ge(II)Ge(IV)I₈, RbGe₂Cl₅, Rb₂GeCl₆, Rb₂Ge(II)Ge(IV)Cl₈, RbGe₂Br₅, Rb₂GeBr₆, Rb₂Ge(II)Ge(IV)Br₈, RbGe₂I₅, Rb₂GeI₆, Rb₂Ge(II)Ge(IV)I₈, KGe₂Cl₅, K₂GeCl₆, K₂Ge(II)Ge(IV)Cl₈, KGe₂Br₅, K₂GeBr₆, K₂Ge(II)Ge(IV)Br₈, KGe₂I₅, K₂GeI₆, K₂Ge(II)Ge(IV)I₈, MAGe₂Cl₅, MA₂GeCl₆, MA₂Ge(II)Ge(IV)Cl₈, MAGe₂Br₅, MA₂GeBr₆, MA₂Ge(II)Ge(IV)Br₈, MAGe₂I₅, MA₂GeI₆, MA₂Ge(II)Ge(IV)I₈; CsSnCl₃, CsSnBr₃, CsSnI₃, RbSnCl₃, RbSnBr₃, KSnCl₃, KSnBr₃, KSn₃, MASnCl₃, MASnBr₃, MASn₃, Cs₂SnCl₄, Cs₂SnBr₄, Cs₂SnI₄, MA₂SnCl₄, MA₂SnBr₄, MA₂SnI₄, Rb₂SnCl₄, Rb₂SnBr₄, Rb₂SnI₄, CsSn₂Cl₅, Cs₂SnCl₆, Cs₂Sn(II)Sn(IV)Cl₈, CsSn₂Br₅, Cs₂SnBr₆, Cs₂Sn(II)Sn(IV)Br₈, CsSn₂I₅, Cs₂SnI₆, Cs₂Sn(II)Sn(IV)I₈, RbSn₂Cl₅, Rb₂SnCl₆, Rb₂Sn(II)Sn(IV)Cl₈, RbSn₂Br₅, Rb₂SnBr₆, Rb₂Sn(II)Sn(IV)Br₈, RbSn₂I₅, Rb₂SnI₆, Rb₂Sn(II)Sn(IV)I₈, KSn₂Cl₅, K₂SnCl₆, K₂Sn(II)Sn(IV)Cl₈, KSn₂Br₅, K₂SnBr₆, K₂Sn(II)Sn(IV)Br₈, KSn₂I₅, K₂SnI₆, K₂Sn(II)Sn(IV)I₈, MASn₂Cl₅, MA₂SnCl₆, MA₂Sn(II)Sn(IV)Cl₈, MASn₂Br₅, MA₂SnBr₆, MA₂Sn(II)Sn(IV)Br₈, MASn₂I₅, MA₂SnI₆, MA₂Sn(II)Sn(IV)I₈, Cs₃Bi₂Cl₉, Cs₃Bi₂Br₉, Cs₃Bi₂I₉, Cs₃Sb₂Cl₉, Cs₃Sb₂Br₉, Cs₃Sb₂I₉; CsPbCl₃, CsPbBr₃, CsPbI₃, RbPbCl₃, RbPbBr₃, KPbCl₃, KPbBr₃, KPbI₃, MAPbCl₃, MAPbBr₃, MAPbI₃, Cs₂PbCl₄, Cs₂PbBr₄, Cs₂PbI₄, MA₂PbCl₄, MA₂PbBr₄, MA₂PbI₄, Rb₂PbCl₄, Rb₂PbBr₄, Rb₂PbI₄, CsPb₂Cl₅, Cs₂PbCl₆, Cs₂Pb(II)Pb(IV)Cl₈, CsPb₂Br₅, Cs₂PbBr₆, Cs₂Pb(II)Pb(IV)Br₈, CsPb₂I₅, Cs₂PbI₆, Cs₂Pb(II)Pb(IV)I₈, RbPb₂Cl₅, Rb₂PbCl₆, Rb₂Pb(II)Pb(IV)Cl₈, RbPb₂Br₅, Rb₂PbBr₆, Rb₂Pb(II)Pb(IV)Br₈, RbPb₂I₅, Rb₂PbI₆, Rb₂Pb(II)Pb(IV)I₈, KPb₂Cl₅, K₂PbCl₆, K₂Pb(II)Pb(IV)Cl₈, KPb₂Br₅, K₂PbBr₆, K₂Pb(II)Pb(IV)Br₈, KPb₂I₅, K₂PbI₆, K₂Pb(II)Pb(IV)I₈, MAPb₂Cl₅, MA₂PbCl₆, MA₂Pb(II)Pb(IV)Cl₈, MAPb₂Br₅, MA₂PbBr₆, MA₂Pb(II)Pb(IV)Br₈, MAPb₂I₅, MA₂PbI₆, MA₂Pb(II)Pb(IV)I₈; Cs₂AgBiCl₆, Cs₂CuBiCl₆, Cs₂InAgCl₆, Cs₂InCuCl₆, Cs₂AgSbCl₆, Cs₂CuSbCl₆, Cs₂AgBiBr₆, Cs₂CuBiBr₆, Cs₂InAgBr₆, Cs₂InCuBr₆, Cs₂AgBiI₆, Cs₂CuBiI₆, Cs₂AgSbBr₆, Cs₂CuSbBr₆, Cs₂AgSbI₆, Cs₂CuSbI₆, Cs₂InAgI₆, CS₂InCuI₆, Cs₃Bi₂Cl₉, Cs₃Bi₂Br₉, Cs₃Bi₂I₉, Cs₃Sb₂Cl₉, Cs₃Sb₂Br₉, Cs₃Sb₂I₉, Cs₃In₂Cl₉, Cs₃In₂Br₉, Cs₃In₂I₉; K₂AgBiCl₆, K₂CuBiCl₆, K₂InAgCl₆, K₂InCuCl₆, K₂AgSbCl₆, K₂CuSbCl₆, K₂AgBiBr₆, K₂CuBiBr₆, K₂InAgBr₆, K₂InCuBr₆, K₂AgBiI₆, K₂CuBiI₆, K₂AgSbBr₆, K₂CuSbBr₆, K₂AgSbI₆, K₂CuSbI₆, K₂InAgI₆, K₂InCuI₆, K₃Bi₂Cl₉, K₃Bi₂Br₉, K₃Bi₂I₉, K₃Sb₂Cl₉, K₃Sb₂Br₉, K₃Sb₂I₉, K₃In₂Cl₉, K₃In₂Br₉, K₃In₂I₉; Na₂AgBiCl₆, Na₂CuBiCl₆, Na₂InAgCl₆, Na₂InCuCl₆, Na₂AgSbCl₆, Na₂CuSbCl₆, Na₂AgBiBr₆, Na₂CuBiBr₆, Na₂InAgBr₆, Na₂InCuBr₆, Na₂AgBiI₆, Na₂CuBiI₆, Na₂AgSbBr₆, Na₂CuSbBr₆, Na₂AgSbI₆, Na₂CuSbI₆, Na₂InAgI₆, Na₂InCuI₆, Na₃Bi₂Cl₉, Na₃Bi₂Br₉, Na₃Bi₂I₉, Na₃Sb₂Cl₉, Na₃Sb₂Br₉, Na₃Sb₂I₉, Na₃In₂Cl₉, Na₃In₂Br₉, Na₃In₂I₉; Li₂AgBiCl₆, Li₂CuBiCl₆, Li₂InAgCl₆, Li₂InCuCl₆, Li₂AgSbCl₆, Li₂CuSbCl₆, Li₂AgBiBr₆, Li₂CuBiBr₆, Li₂InAgBr₆, Li₂InCuBr₆, Li₂AgBiI₆, Li₂CuBiI₆, Li₂AgSbBr₆, Li₂CuSbBr₆, Li₂AgSbI₆, Li₂CuSbI₆, Li₂InAgI₆, Li₂InCuI₆, Li₃Bi₂Cl₉, Li₃Bi₂Br₉, Li₃Bi₂I₉, Li₃Sb₂Cl₉, Li₃Sb₂Br₉, Li₃Sb₂I₉, Li₃In₂Cl₉, Li₃In₂Br₉, Li₃In₂I₉, and combinations thereof.

In one variation, the single crystal substrate includes an oxide perovskite selected from the group consisting of SrTiO₃, LiNbO₃, LiTaO₃, CaTiO₃, BaTiO₃, MgTiO₃, PbTiO₃, EuTiO₃, CdTiO₃, MnTiO₃, FeTiO₃, ZnTiO₃, CoTiO₃, NiTiO₃, BaSnO₃, PbSnO₃, SrSnO₃, CaSnO₃, CdSnO₃, MnSnO₃, ZnSnO₃, CoSnO₃, NiSnO₃, MgSnO₃, BeSnO₃, PbHfO₃, SrHfO₃, CaHfO₃, BaZrO₃, PbZrO₃, SrZrO₃, CaZrO₃, CdZrO₃, MgZrO₃, MnZrO₃, CoZrO₃, NiZrO₃, TiZrO₃, BeZrO₃, BaCeO₃, PbCeO₃, SrCeO₃, CaCeO₃, CdCeO₃, MgCeO₃, MnCeO₃, CoCeO₃, NiCeO₃, BeCeO₃, BaUO₃, SrUO₃, CaUO₃, MgUO₃, BeUO3, BaVO₃, SrVO₃, CaVO₃, MgVO₃, BeVO₃, BaThO₃, LaAlO₃, CeAlO₃, NdAlO₃, SmAlO₃, BiAlO₃, YAlO₃, InAlO₃, FeAlO₃, CrAlO₃, GaAlO₃, LaGaO₃, CeGaO₃, NdGaO₃, SmGaO₃, YGaO₃, LaCrO₃, CeCrO₃, NdCrO₃, SmCrO₃, YCrO₃, FeCrO₃, LaFeO₃, CeFeO₃, NdFeO₃, SmFeO₃, GdFeO₃, YFeO₃, InFeO₃, LaScO₃, CeScO₃, NdScO₃, YScO₃, InScO₃, LaInO₃, NdInO₃, YInO₃, LaYO₃, LaSmO₃, and combinations thereof.

In one variation, the single crystal substrate includes a metal selected from the group consisting of gold (Au), silver (Ag), copper (Cu), platinum (Pt), tin (Sn), aluminum (Al), gallium (Ga), indium (In), thallium (Tl), antimony (Sb), bismuth (Bi), titanium (Ti), molybdenum (Mo), niobium (Nb), nickel (Ni), chromium (Cr), magnesium (Mg), and combinations thereof.

In one variation, the single crystal substrate includes a semiconductor selected from the group consisting of silicon (Si), germanium (Ge), indium phosphide (InP), indium antiminide (InSb), indium arsenide (InAs), cadmium telluride (CdTe), cadmium sulfide (CdS), cadmium selenide (CdSe), gallium arsenide (GaAs), aluminum arsenide (AlAs), aluminum antimonide (AlSb), lead sulfide (PbS), lead selenide (PbSe), lead telluride (PbTe), zinc sulfide (ZnS), zinc oxide (ZnO), indium oxide (In₂O₃), titanium oxide (TiO₂), tin oxide (SnO₂), and combinations thereof.

In one variation, the method further includes disposing a buffer layer on the substrate prior to the depositing an halide perovskite on the substrate, wherein the buffer layer includes a halide salt alloy.

In one variation, the method further includes removing the film including a halide perovskite from the single crystal substrate by wet etching or epitaxial lift off.

In one variation, the method further includes transferring the film including a halide perovskite to a device.

The current technology also provides a method of fabricating a semiconductor structure. The method includes evaporating a first precursor corresponding to the formula AX, A′X, A′X₂ or a combination thereof; evaporating a second precursor corresponding to a formula BX₂, B′X₄, CX₃, DX, or a combination thereof; reacting the evaporated first precursor with the evaporated second precursor to form a halide perovskite corresponding to the formula AₘBₙXₘ₊₂ₙ, AₘB′_{n′}X_{m′+4n′}, A_{m″}B_{n″}B′_{n″*}X_{m″+2n″+4n″*}, AₘCₙXₘ₊₃ₙ, AₘCₙDₗXₘ₊₃ₙ₊ₗ, (A′X)ₘBₙXₘ₊₂ₙ, (A′X)ₘB′_{n′}X_{m′+4n′}, (A′X)_{m″}B_{n″}B′_{n″*}X_{m″+2n″+4n″*}, (A′X)ₘCₙXₘ₊₃ₙ, (A′X)ₘCₙDₗXₘ₊₃ₙ₊ₗ, or a combination thereof; and epitaxially growing a single domain film including the halide perovskite on a single crystal including a halide salt. A is a 1+alkali metal, a 1+transition metal, a 1+lanthanide, a 1+actinide, a 1+organic cation, or a 1+compound having he formula A′X, wherein A′ is an alkaline earth metal, a 2+transition metal, a 2+lanthanide, a 2+actinide, or a combination thereof; A′ is an alkaline earth metal, a 2+transition metal, a 2+lanthanide, a 2+actinide, or a combination thereof; B is a 2+alkaline earth metal, a 2+transition metal, a 2+crystallogen, a 2+lanthanide, a 2+actinide, or a combination thereof; B′ is a 4+metal or a combination of 4+metals; C is a 3+pnictogen, a 3+icosagen, a 3+transition metal, or a combination thereof; D is silver (Ag), copper (Cu), gold (Au), indium (In I), thallium (Tl I), or a combination thereof; X is an inorganic anion, an organic anion, or a combination thereof; and m, m′, m″, n, n′, n″, n″*, and l are individually integers having a value of 0 or greater.

In one variation, the method further includes disposing a first lattice matched layer on the film including the halide perovskite to generate a quantum well with a type I heterojunction, a type II heterojunction, or a type III heterojunction.

In one variation, the method further includes disposing at least one additional bilayer including a second film including a halide perovskite and a second lattice matched layer on the first lattice matched layer, such that a heterojunction is formed between the second film and the first lattice matched layer to generate a semiconductor structure including a at least one quantum well.

In one variation, the film including the halide perovskite has a thickness of a monolayer of the halide perovskite to less than or equal to about 3× the exciton Bohr radius of the halide perovskite.

In one variation, the current technology provides a semiconductor structure made according to the method.

Additionally, the current technology provides a semiconductor structure. The semiconductor structure includes a single crystal substrate, and a single-domain epitaxial film including a halide perovskite disposed on the single crystal substrate.

In one variation, the structure has a lattice misfit of less than about 10% between the single crystal substrate and the film including a halide perovskite.

In one variation, the structure has a lattice misfit of less than about 5% between the single crystal substrate and the film including a halide perovskite.

In one variation, the single crystal substrate is a halide salt, a halide perovskite, an oxide perovskite, a metal, or a semiconductor.

In one variation, the single crystal substrate is a halide salt selected from the group consisting of a metal halide salt, an alkali metal halide salt, an alkaline earth metal halide salt, a transition metal halide salt, and combinations thereof.

In one variation, the halide perovskite corresponds to the formula AₘBₙXₘ₊₂ₙ, A_{m′}B′_{n′}X_{m′+4n′}, A_{m″}B_{n″}B′_{n″*}X_{m″+2n″+4n″*}, AₘCₙXₘ₊₃ₙ, AₘCₙDₗXₘ₊₃ₙ₊ₗ, (A′X)ₘBₙXₘ₊₂ₙ, (A′X)ₘB′_{n′}X_{m′+4n′}, (A′X)_{m″}B_{n″}B′_{n″*}X_{m″+2n″+4n″*}, (A′X)ₘCₙXₘ₊₃ₙ, (A′X)ₘCₙDₗXₘ₊₃ₙ₊ₗ, or a combination thereof. A is a 1+alkali metal, a 1+transition metal, a 1+lanthanide, a 1+actinide, a 1+organic cation, or a 1+compound having the formula A′X, wherein A′ is an alkaline earth metal, a 2+transition metal, a 2+lanthanide, a 2+actinide, or a combination thereof; A′ is an alkaline earth metal, a 2+transition metal, a 2+lanthanide, a 2+actinide, or a combination thereof; B is a 2+alkaline earth metal, a 2+transition metal, a 2+crystallogen, a 2+lanthanide, a 2+actinide, or a combination thereof; B′ is a 4+metal or a combination of 4+metals; C is a 3+pnictogen, a 3+icosagen, a 3+transition metal, or a combination thereof; D is silver (Ag), copper (Cu), gold (Au), indium (In I), thallium (Tl I), or a combination thereof; X is an inorganic anion, an organic anion, or a combination thereof; and m, m′, m″, n, n′, n″, n″*, and l are individually integers having a value of 0 or greater.

In one variation, the single crystal substrate includes an epitaxial buffer layer and the film including a halide perovskite is disposed on the epitaxial buffer layer.

In one variation, the single crystal substrate comprises an epitaxial intermetallic layer and the film comprising a halide perovskite is disposed on the epitaxial intermetallic layer

In one variation, the film including a halide perovskite further includes a dopant.

In one variation, the semiconductor structure further includes a lattice matched layer disposed on the film including a halide perovskite, wherein the film including a halide perovskite is located between the substrate and the lattice matched layer to define a heterojunction or a quantum well.

In one variation, the semiconductor structure includes a plurality of quantum wells.

In one variation, the current technology provides a device including the semiconductor structure, wherein the device is a diode, a circuit, a sensor, a rectifier, a photocoupler, a photocatalyst, a catalyst, a photovoltaic cell, a photodetector, a photoconductor, alight emitting diode (LED), a laser, a memory, or a transistor.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1A is a schematic illustration of a first semiconductor structure according to various aspects of the current technology.

FIG. 1B is a schematic illustration of a second semiconductor structure according to various aspects of the current technology.

FIG. 1C is a schematic illustration of a third semiconductor structure according to various aspects of the current technology.

FIG. 1D is a schematic illustration of a fourth semiconductor structure according to various aspects of the current technology.

FIG. 2 is a flow chart showing a method of making a semiconductor device according to various aspects of the current technology.

FIG. 3 shows schematic crystal structures of cubic CsSnBr₃ as a monolayer (ML) and as a bilayer (BL; i.e., 1 unit cell). For cubic CsSnBr₃, the lattice constant is 5.8 Å; therefore, the ML and BL thicknesses are defined as a/2 (2.9 Å) and a (5.8 Å), respectively.

FIG. 4 shows RHEED patterns obtained during epitaxial growth of CsSnBr₃ according to various aspects of the current technology. Epitaxial CsSnBr₃ films are grown on single crystalline NaCl(100) substrates with various ratios of precursors, CsBr and SnBr₂ (as CsBr:SnBr₂), where two distinct phases (cubic and tetragonal) are observed. The uncertainty of film thickness is 1-1.5 MLs.

FIG. 5A shows a RHEED pattern of NaC along [110].

FIG. 5B shows a RHEED pattern of CsBr with a 22 Å thickness.

FIG. 5C shows a RHEED pattern of SnBr₂ with a 22 Å thickness.

FIG. 6A is a photograph showing an epitaxial CsSnBr₃ sample before application of transparent tape.

FIG. 6B is a photograph showing the epitaxial CsSnBr₃ sample after application of transparent tape to the film surface.

FIG. 6C is a photograph showing the epitaxial CsSnBr₃ sample after the transparent tape was removed from the film surface. The film can be peeled after submersion in liquid nitrogen.

FIG. 7A shows a series of RHEED patterns of a cubic phase film taken from different rotation angles, wherein rotation dependency of the RHEED patterns is shown.

FIG. 7B shows a series of RHEED patterns of a tetragonal phase film taken from different rotation angles, wherein rotation dependency of the RHEED patterns is shown.

FIG. 8A shows a graph of specular RHEED intensity recorded during CsSnBr₃ epitaxial growth at 1:1 stoichiometry on NaCl at 0.28 Å/s. The oscillation period is 5 s and corresponds to a thickness of a half monolayer.

FIG. 8B shows a graph of specular RHEED intensity recorded during CsSnBr₃ epitaxial growth at 1:1 stoichiometry on NaCl at 0.14 Å/s. The oscillation period is 10 s and corresponds to a thickness of a half monolayer.

FIG. 8C is a cross-section SEM image used for growth rate calibration.

FIG. 9A is a cross-section TEM image of an NaCl/CsSnBr₃ interface (about 25 nm). The area marked with a white frame is enlarged and shown in FIG. 9C.

FIG. 9B is the image shown in FIG. 9D with black arrows marking dislocations.

FIG. 9C is an enlarged cross-section TEM image (viewed along the [100] direction of NaCl) of a sample prepared at a 1:1 CsBr:SnBr₂ ratio with CsSnBr₃ film thickness of about 25 nm. The black arrow shows the boundary between epitaxy and NaCl. The original image is shown in FIG. 9A.

FIG. 9D is an enlarged image of the area marked by a white frame in FIG. 9C.

FIG. 9E is a cross-section SEM image showing a smooth surface of epitaxial film.

FIG. 10A is a RHEED pattern of the sample grown at the ratio of 0.25:1 (CsBr:SnBr₂) collected along the [110] direction of NaCl.

FIG. 10B is a simulated SAED pattern of CsSn₂Br₅ along the [210] direction. The calculated d-spacings of (002) and (210) are 7.63 Å and 3.79 Å, respectively, which are consistent with the values calculated from the RHEED pattern (7.58±0.12 Å and 3.77±0.05 Å).

FIG. 10C is a schematic illustration of a crystal structure of CsSn₂Br₅ viewed along the a-axis.

FIG. 10D is a schematic illustration of a crystal structure of CsSn₂Br₅ viewed along the c-axis, including a schematic illustration of different atoms.

FIG. 11 shows an in-situ real-time monitoring of a phase transition. A phase transition from the cubic to tetragonal phase occurs when the deposition ratio of CsBr to SnBr₂ is 0.5:1 after 1-2 monolayers. While the pattern for the tetragonal phase appears monoclinic, it is actually a rotated tetragonal phase as shown in FIGS. 7A-7B and the diffraction spots are therefore not along primary axes.

FIG. 12A shows RHEED oscillations monitored during a growth process. A RHEED pattern is shown with the monitored intensity area highlighted with a white circle.

FIG. 12B shows a RHEED intensity profile with time corresponding to the area monitored in FIG. 12A.

FIG. 13A is a crystal structure characterization of two epitaxial phases; XRD patterns of NaCl (blue) and samples grown at different ratios CsBr:SnBr₂:0.25:1 (black) and 1:1 (red).

FIG. 13B is a photograph of the film grown at CsBr:SnBr₂:0.25:1, wherein the film is substantially transparent.

FIG. 13C is a photograph of the film grown at CsBr:SnBr₂:1:1, wherein the film is substantially opaque.

FIG. 14A shows calculated XRD patterns for cubic CsSnBr₃.

FIG. 14B shows calculated XRD patterns for tetragonal CsSn₂Br₅.

FIG. 14C shows an XRD pattern of a sample grown at a CsBr:SnBr₂ precursor ratio of 0.5:1. The inset shows the appearance of the sample. Both phases (CsSnBr₃ and CsSn₂Br₅) occur when the sample is prepared at 0.5:1 ratio.

FIG. 14D shows an XRD pattern of a sample grown at a CsBr:SnBr₂ precursor ratio of 1.5:1. The inset shows the appearance of the sample.

FIG. 15A is a schematic of a top view of a cubic CsSnBr₃ epitaxial structure on NaCl.

FIG. 15B is a schematic of a side view of a cubic CsSnBr₃ epitaxial structure on NaCl.

FIG. 15C is a schematic of a top view of a tetragonal CsSn₂Br₅ epitaxial structure on NaCl.

FIG. 15D is a schematic of a side view of a tetragonal CsSn₂Br₅ epitaxial structure on NaCl.

FIG. 16 shows XPS spectra of samples grown at different precursor ratios. All the spectra were taken at the top surfaces of an epitaxial film. From the sensitivity factors and the peak area of binding energy of different elements (Cs, Sn, Br), an elemental ratio is obtained.

FIG. 17A shows an XPS spectrum of CsSn₂Br₅ after Ar⁺ ion sputtering, particularly the signal from the Cs element. Sn²⁺ is partially reduced by Ar⁺ during sputtering (1.5 mins), resulting in the Sn3d peak splitting; however, this does not change the molar ratios calculated by integrating the peak area of different elements divided with sensitivity factors.

FIG. 17B shows an XPS spectrum of CsSn₂Br₅ after Ar⁺ ion sputtering, particularly the signal from the Sn element. Sn²⁺ is partially reduced by Ar⁺ during sputtering (1.5 mins), resulting in the Sn3d peak splitting; however, this does not change the molar ratios calculated by integrating the peak area of different elements divided with sensitivity factors.

FIG. 17C shows an XPS spectrum of CsSn₂Br₅ after Ar⁺ ion sputtering, particularly the signal from Br element. Sn²⁺ is partially reduced by Ar⁺ during sputtering (1.5 mins), resulting in the Sn3d peak splitting; however, this does not change the molar ratios calculated by integrating the peak area of different elements divided with sensitivity factors.

FIG. 18A shows absorption spectra of CsSnBr₃ of varying well thicknesses. The spectra are converted from (1-Transmission) and shifted for clarity.

FIG. 18B shows absorption spectra of CsSn₂Br₅ and NaCl. The spectra are converted from (1-Transmission) and shifted for clarity.

FIG. 19A shows DFT band structure simulation. In particular, HSE06 band structure, density of states (DOS) and projected density of states (PDOS) of CsSnBr₃ along the path L-Gamma-ZIN-Gamma-M are shown.

FIG. 19B shows DFT band structure simulation. In particular, HSE06 band structure, density of states (DOS) and projected density of states (PDOS) of CsSn₂Br₅ along the path L-Gamma-ZIN-Gamma-M are shown.

FIG. 20 shows a calculated bandgap as a function of lattice parameter. The bandgap of CsSnBr₃ decreases substantially with a decrease of lattice parameter.

FIG. 21A shows a RHEED pattern of NaC along the [110] direction.

FIG. 21B shows a RHEED pattern of NaCl/CsSnBr₃ (about 40 nm).

FIG. 21C shows a RHEED pattern of NaCl/CsSnBr₃ (about 40 nm)/NaCl (1.5 nm).

FIG. 21D is a schematic illustration of a NaCl/CsSnBr₃ quantum well structure.

FIG. 21E shows PL spectra of quantum well samples with various well widths (5 nm, 10 nm, 20 nm, 40 nm, 80 nm, and 100 nm).

FIG. 21F shows emission energy of quantum wells with varying well width. The inset shows photographs of samples illuminated under UV light. Samples from left to right are bare NaC single crystal, quantum well of NaCl/CsSnBr₃ (40 nm), and quantum well of NaCl/CsSnBr₃ (about 100 nm).

FIG. 22A is a DFT calculation using the PBE functional showing band structure, density of states (DOS), and projected density of states (PDOS) of CsSnBr₃.

FIG. 22B is a DFT calculation using the PBE functional showing band structure, density of states (DOS), and projected density of states (PDOS) of CsSn₂Br₅.

FIG. 23A is an I-V curve of an epitaxial film with different dopant concentrations.

FIG. 23B is an illustration of a structure scheme of devices used for I-V measurements.

FIG. 24A is a RHEED pattern of a single crystalline KCl(100) substrate.

FIG. 24B is a RHEED pattern of a monolayer (ML) of epitaxial grown CsSnI₃ on the single crystalline KCl(100) substrate.

FIG. 24C is a RHEED pattern of an about 20 nm layer of epitaxial grown CsSnI₃ on the single crystalline KCl(100) substrate. The uncertainty of film thickness is 1-1.5 MLs.

FIG. 24D is a RHEED pattern of an about 30 nm layer of epitaxial grown CsSnI₃ on the single crystalline KCl(100) substrate. The uncertainty of film thickness is 1-1.5 MLs.

FIG. 25A is an XRD pattern of a CsSnI₃ sample grown on a KCl substrate.

FIG. 25B is the XRD pattern of FIG. 8A enlarged at the range of 13°-16°.

FIG. 26A is an enlarged cross-section TEM image of a CsSnI₃—KCl interface (viewed along the [100] direction of KCl), wherein epitaxy is shown at the top half of the image to be distinguished from the substrate shown at the bottom half of the image.

FIG. 26B is an SAED of the epitaxy film shown in FIG. 9A.

FIG. 27A is an XPS spectrum of CsSnI₃, Cs.

FIG. 27B is an XPS spectrum of CsSnI₃, Sn.

FIG. 27C is an XPS spectrum of CsSnI₃, I.

FIG. 28A is a UV-Vis spectrum of CsSnI₃.

FIG. 28B is a PL spectrum of CsSnI₃ quantum well samples with various well widths.

FIG. 28C shows PL spectra of quantum well samples CsSnBr₃/CsSn₂Br₅ with various well widths and comparative quantum well samples CsSnBr₃/NaCl.

FIG. 29A is a RHEED pattern of freshly cleaved KCl along [002] direction.

FIG. 29B is a RHEED pattern of KCl/CsSnI₃ (about 10 nm).

FIG. 29C is a RHEED pattern of KCl/CsSn₃ (about 10 nm)/KCl(1.5 nm)

FIG. 29D is a RHEED pattern of KCl/CsSn₃ (about 10 nm)/KCl(1.5 nm)/CsSnI₃ (about 10 nm)/KCl (1.5 nm). The patterns of FIGS. 28A-28D indicate that with well controlled growth, no obvious change occurs even after growing two pairs of CsSnI₃ (about 10 nm)/KCl(1.5 nm). Multi-junction quantum wells can be prepared in this manner.

FIG. 30A is a RHEED pattern of freshly cleaved NaC along [110] direction.

FIG. 30B is a RHEED pattern of NaCl/CsSnBr₃ (about 10 nm)/NaCl (1.5 nm).

FIG. 30C is a RHEED pattern of NaCl/CsSnBr₃ (about 10 nm)/NaCl (1.5 nm)/CsSnBr₃ (about 10 nm)/NaCl (1.5 nm).

FIG. 30D is a RHEED pattern of NaCl/CsSnBr₃ (about 10 nm)/NaCl (1.5 nm)/CsSnBr₃ (about 10 nm)/NaCl (1.5 nm)/CsSnBr₃ (about 10 nm)/NaCl (1.5 nm). The patterns of FIGS. 30A-30D indicate that with well controlled growth, no obvious change occurs even after growing three pairs of CsSnBr₃ (about 10 nm)/NaCl (1.5 nm). Multi-junction quantum wells can be prepared in this manner.

FIG. 31 shows RHEED patterns of CsSnBr₃ epitaxially grown on Ge without HCl treatment at room temperature.

FIG. 32 shows RHEED patterns of CsSnBr₃ epitaxially grown on Ge with HCl treatment at room temperature.

FIG. 33 shows RHEED patterns of InP and of CsSnBr₃ grown on InP.

FIG. 34 shows RHEED patterns of a polycrystalline film obtained at about 75° C. with CsBr:SnBr₂=0.5:1. A photograph of the film is also provided.

FIG. 35 shows RHEED patterns of a polycrystalline film obtained at about 75° C. with CsBr:SnBr₂=1:1. A photograph of the film is also provided.

FIG. 36 shows RHEED patterns of a highly ordered epitaxial film obtained at about 100° C. with CsBr:SnBr₂=0.5:1. A photograph of the film is also provided.

FIG. 37 shows RHEED patterns of a highly ordered epitaxial film obtained at about 100° C. with CsBr:SnBr₂=1:1. A photograph of the film is also provided.

FIG. 38 shows lattice constants of substrates and perovskite species and RHEED patterns of NaCl—NaBr alloy layer in different rotations.

FIG. 39 shows RHEED patterns of a NaC substrate, of a NaCl:NaBr 3:1 alloy, and of a NaCl:NaBr 1:1 alloy.

FIG. 40 is an XRD pattern for a NaCl—NaBr codeposition on a NaC substrate.

FIG. 41 shows RHEED patterns of CsSnBr₃ grown epitaxially on alloyed NaCl—NaBr.

FIG. 42A shows XRD patterns for a NaC substrate, alloyed NaCl—NaBr, and 20 nm, 40 nm, and 60 nm CsSnBr₃ grown epitaxially on alloyed NaClBr.

FIG. 42B is a blown up portion of the XRD patterns shown in FIG. 42A.

FIG. 43 shows controllable phase transition via stoichiometry of CsBr:SnBr₂ from NaCl substrate, cubic CsSnBr₃, tetragonal CsSn₂Br₅, cubic CsSnBr₃, and tetragonal CsSn₂Br₅. The inset at the right bottom shows the architecture of a sample.

FIG. 44A shows an XRD pattern of bare NaCl substrate before phase-controlled growth.

FIG. 44B shows an XRD pattern of a sample after phase-controlled growth as monitored by the RHEED shown in FIG. 43.

FIG. 45 shows photographs of a process of transferring a halide perovskite film form a substrate.

FIG. 46 shows J-V curves of an amorphous film and a single domain crystalline film measured via atomic force microscopy (AFM).

FIG. 47 shows a photocurrent of an amorphous film and a single domain crystalline film measured via atomic force microscopy (AFM).

Corresponding reference numerals indicate corresponding parts throughout the several views of the drawings.

### DETAILED DESCRIPTION

Example embodiments are provided so that this disclosure will be thorough, and will fully convey the scope to those who are skilled in the art. Numerous specific details are set forth such as examples of specific compositions, components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, elements, compositions, steps, integers, operations, and/or components, but do not preclude the presence or addition of one or more other features, integers, steps, operations, elements, components, and/or groups thereof. Although the open-ended term “comprising,” is to be understood as a non-restrictive term used to describe and claim various embodiments set forth herein, in certain aspects, the term may alternatively be understood to instead be a more limiting and restrictive term, such as “consisting of” or “consisting essentially of.” Thus, for any given embodiment reciting compositions, materials, components, elements, features, integers, operations, and/or process steps, the present disclosure also specifically includes embodiments consisting of, or consisting essentially of, such recited compositions, materials, components, elements, features, integers, operations, and/or process steps. In the case of “consisting of,” the alternative embodiment excludes any additional compositions, materials, components, elements, features, integers, operations, and/or process steps, while in the case of “consisting essentially of,” any additional compositions, materials, components, elements, features, integers, operations, and/or process steps that materially affect the basic and novel characteristics are excluded from such an embodiment, but any compositions, materials, components, elements, features, integers, operations, and/or process steps that do not materially affect the basic and novel characteristics can be included in the embodiment.

Any method steps, processes, and operations described herein are not to be construed as necessarily requiring their performance in the particular order discussed or illustrated, unless specifically identified as an order of performance. It is also to be understood that additional or alternative steps may be employed, unless otherwise indicated.

When a component, element, or layer is referred to as being “on,” “engaged to,” “connected to,” or “coupled to” another element or layer, it may be directly on, engaged, connected or coupled to the other component, element, or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various steps, elements, components, regions, layers and/or sections, these steps, elements, components, regions, layers and/or sections should not be limited by these terms, unless otherwise indicated. These terms may be only used to distinguish one step, element, component, region, layer or section from another step, element, component, region, layer or section. Terms such as “first,” “second,” and other numerical terms when used herein do not imply a sequence or order unless clearly indicated by the context. Thus, a first step, element, component, region, layer or section discussed below could be termed a second step, element, component, region, layer or section without departing from the teachings of the example embodiments.

Spatially or temporally relative terms, such as “before,” “after,” “inner,” “outer,” “beneath,” “below,” “lower,” “above,” “upper,” and the like, may be used herein for ease of description to describe one element or feature's relationship to another element(s) or feature(s) as illustrated in the figures. Spatially or temporally relative terms may be intended to encompass different orientations of the device or system in use or operation in addition to the orientation depicted in the figures.

Throughout this disclosure, the numerical values represent approximate measures or limits to ranges to encompass minor deviations from the given values and embodiments having about the value mentioned as well as those having exactly the value mentioned. Other than in the working examples provided at the end of the detailed description, all numerical values of parameters (e.g., of quantities or conditions) in this specification, including the appended claims, are to be understood as being modified in all instances by the term “about” whether or not “about” actually appears before the numerical value. “About” indicates that the stated numerical value allows some slight imprecision (with some approach to exactness in the value; approximately or reasonably close to the value; nearly). If the imprecision provided by “about” is not otherwise understood in the art with this ordinary meaning, then “about” as used herein indicates at least variations that may arise from ordinary methods of measuring and using such parameters. For example, “about” may comprise a variation of less than or equal to 5%, optionally less than or equal to 4%, optionally less than or equal to 3%, optionally less than or equal to 2%, optionally less than or equal to 1%, optionally less than or equal to 0.5%, and in certain aspects, optionally less than or equal to 0.1%.

In addition, disclosure of ranges includes disclosure of all values and further divided ranges within the entire range, including endpoints and sub-ranges given for the ranges. As referred to herein, ranges are, unless specified otherwise, inclusive of endpoints and include disclosure of all distinct values and further divided ranges within the entire range. Thus, for example, a range of “from A to B” or “from about A to about B” is inclusive of A and B.

Example embodiments will now be described more fully with reference to the accompanying drawings.

The current technology provides methods of fabricating epitaxial films and quantum wells of halide perovskites. Epitaxy of halide perovskites is performed by vapor deposition onto single crystal substrates. Different phases of halide perovskite can be controlled by adjusting stoichiometry, which provides the ability to fabricate multilayer quantum wells of a perovskite/metal-halide system with tunable quantum confinement. Structures and devices made from the methods are also provided.

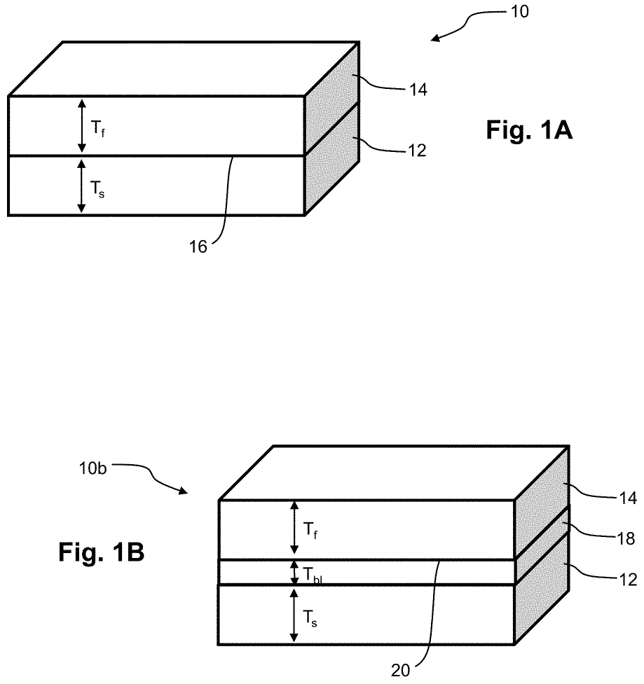

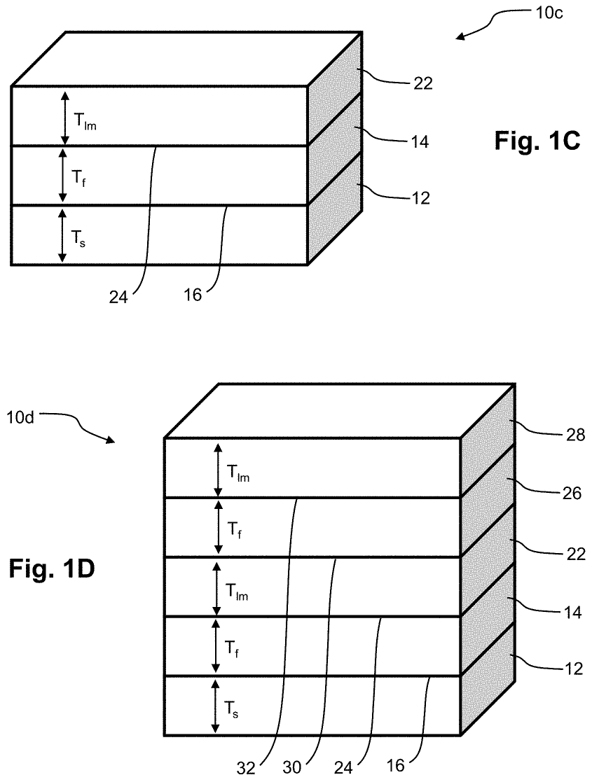

With reference to FIG. 1A, the current technology provides a semiconductor structure 10. The semiconductor structure 10 comprises a single crystal substrate 12 (or a single domain crystal substrate) and a single-domain epitaxial film 14 comprising a halide perovskite disposed on the single crystal substrate 12. As used herein, a “single-domain epitaxial film” refers to an epitaxial film or overlayer that has one well-defined orientation with respect to the substrate crystal structure. A “well-defined orientation” means that there is one orientation perpendicular to a surface of the single crystal substrate 12 and no more than two orientations in-plane to the surface of the single crystal substrate 12. In various embodiments, there is only one out-of-plane orientation and only one in-plane orientation. The film 14 can be disposed directly on the single crystal substrate 12, or indirectly on the single crystal substrate 12 by way of a buffer layer as described below. Accordingly, in various aspects of the current technology, the semiconductor structure 10 is a multilayer stack including a heterojunction.

The single crystal substrate 12 comprises a halide salt, a halide perovskite, an oxide perovskite, a metal, or a semiconductor. The halide salt can be, for example, a metal halide salt, an alkali metal halide salt, an alkaline earth metal halide salt, a transition metal halide salt, or a combination thereof with congruent interaction. Metal halide salts include, as non-limiting examples, PbX₂, SnX₂, GeX₂, AlX₃, BX₃, GaX₃, BiX₃, InX₃, SiX₄, TiX₄, SbX₃, SbX₅, and combinations thereof, where X is a halide or a combination of halides, wherein halides are F⁻, Cl⁻, Br⁻, or I⁻. Alkali metal halide salts correspond to the formula MX, where M is Li, Na, K, Rb, or Cs and X is a halide or a combination of halides. Alkali metal halide salts include, as non-limiting examples, LiF, LiCl, LiBr, LiI, NaF, NaCl, NaBr, NaI, KF, KCl, KBr, KI, RbF, RbCl, RbBr, RbI, CsF, CsCl, CsBr, CsI, and combinations thereof. Alkaline earth metal halide salts have the formula M′X₂, where M′ is Be, Mg, Ca, or Sr and X is a halide. Alkaline earth metal halide salts include, as non-limiting examples, BeF₂, BeCl₂, BeBr₂, BeI₂, MgF₂, MgCl₂, MgBr₂, Mg₂, CaF₂, CaCl₂, CaBr₂, CaI₂, SrF₂, SrCl₂, SrBr₂, Sr₂, and combinations thereof. Transition metal halide salts have the formula MX, where M is Mn, Fe, Co, Ni, Cr, V, or Cu; n is 1, 2, 3, 4, or 5; and X is a halide. Transition metal halide salts include, as non-limiting examples, MnF₃, MnF₄, MnCl₂, MnCl₃, MnBr₂, MnI₂, FeF₂, FeF₃, FeCl₃, FeCl₂, FeBr₂, FeBr₃, FeI₂, FeI₃, CoF₂, CoF₃, CoF₄, CoCl₂, CoCl₃, CoBr₂, CoI₂, NiF₂, NiCl₂, NiI₂, CrF₂, CrF₃, CrF₄, CrF₅, CrF₆, CrCl₂, CrCl₃, CrCl₄, CrBr₂, CrBr₃, CrBr₄, CrI₂, CrI₃, CrI₄, VF₂, VF₃, VF₄, VF₅, VCl₂, VCl₃, VCl₄, VBr₂, VBr₃, VBr₄, VI₂, VI₃, VI₄, CuF, CuF₂, CuCl, CuCl₂, CuBr₂, CuI, and combinations thereof. The halide perovskite can be CsSiCl₃, CsSiBr₃, CsSiI₃, RbSiCl₃, RbSiBr₃, KSiCl₃, KSiBr₃, KSiI₃, MASiCl₃, MASiBr₃, MASiI₃, Cs₂SiCl₄, Cs₂SiBr₄, Cs₂SiI₄, MA₂SiCl₄, MA₂SiBr₄, MA₂SiI₄, Rb₂SiCl₄, Rb₂SiBr₄, Rb₂SiI₄, CsSiI₂Cl₅, Cs₂SiCl₆, Cs₂Si(II)Si(IV)Cl₈, CsSiI₂Br₅, Cs₂SiBr₆, Cs₂Si(II)Si(IV)Br₈, CsSiI₂I₅, Cs₂SiI₆, Cs₂Si(II)Si(IV)I₈, RbSi₂Cl₅, Rb₂SiCl₆, Rb₂Si(II)Si(IV)Cl₈, RbSi₂Br₅, Rb₂SiBr₆, Rb₂Si(II)Si(IV)Br₈, RbSi₂I₅, Rb₂SiI₆, Rb₂Si(II)Si(IV)I₈, KSi₂Cl₅, K₂SiCl₆, K₂Si(II)Si(IV)Cl₈, KSi₂Br₅, K₂SiBr₆, K₂Si(II)Si(IV)Br₈, KSi₂I₅, K₂SiI₆, K₂Si(II)Si(IV)I₈, MASi₂Cl₅, MA₂SiCl₆, MA₂Si(II)Si(IV)Cl₈, MASi₂Br₅, MA₂SiBr₆, MA₂Si(II)Si(IV)Br₈, MASi₂I₅, MA₂SiI₆, MA₂Si(II)Si(IV)I₈; CsGeCl₃, CsGeBr₃, CsGeI₃, RbGeCl₃, RbGeBr₃, KGeCl₃, KGeBr₃, KGeI₃, MAGeCl₃, MAGeBr₃, MAGeI₃, Cs₂GeCl₄, Cs₂GeBr₄, Cs₂GeI₄, MA₂GeCl₄, MA₂GeBr₄, MA₂GeI₄, Rb₂GeCl₄, Rb₂GeBr₄, Rb₂GeI₄, CsGe₂Cl₅, Cs₂GeCl₆, Cs₂Ge(II)Ge(IV)Cl₈, CsGe₂Br₅, Cs₂GeBr₆, Cs₂Ge(II)Ge(IV)Br₈, CsGe₂I₅, Cs₂GeI₆, Cs₂Ge(II)Ge(IV)I₈, RbGe₂Cl₅, Rb₂GeCl₆, Rb₂Ge(II)Ge(IV)Cl₈, RbGe₂Br₅, Rb₂GeBr₆, Rb₂Ge(II)Ge(IV)Br₈, RbGe₂I₅, Rb₂GeI₆, Rb₂Ge(II)Ge(IV)I₈, KGe₂Cl₅, K₂GeCl₆, K₂Ge(II)Ge(IV)Cl₈, KGe₂Br₅, K₂GeBr₆, K₂Ge(II)Ge(IV)Br₈, KGe₂I₅, K₂GeI₆, K₂Ge(II)Ge(IV)I₈, MAGe₂Cl₅, MA₂GeCl₆, MA₂Ge(II)Ge(IV)Cl₈, MAGe₂Br₅, MA₂GeBr₆, MA₂Ge(II)Ge(IV)Br₈, MAGe₂I₅, MA₂GeI₆, MA₂Ge(II)Ge(IV)I₈; CsSnCl₃, CsSnBr₃, CsSnI₃, RbSnCl₃, RbSnBr₃, KSnCl₃, KSnBr₃, KSnI₃, MASnCl₃, MASnBr₃, MASnI₃, Cs₂SnCl₄, Cs₂SnBr₄, Cs₂SnI₄, MA₂SnCl₄, MA₂SnBr₄, MA₂SnI₄, Rb₂SnCl₄, Rb₂SnBr₄, Rb₂SnI₄, CsSn₂Cl₅, Cs₂SnCl₆, Cs₂Sn(II)Sn(IV)Cl₈, CsSn₂Br₅, Cs₂SnBr₆, Cs₂Sn(II)Sn(IV)Br₈, CsSn₂I₅, Cs₂SnI₆, Cs₂Sn(II)Sn(IV)I₈, RbSn₂Cl₅, Rb₂SnCl₆, Rb₂Sn(II)Sn(IV)Cl₈, RbSn₂Br₅, Rb₂SnBr₆, Rb₂Sn(II)Sn(IV)Br₈, RbSn₂I₅, Rb₂SnI₆, Rb₂Sn(II)Sn(IV)I₈, KSn₂Cl₅, K₂SnCl₆, K₂Sn(II)Sn(IV)Cl₈, KSn₂Br₅, K₂SnBr₆, K₂Sn(II)Sn(IV)Br₈, KSn₂I₅, K₂SnI₆, K₂Sn(II)Sn(IV)I₈, MASn₂Cl₅, MA₂SnCl₆, MA₂Sn(II)Sn(IV)Cl₈, MASn₂Br₅, MA₂SnBr₆, MA₂Sn(II)Sn(IV)Br₈, MASn₂I₅, MA₂SnI₆, MA₂Sn(II)Sn(IV)I₈, Cs₃Bi₂Cl₉, Cs₃Bi₂Br₉, Cs₃Bi₂I₉, Cs₃Sb₂Cl₉, Cs₃Sb₂Br₉, Cs₃Sb₂I₉; CsPbCl₃, CsPbBr₃, CsPbI₃, RbPbCl₃, RbPbBr₃, KPbCl₃, KPbBr₃, KPbI₃, MAPbCl₃, MAPbBr₃, MAPbI₃, Cs₂PbCl₄, Cs₂PbBr₄, Cs₂PbI₄, MA₂PbCl₄, MA₂PbBr₄, MA₂PbI₄, Rb₂PbCl₄, Rb₂PbBr₄, Rb₂PbI₄, CsPb₂Cl₅, Cs₂PbCl₆, Cs₂Pb(II)Pb(IV)Cl₈, CsPb₂Br₅, Cs₂PbBr₆, Cs₂Pb(II)Pb(IV)Br₈, CsPb₂I₅, Cs₂PbI₆, Cs₂Pb(II)Pb(IV)I₈, RbPb₂Cl₅, Rb₂PbCl₆, Rb₂Pb(II)Pb(IV)Cl₈, RbPb₂Br₅, Rb₂PbBr₆, Rb₂Pb(II)Pb(IV)Br₈, RbPb₂I₅, Rb₂PbI₆, Rb₂Pb(II)Pb(IV)I₈, KPb₂Cl₅, K₂PbCl₆, K₂Pb(II)Pb(IV)Cl₈, KPb₂Br₅, K₂PbBr₆, K₂Pb(II)Pb(IV)Br₈, KPb₂I₅, K₂PbI₆, K₂Pb(II)Pb(IV)I₈, MAPb₂Cl₅, MA₂PbCl₆, MA₂Pb(II)Pb(IV)Cl₈, MAPb₂Br₅, MA₂PbBr₆, MA₂Pb(II)Pb(IV)Br₈, MAPb₂I₅, MA₂PbI₆, MA₂Pb(II)Pb(IV)I₈; Cs₂AgBiCl₆, Cs₂CuBiCl₆, Cs₂InAgCl₆, Cs₂InCuCl₆, Cs₂AgSbCl₆, Cs₂CuSbCl₆, Cs₂AgBiBr₆, Cs₂CuBiBr₆, Cs₂InAgBr₆, Cs₂InCuBr₆, Cs₂AgBiI₆, Cs₂CuBiI₆, Cs₂AgSbBr₆, Cs₂CuSbBr₆, Cs₂AgSbI₆, Cs₂CuSbI₆, Cs₂InAgI₆, CS₂InCuI₆, C₃Bi₂Cl₉, Cs₃Bi₂Br₉, C₃Bi₂I₉, Cs₃Sb₂Cl₉, Cs₃Sb₂Br₉, Cs₃Sb₂I₉, Cs₃In₂Cl₉, Cs₃In₂Br₉, Cs₃In₂I₉; K₂AgBiCl₆, K₂CuBiCl₆, K₂InAgCl₆, K₂InCuCl₆, K₂AgSbCl₆, K₂CuSbCl₆, K₂AgBiBr₆, K₂CuBiBr₆, K₂InAgBr₆, K₂InCuBr₆, K₂AgBiI₆, K₂CuBiI₆, K₂AgSbBr₆, K₂CuSbBr₆, K₂AgSbI₆, K₂CuSbI₆, K₂InAgI₆, K₂InCuI₆, K₃Bi₂Cl₉, K₃Bi₂Br₉, K₃Bi₂I₉, K₃Sb₂Cl₉, K₃Sb₂Br₉, K₃Sb₂I₉, K₃In₂Cl₉, K₃In₂Br₉, K₃In₂I₉; Na₂AgBiCl₆, Na₂CuBiCl₆, Na₂InAgCl₆, Na₂InCuCl₆, Na₂AgSbCl₆, Na₂CuSbCl₆, Na₂AgBiBr₆, Na₂CuBiBr₆, Na₂InAgBr₆, Na₂InCuBr₆, Na₂AgBiI₆, Na₂CuBiI₆, Na₂AgSbBr₆, Na₂CuSbBr₆, Na₂AgSbI₆, Na₂CuSbI₆, Na₂InAgI₆, Na₂InCuI₆, Na₃Bi₂Cl₉, Na₃Bi₂Br₉, Na₃Bi₂I₉, Na₃Sb₂Cl₉, Na₃Sb₂Br₉, Na₃Sb₂I₉, Na₃In₂Cl₉, Na₃In₂Br₉, Na₃In₂I₉; Li₂AgBiCl₆, Li₂CuBiCl₆, Li₂InAgCl₆, Li₂InCuCl₆, Li₂AgSbCl₆, Li₂CuSbCl₆, Li₂AgBiBr₆, Li₂CuBiBr₆, Li₂InAgBr₆, Li₂InCuBr₆, Li₂AgBiI₆, Li₂CuBiI₆, Li₂AgSbBr₆, Li₂CuSbBr₆, Li₂AgSbI₆, Li₂CuSbI₆, Li₂InAgI₆, Li₂InCuI₆, Li₃Bi₂Cl₉, Li₃Bi₂Br₉, Li₃Bi₂I₉, Li₃Sb₂Cl₉, Li₃Sb₂Br₉, Li₃Sb₂I₉, Li₃In₂Cl₉, Li₃In₂Br₉, Li₃In₂I₉, and combinations thereof. The oxide perovskite can be SrTiO₃, LiNbO₃, LiTaO₃, CaTiO₃, BaTiO₃, MgTiO₃, PbTiO₃, EuTiO₃, CdTiO₃, MnTiO₃, FeTiO₃, ZnTiO₃, CoTiO₃, NiTiO₃, BaSnO₃, PbSnO₃, SrSnO₃, CaSnO₃, CdSnO₃, MnSnO₃, ZnSnO₃, CoSnO₃, NiSnO₃, MgSnO₃, BeSnO₃, PbHfO₃, SrHfO₃, CaHfO₃, BaZrO₃, PbZrO₃, SrZrO₃, CaZrO₃, CdZrO₃, MgZrO₃, MnZrO₃, CoZrO₃, NiZrO₃, TiZrO₃, BeZrO₃, BaCeO₃, PbCeO₃, SrCeO₃, CaCeO₃, CdCeO₃, MgCeO₃, MnCeO₃, CoCeO₃, NiCeO₃, BeCeO₃, BaUO₃, SrUO₃, CaUO₃, MgUO₃, BeUO3, BaVO₃, SrVO₃, CaVO₃, MgVO₃, BeVO₃, BaThO₃, LaAlO₃, CeAlO₃, NdAlO₃, SmAlO₃, BiAlO₃, YAlO₃, InAlO₃, FeAlO₃, CrAlO₃, GaAlO₃, LaGaO₃, CeGaO₃, NdGaO₃, SmGaO₃, YGaO₃, LaCrO₃, CeCrO₃, NdCrO₃, SmCrO₃, YCrO₃, FeCrO₃, LaFeO₃, CeFeO₃, NdFeO₃, SmFeO₃, GdFeO₃, YFeO₃, InFeO₃, LaScO₃, CeScO₃, NdScO₃, YScO₃, InScO₃, LaInO₃, NdInO₃, YInO₃, LaYO₃, LaSmO₃, and combinations thereof. The metal can be, as non-limiting examples, gold (Au), silver (Ag), copper (Cu), platinum (Pt), tin (Sn), aluminum (Al), gallium (Ga), indium (In), thallium (Tl), antimony (Sb), bismuth (Bi), titanium (Ti), molybdenum (Mo), niobium (Nb), nickel (Ni), chromium (Cr), magnesium (Mg), and combinations thereof. The semiconductor can be, as non-limiting examples, silicon (Si), germanium (Ge), indium phosphide (InP), indium antiminide (InSb), indium arsenide (InAs), cadmium telluride (CdTe), cadmium sulfide (CdS), cadmium selenide (CdSe), gallium arsenide (GaAs), aluminum arsenide (AlAs), aluminum antimonide (AlSb), lead sulfide (PbS), lead selenide (PbSe), lead telluride (PbTe), zinc sulfide (ZnS), zinc oxide (ZnO), indium oxide (In₂O₃), titanium oxide (TiO₂), tin oxide (SnO₂), and combinations thereof. In various embodiments, the single crystal substrate comprises ionic crystals, such that the single crystal substrate is a single ionic crystal substrate, where the halide salt, halide perovskite, oxide perovskite, metal, or semiconductor are in the form of ionic crystals.

The substrate 12 has a thickness Ts of greater than or equal to about 1 nm to less than or equal to about 1 m, of greater than or equal to about 100 nm to less than or equal to about 100 cm, or of greater than or equal to about 500 μm to less than or equal to about 10 mm.

The film 14 comprises a halide perovskite that corresponds to a formula AₘBₙXₘ₊₂ₙ, A_{m′}B′_{n′}X_{m′+4n′}, A_{m″}B_{n″}B′_{n″*}X_{m″+2n″+4n″*}, AₘCₙXₘ₊₃ₙ, AₘCₙDₗXₘ₊₃ₙ₊ₗ, (A′X)ₘBₙXₘ₊₂ₙ, (A′X)ₘB′_{n′}X_{m′+4n′}, (A′X)_{m″}B_{n″}B′_{n″*}X_{m″+2n″+4n″*}, (A′X)ₘCₙXₘ₊₃ₙ, (A′X)ₘCₙDₗXₘ₊₃ₙ₊ₗ, or a combination thereof, wherein A is a 1+alkali metal, a 1+transition metal, a 1+lanthanide, a 1+actinide, a 1+organic cation, or a 1+compound having he formula A′X, wherein A′ is an alkaline earth metal, a 2+transition metal, a 2+lanthanide, a 2+actinide, or a combination thereof; A′ is an alkaline earth metal, a 2+transition metal, a 2+lanthanide, a 2+actinide, or a combination thereof; B is a 2+alkaline earth metal, a 2+transition metal, a 2+crystallogen, a 2+lanthanide, a 2+actinide, or a combination thereof; C is a 3+pnictogen, a 3+icosagen, a 3+transition metal, or a combination thereof; D is silver (Ag), copper (Cu), gold (Au), indium (In I), thallium (Tl I), or a combination thereof; X is an inorganic anion, an organic anion, or a combination thereof; and m, m′, m″, n, n′, n″, n″*, and l are individually integers having a value of 0 or greater, such as a value of 0, 1, 2, 3, 4, 5, 6, 7, 8, or 9. In various embodiments, A is cesium (Cs), rubidium (Rb), potassium (K), sodium (Na), lithium (Li), copper (Cu I), methylammonium (MA), formamidinium (FA), organic cation, or a combination thereof; A′ is beryllium (Be), magnesium (Mg), calcium (Ca), strontium (Sr), barium (Ba), iron (Fe II), chromium (Cr II), cobalt (Co II), nickel (Ni II), manganese (Mn II), lead (Pb II), copper (Cu II), vanadium (V II), zinc (Zn II) or a combination thereof; B is tin (Sn), lead (Pb), copper (Cu II), germanium (Ge), or a combination thereof; B′ is tin (Sn), germanium (Ge), lead (Pb), or a combination thereof; C is bismuth (Bi), antimony (Sb), indium (In II), iron (Fe), aluminum (Al) or a combination thereof; and X is an inorganic anion selected from the group consisting of a halogen (e.g., F, Cl, Br, I, or a combination thereof), an oxalate, a hydroxide, a chlorate, an iodate, a nitrite, a sulfate, a thiosulfate, a phosphate, an antimonite, or a combination thereof, an organic anion selected from the group consisting of acetate, formate, borate, carborane, phenyl borate, and combinations thereof, or a combination of inorganic anions and organic ions. When X is not a halide, it is understood that halide components are then provided from another precursor such that the non-halide X is substantially eliminated from a film during a reaction and deposition.

Non-limiting examples of halide perovskites include CsSiCl₃, CsSiBr₃, CsSiI₃, RbSiCl₃, RbSiBr₃, KSiCl₃, KSiBr₃, KSi₃, MASiCl₃, MASiBr₃, MASiI₃, Cs₂SiCl₄, Cs₂SiBr₄, Cs₂SiI₄, MA₂SiCl₄, MA₂SiBr₄, MA₂SiI₄, Rb₂SiCl₄, Rb₂SiBr₄, Rb₂SiI₄, CsSiI₂Cl₅, Cs₂SiCl₆, Cs₂Si(II)Si(IV)Cl₈, CsSiI₂Br₅, Cs₂SiBr₆, Cs₂Si(II)Si(IV)Br₈, CsSiI₂I₅, Cs₂SiI₆, Cs₂Si(II)Si(IV)I₈, RbSi₂Cl₅, Rb₂SiCl₆, Rb₂Si(II)Si(IV)Cl₈, RbSi₂Br₅, Rb₂SiBr₆, Rb₂Si(II)Si(IV)Br₈, RbSi₂I₅, Rb₂SiI₆, Rb₂Si(II)Si(IV)I₈, KSi₂Cl₅, K₂SiCl₆, K₂Si(II)Si(IV)Cl₈, KSi₂Br₅, K₂SiBr₆, K₂Si(II)Si(IV)Br₈, KSi₂I₅, K₂SiI₆, K₂Si(II)Si(IV)I₈, MASi₂Cl₅, MA₂SiCl₆, MA₂Si(II)Si(IV)Cl₈, MASi₂Br₅, MA₂SiBr₆, MA₂Si(II)Si(IV)Br₈, MASi₂I₅, MA₂SiI₆, MA₂Si(II)Si(IV)I₈; CsGeCl₃, CsGeBr₃, CsGeI₃, RbGeCl₃, RbGeBr₃, KGeCl₃, KGeBr₃, KGeI₃, MAGeCl₃, MAGeBr₃, MAGeI₃, Cs₂GeCl₄, Cs₂GeBr₄, Cs₂GeI₄, MA₂GeCl₄, MA₂GeBr₄, MA₂GeI₄, Rb₂GeCl₄, Rb₂GeBr₄, Rb₂GeI₄, CsGe₂Cl₅, Cs₂GeCl₆, Cs₂Ge(II)Ge(IV)Cl₈, CsGe₂Br₅, Cs₂GeBr₆, Cs₂Ge(II)Ge(IV)Br₈, CsGe₂I₅, Cs₂GeI₆, Cs₂Ge(II)Ge(IV)I₈, RbGe₂Cl₅, Rb₂GeCl₆, Rb₂Ge(II)Ge(IV)Cl₈, RbGe₂Br₅, Rb₂GeBr₆, Rb₂Ge(II)Ge(IV)Br₈, RbGe₂I₅, Rb₂GeI₆, Rb₂Ge(II)Ge(IV)I₈, KGe₂Cl₅, K₂GeCl₆, K₂Ge(II)Ge(IV)Cl₈, KGe₂Br₅, K₂GeBr₆, K₂Ge(II)Ge(IV)Br₈, KGe₂I₅, K₂GeI₆, K₂Ge(II)Ge(IV)I₈, MAGe₂Cl₅, MA₂GeCl₆, MA₂Ge(II)Ge(IV)Cl₈, MAGe₂Br₅, MA₂GeBr₆, MA₂Ge(II)Ge(IV)Br₈, MAGe₂I₅, MA₂GeI₆, MA₂Ge(II)Ge(IV)I₈; CsSnCl₃, CsSnBr₃, CsSnI₃, RbSnCl₃, RbSnBr₃, KSnCl₃, KSnBr₃, KSn₃, MASnCl₃, MASnBr₃, MASn₃, Cs₂SnCl₄, Cs₂SnBr₄, Cs₂SnI₄, MA₂SnCl₄, MA₂SnBr₄, MA₂SnI₄, Rb₂SnCl₄, Rb₂SnBr₄, Rb₂SnI₄, CsSn₂Cl₅, Cs₂SnCl₆, Cs₂Sn(II)Sn(IV)Cl₈, CsSn₂Br₅, Cs₂SnBr₆, Cs₂Sn(II)Sn(IV)Br₈, CsSn₂I₅, Cs₂SnI₆, Cs₂Sn(II)Sn(IV)I₈, RbSn₂Cl₅, Rb₂SnCl₆, Rb₂Sn(II)Sn(IV)Cl₈, RbSn₂Br₅, Rb₂SnBr₆, Rb₂Sn(II)Sn(IV)Br₈, RbSn₂I₅, Rb₂SnI₆, Rb₂Sn(II)Sn(IV)I₈, KSn₂Cl₅, K₂SnCl₆, K₂Sn(II)Sn(IV)Cl₈, KSn₂Br₅, K₂SnBr₆, K₂Sn(II)Sn(IV)Br₈, KSn₂I₅, K₂SnI₆, K₂Sn(II)Sn(IV)I₈, MASn₂Cl₅, MA₂SnCl₆, MA₂Sn(II)Sn(IV)Cl₈, MASn₂Br₅, MA₂SnBr₆, MA₂Sn(II)Sn(IV)Br₈, MASn₂I₅, MA₂SnI₆, MA₂Sn(II)Sn(IV)I₈, Cs₃Bi₂Cl₉, Cs₃Bi₂Br₉, Cs₃Bi₂I₉, Cs₃Sb₂Cl₉, Cs₃Sb₂Br₉, Cs₃Sb₂I₉; CsPbCl₃, CsPbBr₃, CsPbI₃, RbPbCl₃, RbPbBr₃, KPbCl₃, KPbBr₃, KPbI₃, MAPbCl₃, MAPbBr₃, MAPbI₃, Cs₂PbCl₄, Cs₂PbBr₄, Cs₂PbI₄, MA₂PbCl₄, MA₂PbBr₄, MA₂PbI₄, Rb₂PbCl₄, Rb₂PbBr₄, Rb₂PbI₄, CsPb₂Cl₅, Cs₂PbCl₆, Cs₂Pb(II)Pb(IV)Cl₈, CsPb₂Br₅, Cs₂PbBr₆, Cs₂Pb(II)Pb(IV)Br₈, CsPb₂I₅, Cs₂PbI₆, Cs₂Pb(II)Pb(IV)I₈, RbPb₂Cl₅, Rb₂PbCl₆, Rb₂Pb(II)Pb(IV)Cl₈, RbPb₂Br₅, Rb₂PbBr₆, Rb₂Pb(II)Pb(IV)Br₈, RbPb₂I₅, Rb₂PbI₆, Rb₂Pb(II)Pb(IV)I₈, KPb₂Cl₅, K₂PbCl₆, K₂Pb(II)Pb(IV)Cl₈, KPb₂Br₅, K₂PbBr₆, K₂Pb(II)Pb(IV)Br₈, KPb₂I₅, K₂PbI₆, K₂Pb(II)Pb(IV)I₈, MAPb₂Cl₅, MA₂PbCl₆, MA₂Pb(II)Pb(IV)Cl₈, MAPb₂Br₅, MA₂PbBr₆, MA₂Pb(II)Pb(IV)Br₈, MAPb₂I₅, MA₂PbI₆, MA₂Pb(II)Pb(IV)I₈; Cs₂AgBiCl₆, Cs₂CuBiCl₆, Cs₂InAgCl₆, Cs₂InCuCl₆, Cs₂AgSbCl₆, Cs₂CuSbCl₆, Cs₂AgBiBr₆, Cs₂CuBiBr₆, Cs₂InAgBr₆, Cs₂InCuBr₆, Cs₂AgBiI₆, Cs₂CuBiI₆, Cs₂AgSbBr₆, Cs₂CuSbBr₆, Cs₂AgSbI₆, Cs₂CuSbI₆, Cs₂InAgI₆, CS₂InCuI₆, Cs₃Bi₂Cl₉, Cs₃Bi₂Br₉, Cs₃Bi₂I₉, Cs₃Sb₂Cl₉, Cs₃Sb₂Br₉, Cs₃Sb₂I₉, Cs₃In₂Cl₉, Cs₃In₂Br₉, Cs₃In₂I₉; K₂AgBiCl₆, K₂CuBiCl₆, K₂InAgCl₆, K₂InCuCl₆, K₂AgSbCl₆, K₂CuSbCl₆, K₂AgBiBr₆, K₂CuBiBr₆, K₂InAgBr₆, K₂InCuBr₆, K₂AgBiI₆, K₂CuBiI₆, K₂AgSbBr₆, K₂CuSbBr₆, K₂AgSbI₆, K₂CuSbI₆, K₂InAgI₆, K₂InCuI₆, K₃Bi₂Cl₉, K₃Bi₂Br₉, K₃Bi₂I₉, K₃Sb₂Cl₉, K₃Sb₂Br₉, K₃Sb₂I₉, K₃In₂Cl₉, K₃In₂Br₉, K₃In₂I₉; Na₂AgBiCl₆, Na₂CuBiCl₆, Na₂InAgCl₆, Na₂InCuCl₆, Na₂AgSbCl₆, Na₂CuSbCl₆, Na₂AgBiBr₆, Na₂CuBiBr₆, Na₂InAgBr₆, Na₂InCuBr₆, Na₂AgBiI₆, Na₂CuBiI₆, Na₂AgSbBr₆, Na₂CuSbBr₆, Na₂AgSbI₆, Na₂CuSbI₆, Na₂InAgI₆, Na₂InCuI₆, Na₃Bi₂Cl₉, Na₃Bi₂Br₉, Na₃Bi₂I₉, Na₃Sb₂Cl₉, Na₃Sb₂Br₉, Na₃Sb₂I₉, Na₃In₂Cl₉, Na₃In₂Br₉, Na₃In₂I₉; Li₂AgBiCl₆, Li₂CuBiCl₆, Li₂InAgCl₆, Li₂InCuCl₆, Li₂AgSbCl₆, Li₂CuSbCl₆, Li₂AgBiBr₆, Li₂CuBiBr₆, Li₂InAgBr₆, Li₂InCuBr₆, Li₂AgBiI₆, Li₂CuBiI₆, Li₂AgSbBr₆, Li₂CuSbBr₆, Li₂AgSbI₆, Li₂CuSbI₆, Li₂InAg₆, Li₂InCu₆, Li₃Bi₂Cl₉, Li₃Bi₂Br₉, Li₃Bi₂I₉, Li₃Sb₂Cl₉, Li₃Sb₂Br₉, Li₃Sb₂I₉, Li₃In₂Cl₉, Li₃In₂Br₉, Li₃In₂I₉, (BaF)₂PbCl₄, (BaF)₂PbBr₄, (BaF)₂PbI₄, (BaF)₂SnCl₄, (BaF)₂SnBr₄, (BaF)₂SnI₄, and (BaF)₂PbCl₆, (BaF)₂PbBr₆, (BaF)₂PbI₆, (BaF)₂SnCl₆, (BaF)₂SnBr₆, (BaF)₂SnI₆, and combinations thereof.

In various embodiments, the film 14 comprising a halide perovskite further comprises a dopant. The dopant can be, for example, a p-type dopant or an n-type dopant. Non-limiting examples of dopants include BF₃, BCl₃, BBr₃, BI₃, B₂S₃, AlF₃, AlCl₃, AlBr₃, AlI₃, Al₂S₃, GaF₃, GaCl₃, GaBr₃, GaI₃, Ga₂S₃, MnF₃, MnF₄, MnCl₂, MnCl₃, MnBr₂, MnI₂, FeF₂, FeF₃, FeCl₃, FeCl₂, FeBr₂, FeBr₃, FeI₂, FeI₃, CoF₂, CoF₃, CoF₄, CoCl₂, CoCl₃, CoBr₂, CoI₂, NiF₂, NiCl₂, NiI₂, CrF₂, CrF₃, CrF₄, CrF₅, CrF₆, CrCl₂, CrCl₃, CrCl₄, CrBr₂, CrBr₃, CrBr₄, CrI₂, CrI₃, CrI₄, VF₂, VF₃, VF₄, VF₅, VCl₂, VCl₃, VCl₄, VBr₂, VBr₃, VBr₄, VI₂, VI₃, VI₄, CuF, CuF₂, CuCl, CuCl₂, CuBr₂, CuI, BaF₂, BaCl₂, BaBr₂, Ba₂, BiF₃, BiCl₃, BiBr₃, BiI₃, SnF₄, SnCl₄, SnBr₄, SnI₄, SiF₄, SiCl₄, SiBr₄, SiI₄, SnO, SnS, SnSe, SnTe, GeO, GeS, GeSe, GeTe, PbO, PbS, PbSe, PbTe. The dopant has a concentration in the film 14 of greater than or equal to about 0.00001% (weight) to 10% (weight), of greater than or equal to about 0.001% (weight) to 15% (weight), or of greater than or equal to about 0.1% (weight) to 1% (weight).

The film 14 comprising a halide perovskite has a thickness TI equal to a monolayer (ML) of the halide perovskite to less than or equal to about 3× the exciton Bohr radius. As used herein, a “monolayer” is one half of a particular halide perovskite unit cell. In various embodiments, the halide perovskite has a thickness TI of greater than or equal to about 1 μm to less than or equal to about 100 nm, or greater than or equal to about 1 nm to less than or equal to about 50 nm.

An interface 16, i.e., a heterojunction, is formed between the single crystal substrate 12 and the film 14 comprising a halide perovskite. The single crystal substrate 12 has a first lattice constant and the film 14 comprising a halide perovskite has a second lattice constant. As used herein, a “lattice constant” refers to a distance between atoms in a crystal, which provides a measure of structural compatibility of between different crystals. Lattices in three dimensions generally have three lattice constants, referred to as a, b, and c. However, in cubic crystal structures, a=b=c, such that the lattice constant is simply referred to as a. Here, the first lattice constant is substantially the same as the second lattice constant. Put another way, the semiconductor structure 10 is lattice matched. As used herein, a “lattice matched” structure is a structure comprising a plurality of thin layers of different chemical composition, but featuring substantially the same lattice constant. As used herein, “substantially the same lattice constant” refers to an absolute mismatch or misfit between lattice constants of less than or equal to about 10% or less than or equal to about 5%. As used herein, a “lattice mismatch” or a “lattice misfit” refers to a structure comprising a first layer of a first chemical composition and a second layer of a second chemical composition, wherein the lattice constant of the first chemical composition is different from the lattice constant of the second chemical composition. Lattice mismatch/misfit may prevent growth of defect-free epitaxial films unless the thickness of the film is below a critical thickness, in which case the lattice mismatch is compensated by strain in the film. Having a low lattice mismatch/misfit, such as a lattice mismatch/misfit of less than about 10% or less than about 5% allows energy gap changes between adjacent layers, which maintain substantially the same crystallographic structure. As a hypothetical example, if a single crystal substrate is a cubic crystal structure with a_{sub}=3.75 Å and a film comprising a halide perovskite is a cubic crystal structure with a_{film}=4.00 Å, the lattice misfit between the single crystal substrate and the film is (1−(4/3.75))/100=−6.25%, which is equivalent to an absolute lattice mismatch or misfit of 6.25%. Therefore, the semiconductor structure 10 has an absolute lattice mismatch or misfit of less than about 10% or less than about 5% at the interface 16 between the single crystal substrate 12 and the film 14 comprising a halide perovskite.

In various embodiments, the single crystal substrate 12 includes a buffer layer that provides a better lattice match with the film 14 comprising a halide perovskite than with the substrate 12. FIG. 1B shows a semiconductor structure 10b comprising the substrate 12 and film 14 comprising a halide perovskite as defined in regard to FIG. 1A. However, in the semiconductor structure 10b the single crystal substrate 12 comprises a buffer layer 18 and the film 14 comprising a perovskite is disposed on the buffer layer 18. Therefore, the buffer layer 18 is located between the single crystal substrate 12 and the film 14 comprising a halide perovskite, such that an interface 20 is defined between the buffer layer 18 and the film 14 comprising a halide perovskite. Here, the semiconductor structure 10b has a lattice mismatch of less than about 3% or less than about 1% at the interface 20 between buffer layer 18 and the film 14 comprising a halide perovskite.

The buffer layer 18 has a thickness T_{bl} of greater than or equal to about 1 Å to less than or equal to about 10¹⁰ Å, of greater than or equal to about 10 to less than or equal to about 108 Å, or from greater than or equal to about 20 Å to less than or equal to about 105 Å.

The buffer layer 18 comprises a material that has a lattice misfit of less than 3% or less than 1% with the film 14 comprising a halide perovskite. Accordingly, the buffer layer 18 comprises a pseudomorphic material with a lattice constant tuned to the lattice constant of the halide perovskite in the film 14. As used herein, a “pseudomorphic material” refers to a layer of a single-crystal material disposed on a single-crystal substrate, wherein the single-crystal material and the single-crystal substrate having different chemical compositions, but the single-crystal material adopts the substrate lattice. An epitaxial material maintains a substantially exact matched lattice constant to the substrate so that there is an induced strain (compressive or tensile) in the epitaxial film, wherein “substantially exact” refers to a difference of less than or equal to about 5% or less than or equal to about 1%. Here, the buffer layer 18 can comprise a pseudomorphic material that provides a pseudomorphic epitaxial overlayer. The pseudomorphic material is a salt or a salt alloy, i.e., a salt doped with another salt to create a lattice constant gradient, a perovskite, or a perovskite alloy. In various embodiments, the single crystal substrate 12 and the buffer layer 18 comprise the same halide salt, but the buffer layer 18 further comprises a second component, such as, for example, a second halide salt or a halide salt alloy. Therefore, the buffer layer 18 can be an epitaxial buffer layer. In some embodiments, the buffer layer 18 is an intermetallic layer that provides a transition between different types of bonding (e.g., ionic to covalent) between the single crystal substrate 12 and the film 14 via metallic bonding in the intermetallic layer. The intermetallic layer is epitaxial or epitaxial and pseudomorphic. In some embodiments, the intermetallic layer comprises elements from the single crystal substrate 12 and the film 14. For example, Cs_{w}Si_{z} (and other alkali metal silicides) are useful intermetallic layers for growing ABXₑ halide perovskite on Si and A_{w}Ge_{z}, GeX₂ or GeX₄ (X=F, Cl, Br, I) and other alkali metal germanides are useful intermetallic layers for modifying Ge for growing ABXₑ halide perovskite, where w and z are integers between 1 and 4. Analogous intermetallics could be used for GaAs, GaN, GaP, AlP, AlAs, InSb, InP, CdTe, CdS, ZnO, SrTiO₃, LaTiO₃, Ag, Au, Mo crystal substrates for growing ABXₑ halide perovskite.

With reference to FIG. 1C, the current technology also provides a semiconductor structure 10c. The semiconductor structure 10c comprises the substrate 12 and film 14 comprising a halide perovskite as defined in regard to FIG. 1A. Although the film 14 comprising a halide perovskite is shown disposed on the substrate 12, it is understood that a buffer layer can be disposed between the substrate 12 and the film 14 comprising the halide perovskite as described in regard to FIG. 1B. However, the semiconductor structure 10c further comprises a lattice matched layer 22 disposed on the film 14 comprising a halide perovskite, wherein the film 14 comprising a halide perovskite is located between the substrate 12 and the lattice matched layer 22 to define a heterojunction or a quantum well. The lattice matched layer 22 and the film 14 comprising a halide perovskite define an interface 24. In various embodiments, there is a bandgap difference of at least about 0.2 eV, at least about 1 eV, or at least about 5 eV between the substrate 12 and the film 14 and between the lattice matched layer 22 and the film 14, which results in quantum confinement within the film 14.

The lattice matched layer 22 has a thickness Tₗₘ of greater than or equal to about 1 Å to less than or equal to about 10 Å and comprises a halide salt or halide salt alloy (as discussed above in regard to buffer layers), a semiconductor (such as the semiconductors described above in regard to the substrate 12), an insulator, a halide perovskite (including halide perovskites having different phases), Ge, InP, BaTiO₃, ZnSe, or CdS that has a lattice misfit of less than about 10% or less than about 5% with respect to the film 14 comprising a halide perovskite at the interface 24. In some embodiments, as shown in FIG. 1D, a semiconductor structure 10d further comprises at least one additional bilayer comprising a second film 26 comprising a halide perovskite and a second lattice matched layer 28 disposed on the lattice matched layer 22, such that a heterojunction is formed at an interface 30 between the second film 26 comprising a halide perovskite and the lattice matched layer 22, and at an interface 32 between the second film 26 comprising a halide perovskite and the second lattice matched layer 28 to generate a semiconductor structure comprising a quantum well or a plurality of quantum wells, i.e., at least one quantum well. The second film 26 may comprise the same or different halide perovskite as the film 14 and the second lattice matched layer 28 may comprise the same or different material as the lattice matched layer 22.

The current technology further provides a device comprising any of the semiconducting structures 10, 10b, 10c, 10d shown in FIGS. 1A-1D. The device can be, as non-limiting examples, a diode, a circuit, a sensor, a rectifier, a photocoupler, a photocatalyst, a catalyst, a photovoltaic cell, a photodetector, a photoconductor, a light emitting diode (LED), a laser, a memory, or a transistor. In some embodiments, the semiconducting structures 10, 10b, 10c, 10d do not include the substrate 12 when integrated into a device.

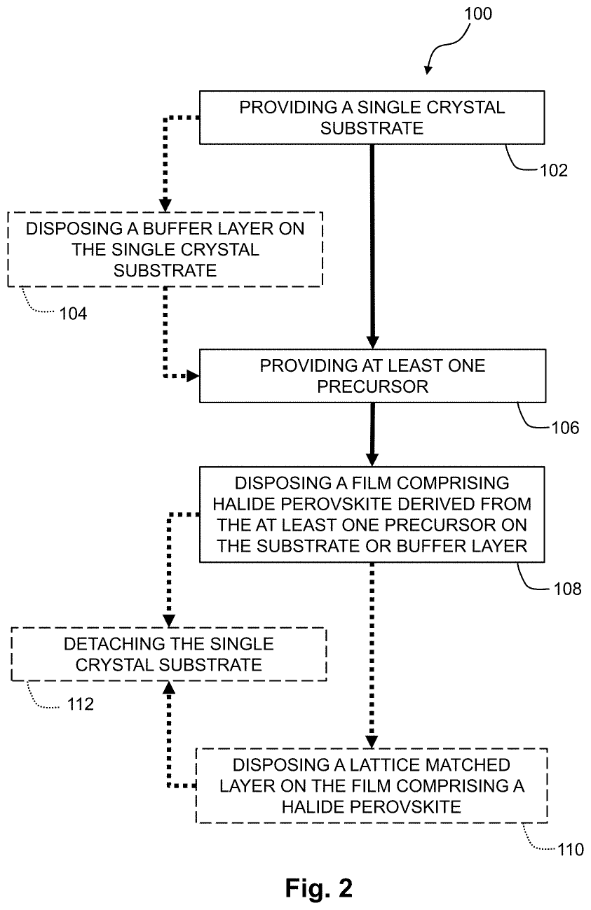

As shown in FIG. 2, the current technology also provides a method 100 for fabricating a semiconductor structure, such as the semiconductor structures 10, 10b, 10c, 10d described with reference to FIGS. 1A-1D.

In block 102, the method 100 comprises providing a single crystal substrate. The single crystal substrate can be any substrate described above. In some embodiments, the substrate has a polished surface on which a layer or film will be disposed. In other embodiments, the method 100 comprises cleaving the substrate from a larger substrate material to generate a fresh surface on which another layer or film will be disposed.

In various embodiments, the single crystal substrate has lattice constant that is substantially the same, i.e., has a lattice misfit of less than or equal to about 10% or less than or equal to about 5%, as the lattice constant of a halide perovskite that is to be disposed on the substrate. In other embodiments, the single crystal substrate has lattice constant that is not the same, i.e., has a lattice misfit of greater than or equal to about 5% or greater than or equal to about 10%, as the lattice constant of a halide perovskite that is to be disposed on the substrate. For example, many halide perovskites having the formula ABX₃ have lattice constants of greater than or equal to about 5.5 Å to less than or equal to about 6.5 Å. Therefore, in block 104 the method 100 optionally includes disposing a buffer layer on the single crystal substrate, wherein the buffer layer comprises a halide salt or a halide salt alloy, i.e., a halide salt doped with another salt to create a lattice constant gradient, a perovskite, or a perovskite alloy. The buffer layer can be uniform, i.e., be a uniform halide salt alloy, or the buffer layer can be graded, i.e., have a decreasing or increasing concentration of an alloying halide salt in the direction of from the substrate to the film comprising a halide perovskite. Providing a buffer layer allows for lattice-matched single crystalline substrates for pseudomorphic hetero-epitaxial growth of halide perovskite thin-films with well-controlled defect and dislocation densities. The lattice constants of single crystalline substrates can be tailored by combination of multiple isostructural sources having similar lattice constants for, as non-limiting examples, NaX (NaI, NaCl, NaBr).

Therefore, in various embodiments, the disposing a buffer layer on the single crystal substrate comprises lattice tuning the buffer layer. The lattice tuning can be performed by epitaxial growth of alloyed salt layers prepared by co-deposition of different salt sources. Lattice tuning is based on the principle of Vegard's rule:

a_{C}=xa_{A}+(1−x)a_{B},

where the alloyed lattice constant (a_{C}) is a linear function of the lattice constants from two constituent materials A and B. This approach prevents or minimizes unwanted dislocation formation, allows precise strain engineering (tensile and compressive), allows pseudomorphic heteroepitaxial growth with controlled levels of defect/dislocation density, and leads to flat surfaces for halide perovskite film epitaxy.

In block 106, the method 100 comprises providing at least one precursor. The at least one precursor is provided based on a predetermined halide perovskite to be disposed on the single crystal substrate (or buffer layer). For example, the halide perovskite ABX₃ can be generated reacting AX and BX₂, in which AX can be halide salt such as CsCl, CsBr, CsI or other organic halide precursors such as methylammonium halide (MAX), formamidinium halide (FAX); and BX₂ can be a halide salt such as SnCl₂, SnBr₂, SnI₂ or a non-halide inorganic salts such as Sn(NO₃)₂, or an organo-metallic precursors, such as tin acetate Sn(Ac)₂. Therefore, in various embodiments, the least one precursor comprises a first precursor corresponding to the formula AX, A′X, A′X₂, or a combination thereof, and a second precursor corresponding to the formula BX₂, B′X₄, CX₃, DX, or a combination thereof, wherein A, X, B, B′, and X are defined above. However, it is understood that there can be more than two precursors each being individually selected from the group consisting of AX, A′X, A′X₂, BX₂, B′X₄, CX₃, and DX. In other embodiments, the at least one precursor comprises the halide perovskite to be deposited onto the single crystal substrate. As non-limiting examples, the precursors CsBr and SnBr₂ (and optionally a dopant, e.g., BaBr₂) can react to form the halide perovskite CsSnBr₃, the precursors CsI and SnI₂ (and optionally a dopant, e.g., BaI₂) can react to form the halide perovskite CsSnI₃, the precursors CsBr, AgBr and BiBr₃ can react to form the halide perovskite Cs₂BiAgBr₆, the precursors CsI, AgI and BiI₃ can react to form the halide perovskite Cs₂BiAgI₆, the precursors CsBr, CuBr and BiBr₃ can react to form the halide perovskite Cs₂BiCuBr₆, the precursors CsI, CuI and BiI₃ can react to form the halide perovskite Cs₂BiCuI₆, the precursors CsBr, and BiBr₃ can react to form the halide perovskite Cs₃Bi₂Br₉, and the precursors CsI, and BiI₃ can react to form the halide perovskite Cs₃Bi₂I₉.

The at least one precursor is selected such that a halide perovskite with a stable crystal structure is generated. For example, the Goldschmidt tolerance factor, τ, can be used to estimate how well an A site cation can fit with a BX₃ octahedral framework:

$$τ = \frac{( {r}_{A} + {r}_{X} )}{\sqrt{2 ( {r}_{A} + {r}_{X} )}} ,$$

where, r_{A}, r_{B} and r_{X} are corresponding ionic radii accounting for valence and coordination, and r=1 indicates an ideal fit. Additionally an octahedral factor is a second critical stability criteria for the formation of perovskite structures, defined as

$$μ = \frac{{r}_{s}}{{r}_{x}} ,$$

which accounts for geometrical favorability of fitting a B atom in an octahedral hole. Favorable tolerance factors are in the range of greater than or equal to about 0.88 to less than or equal to about 1.05 for perovskite phases, while values less than about 0.88 can lead to non-perovskite structures; similarly, favorable octahedral factors μ are greater than or equal to about 0.41. therefore, selection of the halide perovskite; and therefore, of the at least one precursor, may be determined based on the foregoing factors. Non-limiting examples of halide perovskite that satisfy both the tolerance factor τ and the octahedral factor μ include CsSnCl₃ (τ=0.94, μ=0.53), CsSnBr₃ (τ=0.93, μ=0.49), CsSnI₃ (τ=0.91, μ=0.44), RbSnCl₃ (τ=0.90, μ=0.53), RbSnBr₃ (τ=0.89, μ=0.49), KSnCl₃ (τ=0.88, μ=0.53), MASnCl₃ (τ=1.01, μ=0.53), MASnBr₃ (τ=1.00, μ=0.49), and MASnI₃ (τ=0.98, μ=0.44).

Moreover, in various embodiments, the at least one precursor comprises at least one dopant. The dopant can be, for example, a p-type dopant or an n-type dopant. Non-limiting examples of dopants are described above.

In block 108, the method 100 comprises disposing a film of halide perovskite derived from the at least one precursor on the substrate or buffer layer. The disposing comprises evaporating the at least one precursor, and depositing a film comprising a halide perovskite derived from the at least one precursor on a single crystal substrate. In various embodiments, the disposing comprises evaporating a first precursor corresponding to the formula AX, A′X or a combination thereof; evaporating a second precursor corresponding to a formula BX₂, B′X₄, CX₃, DX, or a combination thereof; reacting the evaporated first precursor with the evaporated second precursor to form halide perovskite corresponding to the formula AₘBₙX₃₊₂ₙ, Am′Bn′X_{m′+4n′}, A_{m″}B_{n″}B′_{n″*}X_{m″+2n″+4n″*}, AₘCₙXₘ₊₃ₙ, AₘCₙDₗXₘ₊₃ₙ₊ₗ, or (A′X)ₘBₙXₘ₊₂ₙ; and epitaxially growing a single domain film comprising the halide perovskite on the single crystal substrate (or buffer layer), wherein A, A′, B, B′, C, D, X, m, m′, m″, n′, n″, n′″, n″*, and l are defined above. Non-limiting examples of perovskites are provided above.

In various embodiments, the halide perovskite is generated at a deposition rate of greater than or equal to about 0.01 Å/s to less than or equal to about 20 Å/s The film comprising the halide perovskite has a thickness TI equal to a monolayer of the halide perovskite to less than or equal to about 3× the exciton Bohr radius of the halide perovskite. In various embodiments, the halide perovskite has a thickness TI of greater than or equal to about 1 pm to less than or equal to about 100 nm, or greater than or equal to about 1 nm to less than or equal to about 50 nm.

The evaporating and depo siting are performed by vapor deposition method selected from the group consisting of molecular beam epitaxy, atomic layer deposition (ALD), thermal evaporation, evaporating, sputtering, pulsed laser deposition, electron beam evaporation, chemical vapor deposition, cathodic arc deposition, and electrohydrodynamic deposition. The epitaxial growth of halide perovskites can be monitored in real-time and in situ using reflection high-energy electron diffraction using (RHEED). The vapor deposition is performed at a temperature of greater than or equal to about room temperature (or lower) to less than or equal to about 1000° C. In other embodiments, the at least one precursor comprises the predetermined halide perovskite, and the evaporating and depositing are performed by sputtering. Regardless of the deposition method, there is a lattice misfit of less than or equal to about 10%, or less than or equal to about 5% between the single crystal substrate and the halide perovskite of the film or a lattice misfit of less than or equal to about 3% or less than or equal to about 1% between the buffer layer and the halide perovskite of the film.

The structure of the halide perovskite can be manipulated by adjusting the amounts of the precursors and optional dopant. For example, first and second precursors can be varied at a first precursor:second precursor ratio of about 1-100:1, 1:1, or 1:1-100.

Referring again to FIG. 2, in block 110 the method 100 optionally includes disposing a lattice matched layer on the film comprising a halide perovskite to generate a quantum well or a type I heterojunction, a type II heterojunction, or a type III heterojunction. The lattice matched layer 22 has a thickness Tₗₘ of greater than or equal to about 1 Å to less than or equal to about 108 Å and comprises a halide salt or halide salt alloy (as discussed above in regard to buffer layers), a semiconductor (such as the semiconductors described above in regard to the substrates), an insulator, a halide perovskite (including halide perovskites having different phases), Ge, InP, BaTiO₃, ZnSe, or CdS that has a lattice misfit of less than about 10% or less than about 5% with respect to the film comprising a halide perovskite at the interface. The lattice matched layer is disposed by vapor deposition.

In various embodiments, the method 100 further comprises disposing at least one additional bilayer comprising a second film comprising a halide perovskite and a second lattice matched layer on the first lattice matched layer, such that a second quantum well or heterojunction is formed between the second film and the first lattice matched layer to generate a semiconductor structure comprising a plurality of quantum wells and/or heterojunctions. The second film may comprise the same or different halide perovskite as the film comprising a halide perovskite and the second lattice matched layer may comprise the same or different material as the lattice matched layer.

Halide-perovskites are often polymorphic with complex, temperature dependent phase diagrams. Stoichiometry, temperature, and strain can all affect the crystal structure and symmetry of halide perovskites and drive additional phase transitions. Here, phase transitions can be induced to design coupling of phases with distinct properties. There are unique properties that can occur at the interface of coupled oxide perovskite including superconductivity, ferroelectricity, and magnetism, which can be controlled by engineering the symmetries and degrees of freedom of correlated electrons at the interface of oxide perovskite and suitable for application such as magnetic superconductors, non-centrosymmetric superconductors and multiferroics. Also, the introduction of strain during a cubic-tetragonal phase transition could lead to the formation of ferroelastic twin domains. Therefore, tunable phases of halide perovskite in multilayers leads to properties, such as ferroic, multiferroic and superconducting systems. The in-situ and real time diffraction techniques described for the deposition of halide perovskite films halide perovskite quantum well growth where each layer is monitored before being buried by the next.

By tuning the strain and stoichiometry, phase transitions can be controlled to different phases. For example, the phase transition of epitaxial CsSnBr₃ on NaCl from cubic to tetragonal and then back to cubic phase demonstrates that control over multilayer phases is achievable. Similarly, lattice constant engineering and stoichiometry control can be utilized to achieve controllable phase transition so that as-designed multi-phase film stack structures, i.e., semiconductor structures, with specific thickness and morphology can be fabricated.

Referring again to FIG. 2, after either the disposing of block 108 or the optional disposing of a lattice matched layer of block 110, the method 110 optionally comprises detaching or removing the single substrate from the semiconductor structure. The detaching or removing is performed, for example, by wet etching or epitaxial lift off. Wet etching is performed, for example, with water etching of the substrate. Epitaxial lift off is performed, for example, by immersing the epitaxial film grown on a substrate into liquid nitrogen for from greater than or equal to about 1 s to less than or equal to about 600 s, or from greater than or equal to about 5 s to less than or equal to about 30 s. Alternatively, the film and substrate can be subjected to flash heatings. The film and substrate are then immersed into a solvent or oil that cannot dissolve or destroy the sample with low boiling temperature (to prevent the sample from adsorbing water when it is taken out from the liquid nitrogen), such as, for example, diethyl ether. After warming, the film and substrate are removed from the solvent or oil and tape is pressed onto the halide perovskite film (with or without a gold layer on top). The tape can be conductive or non-conductive, transparent or non-transparent, a polymer, or a metal. Slowly peeling the tape then separates the halide perovskite film from the substrate. Separating halide perovskite structures from the substrate allows for the substrate to be reused and for the halide perovskite structure to be inserted more easily into devices

The current technology further provides a semiconductor structure made by the method 100, such as the structures describe above with reference to FIGS. 1A-1D.

Embodiments of the present technology are further illustrated through the following non-limiting examples.

### Example 1

The growth of epitaxial semiconductors and oxides has revolutionized the electronics and optics fields and continues to be exploited to uncover new physics stemming from quantum interactions. While the recent emergence of halide perovskites offer exciting new opportunities for a range of thin-film electronics, the principles of epitaxy have yet to be applied to this new class of materials and the full potential of these materials is still not yet known. Methods of inorganic halide perovskite epitaxy are now provided. The epitaxy is enabled by reactive vapor phase deposition onto single crystal metal halide substrates. For the archetypical halide perovskites, CsSnBr₃ and CsSnI₃, different epitaxial phases that emerge via stoichiometry control that are both stabilized epitaxially with vastly differing lattice constants and that are accommodated via epitaxial rotation are described. This epitaxial growth is exploited to demonstrate multilayer quantum wells of a halide-perovskite/metal-halide system. These methods push halide perovskites to their full potential.

### Methods

Epitaxial and Quantum Well Growth

Vapor deposition of perovskites was performed in a multisource custom thermal evaporator (Angstrom Engineering) equipped with a real-time and in situ reflection high-energy electron diffraction (RHEED) system (STAIB Instruments). The precursors, CsBr and SnBr₂, (or CsI and SnI₂), were co-evaporated from separate tungsten boats to form a perovskite layer. Prior to growth, NaCl (100) (and KCl (200)) single crystal substrates were freshly prepared by cleaving in a glovebox. Epitaxial growth was performed under a base pressure of less than 3×10−6 torr and deposition rates were measured in situ with a quartz crystal microbalance. The crystal structure was monitored in situ and in real-time using RHEED (30.0 keV) optimized with an ultra-low current (less than 10 nA) to eliminate damage and charging of the film over the growth times investigated. RHEED oscillations were monitored with substrates fixed at various in-plane orientations (KSA400). Rotation dependent RHEED patterns were collected after each deposition was halted via source and substrate shutters. Quantum well multilayers were fabricated under similar growth conditions where epitaxial NaCl (or KCl) was vapor deposited from a NaCl (or KCl) powder source at a rate of 0.02 Å/s. In the quantum well samples, the top layer of NaC (or KCl) is 1.5 nm.

Material Characterization

Cross-section transmission electron microscope (TEM) samples were prepared by focused ion beam (FIB) attached to a FEI Nova 200 Nanolab SEM/FIB and then analyzed by JEOL 3100R05 Double Cs Corrected TEM/STEM. A carbon top-layer was deposited on the cutting area to protect the epitaxial film. Scanning electron microscopy (SEM, Carl Zeiss Auriga Dual Column FIB SEM) was performed for ex situ film thickness calibration and morphology characterization. Photoluminescence spectra were measured using a PTI Quanta Master 40 spectroflurometer under a nitrogen atmosphere and various excitation wavelengths. Dielectric long-pass filters were used during the PL measurement to prevent both wavelength doubling and light bleeding. UV-VIS transmission spectra were taken using a Perkin Elmer UV-VIS Spectrometer for CsSnBr₃ and CsSn₂Br₅ samples (Lambda 900) and CsSnI₃ (Lambda 1050). X-ray diffraction was characterized with use of a Bruker D2 Phaser XRD instrument with a Cu Kα source at 30 kV and 10 mA and a Ni filter in the Bragg-Brentano configuration. X-ray photoelectron spectroscopy was performed in a separate chamber with a Kratos Axis Ultra XPS using a monochromated AlKα (1.486 keV) as X-ray source. Before taking XPS, the films were etched by Argon ion for 1.5 min to prevent the interference of surface contamination.

Simulation of Crystal and Band Structures

Electronic band structures and densities of states (DOS) of CsSnBr₃ and CsSn₂Br₅ were simulated using density functional theory (DFT). Electronic band structures and densities of states (DOS) of CsSnBr₃ and CsSn₂Br₅ were simulated using density functional theory (DFT). The exchange-correlation functional is the Perdew-Burke-Ernzerhof (PBE) functional, which belongs to the generalized gradient approximations (GGA) class, and the Heyd-Scuseria-Ernzerhof (HSE06), which is a screened hybrid functional. The structures of the materials were optimized using DFT with the PBE functional, resulting in a cubic unit cell with a=5.888 Å for CsSnBr₃ and a tetragonal unit cell with a=b=8.483 Å, c=15.28 Å for CsSn₂Br₅. Additional computational details are described below. Crystal structures were drawn using VESTA and SAED patterns and were simulated with CrystalMaker.

Computational Details

All the DFT calculations were performed using the Vienna Ab initio Simulation package (VASP) with the implemented projector augmented wave (PAW) potentials. All electronic self-consistent energy calculations converge within the accuracy of 1E−5 eV between each electronic iteration. Gaussian smearing with a smearing width of 0.05 eV is used to treat bands with partial occupancies. For the cubic unit cell, an energy cutoff of the plane wave basis set (ECUT) equal to 300 eV and a gamma-centered 8×8×8 k-point mesh were used for both PBE and HSE06 calculations. For the tetragonal unit cell, using a gamma-centered 4×4×2 k-point mesh (i.e., k-point spacing of 0.03 Å⁻¹) was suitable. For HSE06 calculations, E_{CUT}=250 eV was used, which yields an error of about 10 meV, but reduces computational cost. For PBE and HSE06 band structure calculations, paths connecting high-symmetry k-points were divided into 10-15 k-points. The high symmetry points in the plots were previously defined. For PBE DOS calculations, a finer grid of k-point that has the separation between k-points of around 0.01 Å⁻¹ was used, i.e., gamma-centered 16×16×16 and 11×11×6 grids were used for the CsSn₂Br₅ and CsSnBr₃ DOS calculations, respectively. For HSE06 DOS calculations, the gamma-centered 8×8×8 and 4×4×2 k-point meshes for CsSnBr₃ and CsSn₂Br₅ were used, respectively. These grids result in a k-point spacing of around 0.02-0.03 Å⁻¹, which is sufficient for DOS calculations.

### Results and Discussion

Cesium Tin Bromide

A. Epitaxial Growth

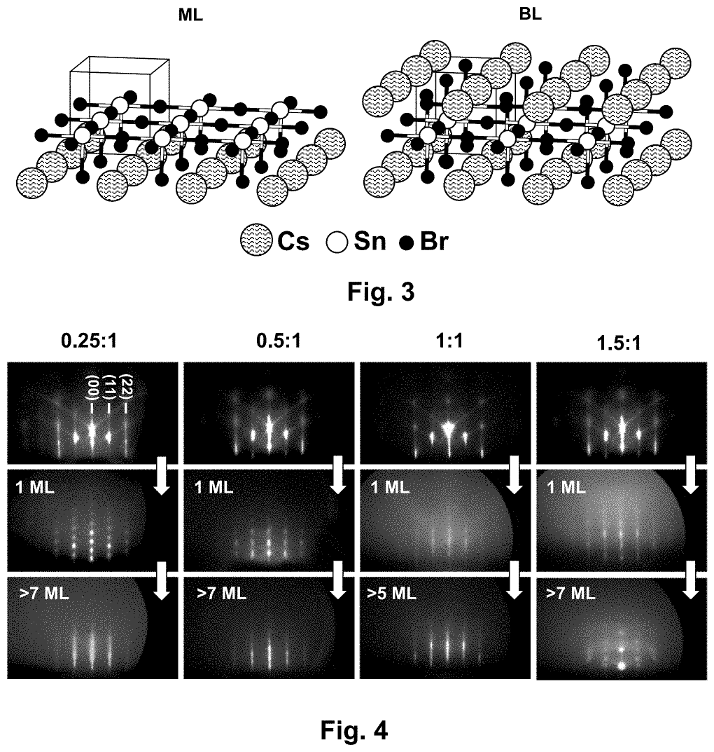

Metal halide salts have been used in the epitaxial growth studies of organic semiconducting materials. Here, they provide an ideal range of lattice constants (5.4-6.6 Å) closely matched to those of the halide perovskites (5.5-6.2 Å) that can be exploited for halide perovskite epitaxy with similar bonding interactions (congruent interaction), low cost, and can be wet-etched for transferring epitaxial films for a range of applications. CsSnBr₃ is a promising and air-stable candidate in optoelectronics with a bandgap of 1.8 eV. The lattice constant of cubic CsSnBr₃ (5.80 Å, see FIG. 3) is most closely lattice matched from all the MX alkali halide salts with NaCl (cubic lattice constant of 5.64 Å). While the compressive misfit between CsSnBr₃ and NaCl is −2.8%, this provides one of the smallest misfits readily available.

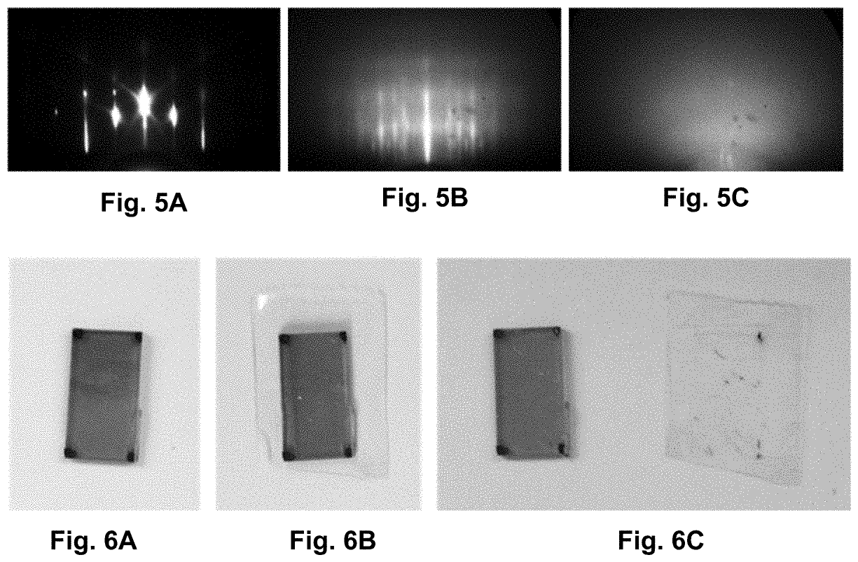

Thin film cesium tin bromide was grown epitaxially on NaC single crystalline substrates via reactive thermal deposition of CsBr and SnBr₂. The crystal growth was monitored in situ and in real-time with ultra-low current reflection high-energy electron diffraction (RHEED) that enables continuous monitoring even on insulating substrates. RHEED patterns captured during the epitaxial growth of the perovskite are shown in FIG. 4. The first row of FIG. 4 shows the initial RHEED patterns of the NaCl(100) crystal with the electron beam directed along the NaCl[110]. The impact of the precursor ratio on the film crystal structure is investigated with CsBr:SnBr₂ molar ratios ranging from 0.25:1 to 1.5:1. As a control experiment, the individual growths of both precursors CsBr and SnBr₂ on NaCl(100) surface show distinct (and rotationally-disordered) patterns from the reacted perovskite film (shown in FIGS. 5A-5C). The epitaxially deposited halide perovskite films are strongly bonded to the metal halide crystals (see FIGS. 6A-6C).

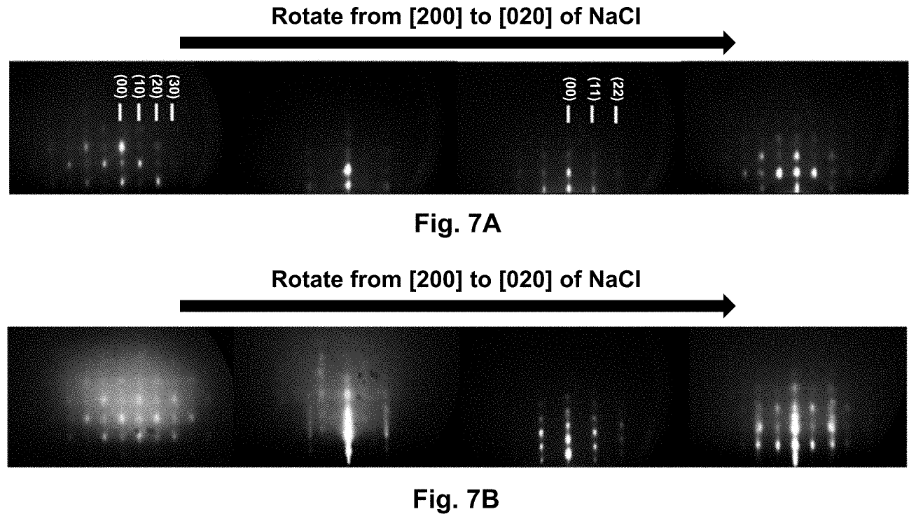

When depositing CsSnBr₃ using a molar ratio of 1:1 (CsBr:SnBr₂), the RHEED patterns remain streaky, indicating the formation of a smooth crystalline layer. After the deposition of the first monolayer, the underlying substrate Kikuchi lines disappear as expected due to the shift in elemental composition. The geometry and spacing of these reciprocal lattice points obtained along the [110] and [100] indicate that the crystal structure of the perovskite is cubic with a calculated lattice constant of 5.8±0.1 Å (shown in FIG. 7A) that is further confirmed with ex situ XRD to obtain an out-of-plane lattice constant of 5.795±0.005 Å (discussed below). Several other bulk phases have been reported for CsSnBr₃, including tetragonal and monoclinic phases; however, only the cubic phase is stable at room temperature. The high symmetry shown in the all the diffraction data clearly indicate the presence of the cubic phase (FIG. 7A). Thus, the films are not pseudomorphic past the first monolayer, which is in accordance with the level of compressive misfit. This implies there is a small critical thickness and that there will be a large dislocation density to accommodate the misfit. However, because it is compressive misfit, it is less likely to lead to film cracking than if it were tensile misfit. Ultimately such misfit can likely be tuned through compositional alloying of the metal halide substrate, either in the bulk or as thin layers.

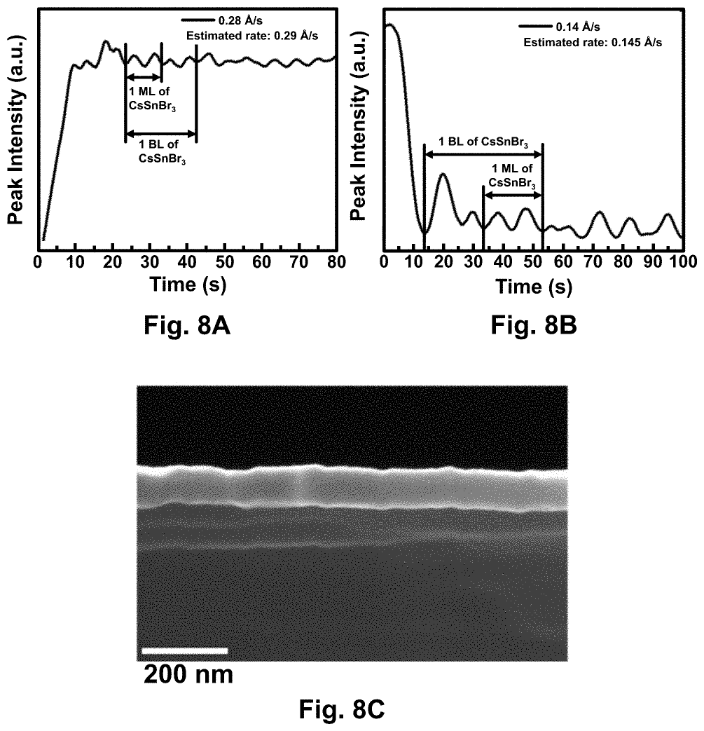

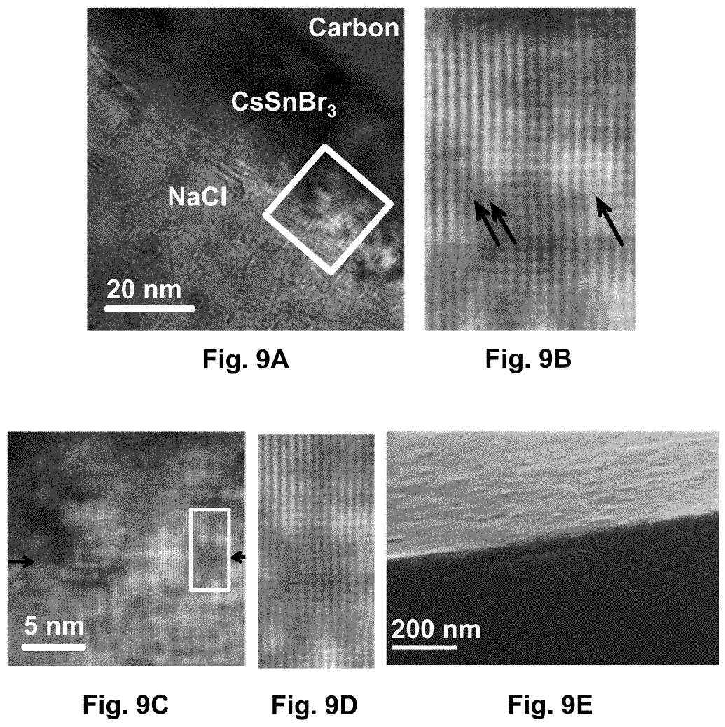

During this 1:1 growth, clear RHEED oscillations that vary with deposition rate are observed. Such oscillations are a hallmark of layer-by-layer growth (FIGS. 8A-8B) where the oscillation period typically correspond to the growth a monolayer or bilayer, but can also show complex bimodal periods. Here, the oscillation period corresponds to half a monolayer (two periods per monolayer), which suggests a more complex underlying reactive growth mechanism or an associated reconstruction during the reaction. FIG. 8C shows a cross-section SEM image used for growth rate calibration. This is also similar to RHEED oscillation beating seen in ZnSe migration enhanced epitaxial growth on GaAs where the oscillation period corresponded to a half monolayer. Cross-section TEM images of the epitaxial CsSnBr₃ film are shown in FIGS. 9A-9E. Despite the mismatch between NaCl and CsSnBr₃, the atomic arrangement at the interface is highly ordered and essentially indistinguishable. The cross-section SEM shown in FIG. 9E further confirms the smooth surface of films prepared with 1:1 ratio of CsBr and SnBr₂, indicating its suitability for the fabrication of thin-film opto-electronic devices.

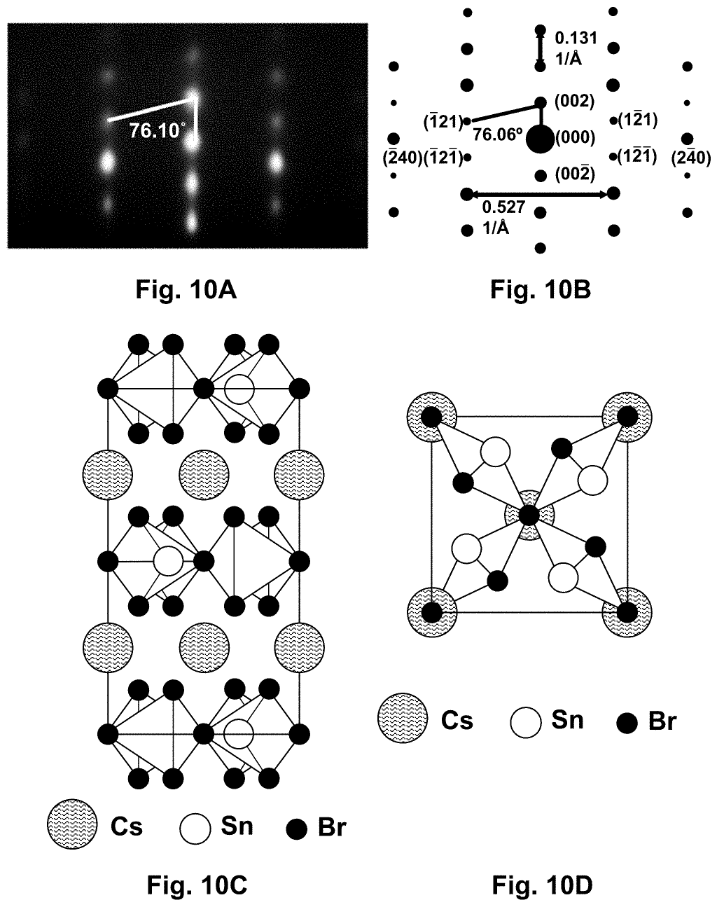

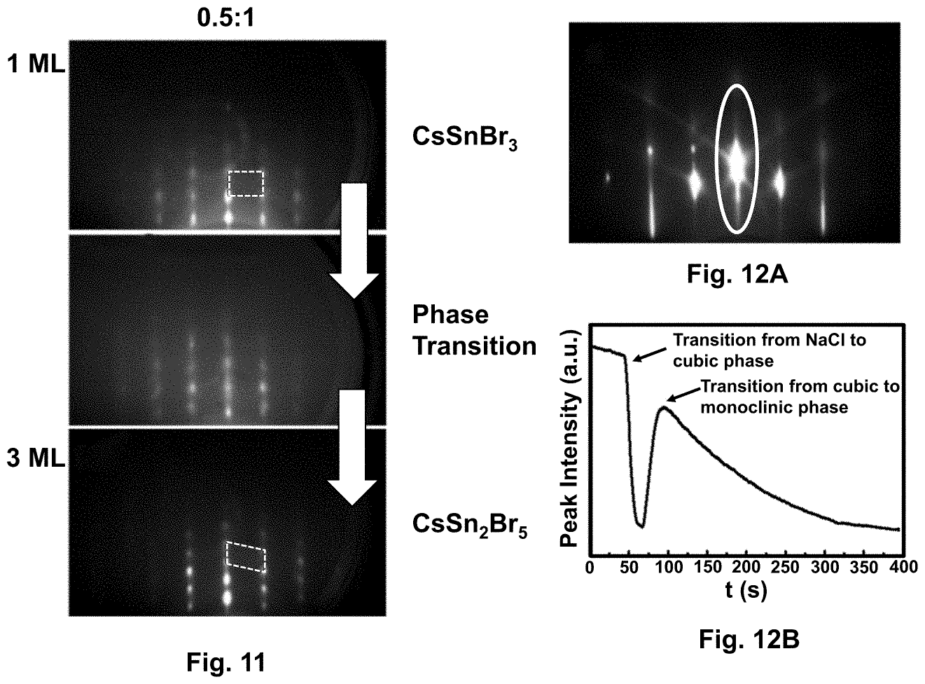

In contrast to the growth with a 1:1 stoichiometry, growth with a 0.5:1 stoichiometry results in a phase transition from the cubic CsSnBr₃ to a stable tetragonal phase that takes place at the earliest stages of growth within the first 2 monolayers. Rotation dependent RHEED patterns for the tetragonal phase are shown in FIG. 7B. While tetragonal distortions are common for large lattice misfits, the tetragonal phase is not a simple distortion, neither is reported low temperature tetragonal, and appears to be a monoclinic phase when monitored along the NaC [110] direction. Upon inspection of the RHEED data, simulated selected area electron diffraction (SAED) patterns, and XRD data the new phase is found to be the CsSn₂Br₅ phase. CsSn₂Br₅ has a bulk tetragonal structure with lattice constants of a=8.48 Å and c=15.28 Å45. The d-spacings along the substrate normal and along in-plane axes parallel to the NaCl [110] are 7.58±0.12 Å and 3.77±0.05 Å, respectively. The d-spacings, 7.58±0.12 Å is close to a half value of 15.28 Å corresponding to the d-spacings of (002) crystal planes of CsSn₂Br₅; 3.77±0.05 Å is close to the d-spacings of (210) crystal planes of CsSn₂Br₅, 3.79 Å. The RHEED pattern along NaCl [110] is consistent with the simulated SAED pattern of CsSn₂Br₅ along [210] direction (shown in FIGS. 10A-10D). Therefore, this indicates that the growth with moderate Cs deficiency leads to the susceptibility to transition to CsSn₂Br₅. This phase transition process is further elucidated by the RHEED data in FIG. 11 where only the first ML is cubic and then the subsequent layers transform to the tetragonal phase, even if the growth is halted. Real time RHEED videos showing the phase transition were made. The transition was monitored with substrates fixed at NaCl [110] since the phase transition is only observed along this direction due to the symmetry and lattice matching of the a-b plane of the tetragonal phase. The RHEED intensity monitoring also allows the study of phase transitions from cubic to tetragonal because RHEED pattern changes can be monitored as the change of particular diffraction spots locations (FIGS. 12A-12B). At later stages of growth (greater than 7 MLs) the spotty patterns of the tetragonal phase become streaky, which is indicative of the crystalline film changing from rough to smooth while maintaining the initial tetragonal crystal structure as observed via RHEED.

Epitaxial growth with both a greater CsBr deficiency (0.25:1) and excess (1.5:1) were also investigated as shown in FIG. 3. At the 0.25:1 ratio, the pure tetragonal phase is observed (without first seeing the cubic structure). Further increasing the CsBr:SnBr₂ ratio to 1.5:1 results in ring-like patterns, which indicates the film becomes a three-dimensional polycrystalline powder.

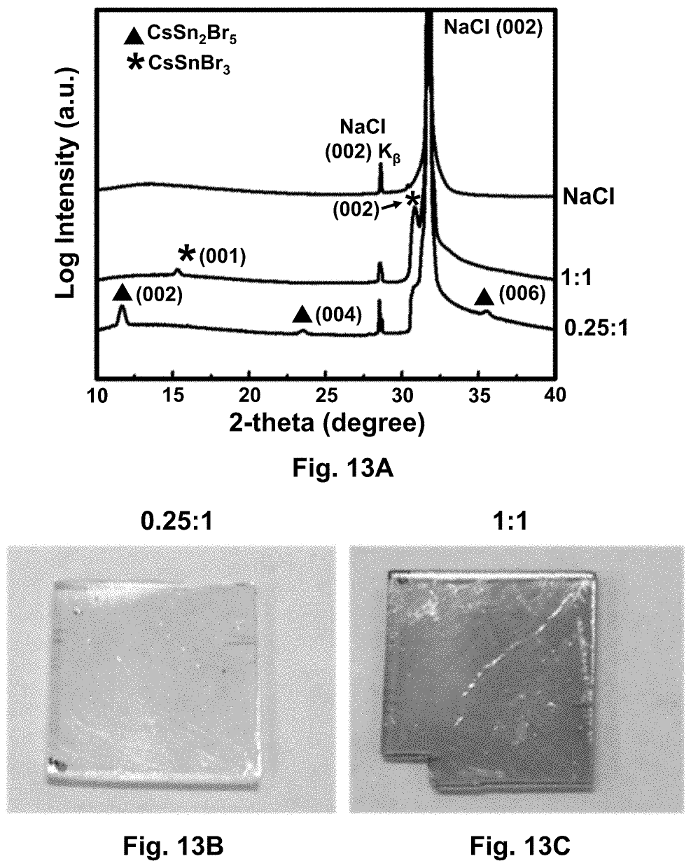

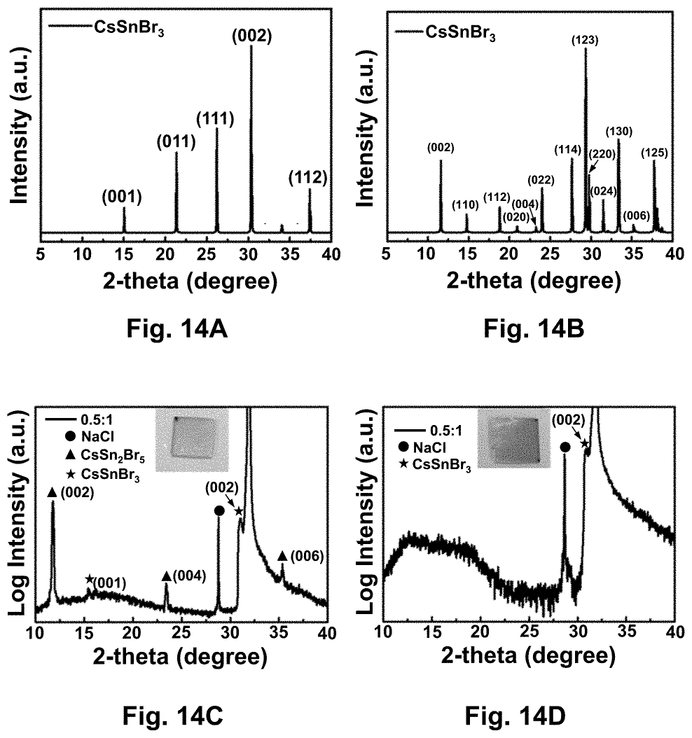

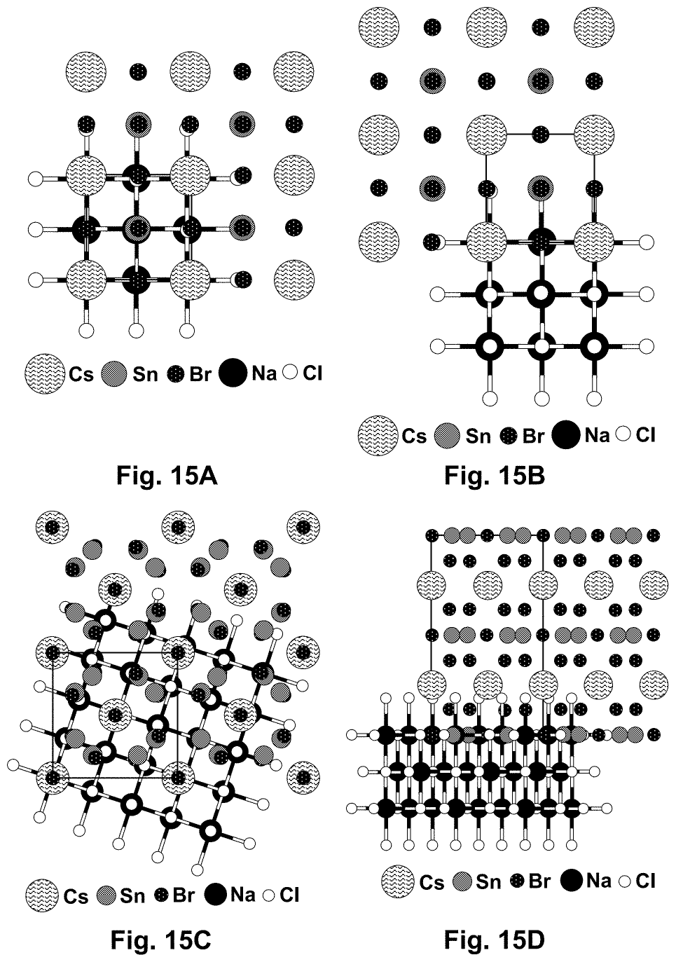

To further confirm the phases shown in the RHEED patterns, X-ray diffraction (XRD) was used to determine the out-of-plane lattice parameter for the epitaxial films. As the ratio of CsBr to SnBr₂ increases from 0.25:1 to 1:1, the peaks at 11.57° (d=7.678±0.007 Å) and 23.46° are replaced by peaks at 15.31° (d=5.795±0.005 Å) and 30.83° as shown in FIGS. 13A-13C. The observed peaks are consistent with the d-spacings along the c-axis calculated from RHEED patterns and correspond to the (001)/(002) and (002)/(004) peaks of the cubic CsSnBr₃ and tetragonal CsSn₂Br₅ phases respectively. Based on the RHEED and XRD data, the measured lattice constants and orientations of the two epitaxial phases are summarized in Table 1, along with simulated XRD patterns of polycrystalline CsSnBr₃ and CsSn₂Br₅ (FIGS. 14A-14D). Surprisingly, both the cubic CsSnBr₃ and tetragonal CsSn₂Br₅ can grow epitaxially, even though the lattice constant of CsSn₂Br₅ is much larger and the mismatch between CsSn₂Br₅ and NaCl is 4.9%. This larger lattice is accommodated via the rotation of CsSn₂Br₅ relative to the metal halide substrates. For the cubic CsSnBr₃, the (001) crystal planes stack along the [001] direction of NaCl. In contrast, the CsSn₂Br₅ epitaxial phase is rotated so that the (210) crystal planes of CsSn₂Br₅ are parallel to the (110) crystal planes of NaCl. Schematics of the epitaxial growth of CsSn₂Br₅ and CsSnBr₃ on NaCl substrates is shown in FIGS. 15A-15D.

TABLE 1
Lattice constant and film orientation obtained from RHEED patterns and XRD data.

| | | CsSnBr₃ | CsSn₂Br₅ |
|---|---|---|---|
| | | Pm3m, | I4/mcm, a = b = 8.48 Å, |
| Bulk Crystal structure | | a = b = c = 5.80 Å | c = 15.28 Å |
| Precursor Ratio of | 0.25:1 | — | Observed |
| CsBr to SnBr₂ | 0.5:1 | Observed < 2 ML | Observed > 3 ML |
| | 1:1 | Observed | — |
| | 1.5:1 | — | — |
| Orientation | Along NaCl [110] | [110] | [210] |
| | Along NaCl [100] | [100] | [3-10] |
| | Along NaCl [001] | [001] | [002] |
| Mismatch with NaCl | | −2.8% | 4.9% |

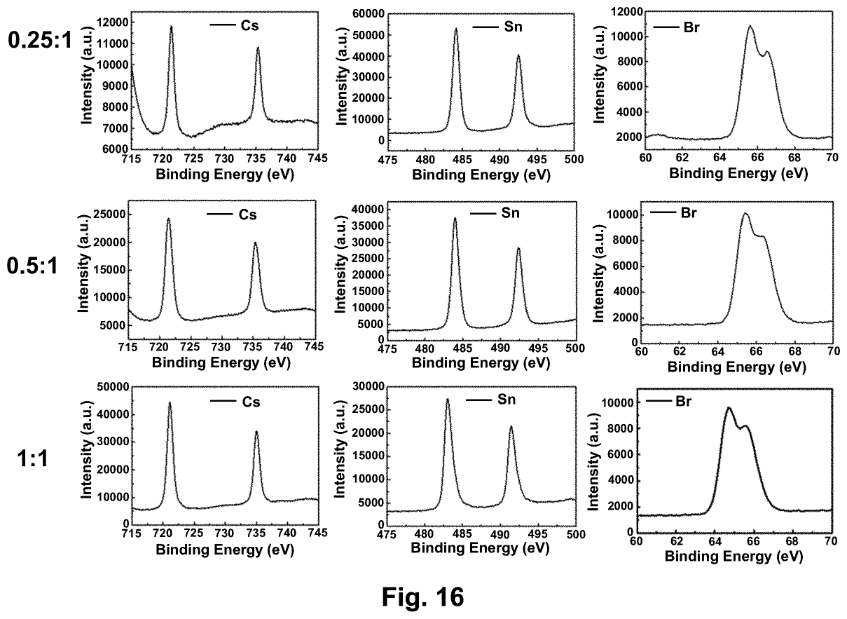

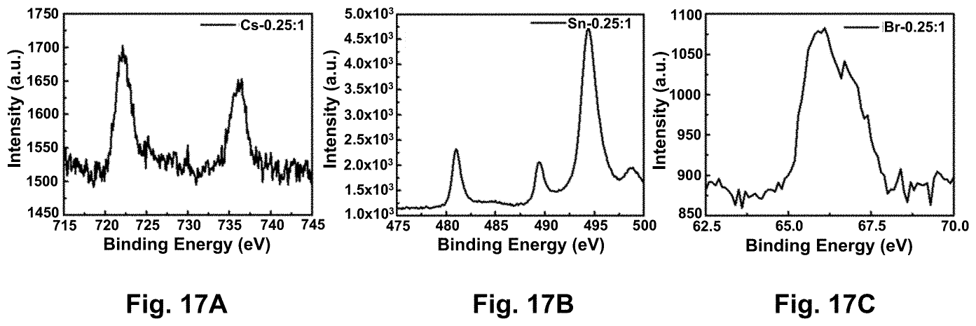

Epitaxial films were also characterized by X-ray photoelectron spectroscopy (XPS) as shown in FIG. 16 to measure the elemental ratios in the films deposited using various ratios. By fitting the XPS peak, the elemental ratio of Cs to Sn is calculated and summarized in Table 2. The epitaxial film deposited with 1:1 ratio of CsBr to SnBr₂ is indeed stoichiometric CsSnBr₃. The other two ratios of 0.25:1 and 0.5:1 both lead to deficient Cs. When prepared with a 0.25:1 ratio, the atomic concentration of Cs is much lower than that of Sn and Br. However, after Ar sputtering of the top surface, the atomic concentration of Cs increases, and the elemental ratio is close to stoichiometric CsSn₂Br₅ (as shown in FIGS. 17A-17C and Table 3). This suggests that the Cs vacancies concentrated at the interface are likely eliminated as the growth proceeds or subsequently concentrated as the growth is halted.

TABLE 2
Elemental ratio of as-deposited films obtained from XPS data.

| | Real Ratio | | |
|---|---|---|---|
| Precursor Ratio | Cs | Sn | Br |
| 0.25:1 | 1.0 ± 0.1 | 10.0 ± 1.0 | 13.3 ± 1.3 |
| 0.5:1 | 1.0 ± 0.1 | 3.0 ± 0.3 | 5.0 ± 0.5 |
| 1:1 | 1.0 ± 0.1 | 1.3 ± 0.1 | 2.9 ± 0.3 |

TABLE 3
Elemental ratio of as-deposited films obtained from
XPS data collected after 1.5 min Ar⁺ ion sputtering.

| | Real Ratio | | |
|---|---|---|---|
| Precursor Ratio | Cs | Sn | Br |
| 0.25:1 | 1.0 ± 0.1 | 4.0 ± 0.4 | 5.5 ± 0.6 |

The combination of RHEED, XRD and XPS analysis indicates that the growth of CsSnBr₃ is more favorable when Cs is stoichiometric or in slight excess, while CsSn₂Br₅ dominates when there is a Cs deficiency. Both selective elemental vacancies and lattice mismatch can ultimately play a role in initiating strain-driven phase transitions in these systems.

B. Optical Properties and Electronic Band Structures

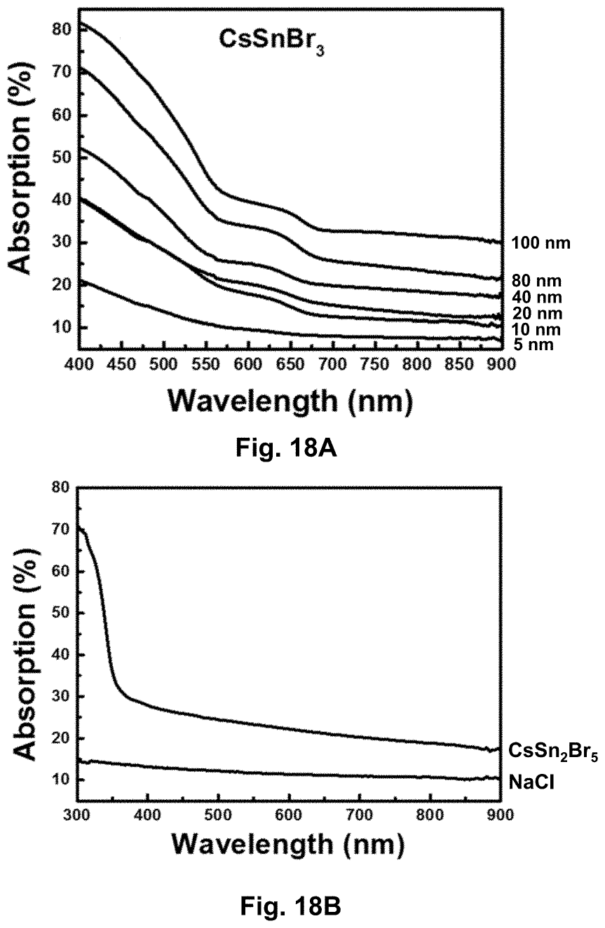

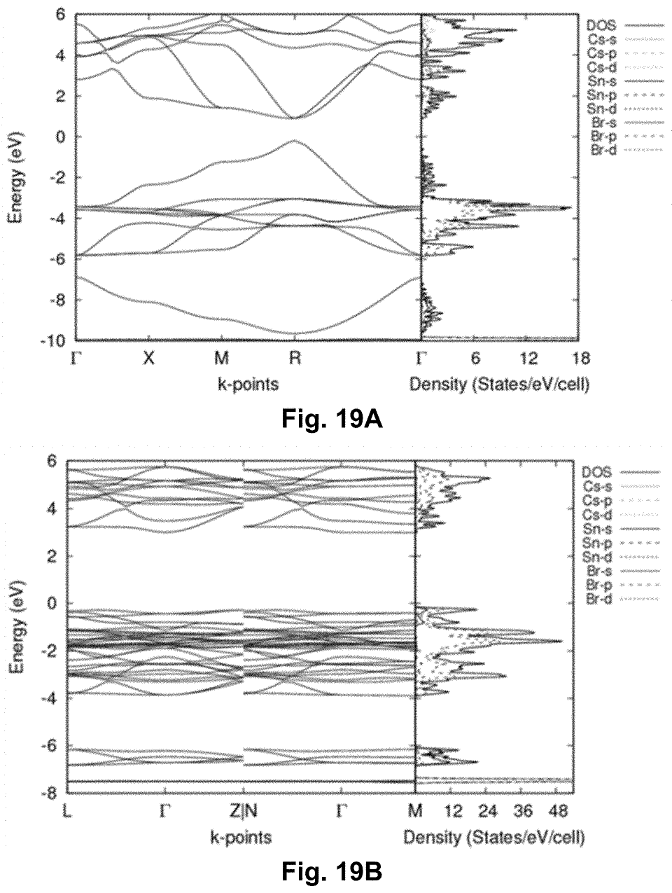

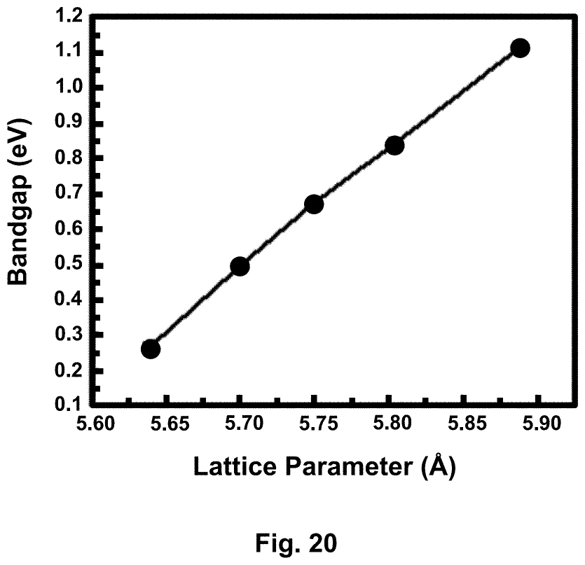

Experimental and theoretical studies were performed on the CsSn₂Br₅ and CsSnBr₃ phases. Absorption spectra of as-prepared epitaxial film are shown in FIGS. 18A-18B and confirm the band-gap of epitaxial CsSnBr₃ is 1.83±0.02 eV, which is consistent with both theoretical and experimental results reported previously. For CsSn₂Br₅, a bandgap of 3.34±0.04 eV (see FIGS. 18A-18B) is measured, which is clearly distinguishable from the NaCl bandgap of about 9 eV. The calculated band structures of CsSnBr₃ and CsSn₂Br₅ using the HSE06 functional are shown in FIGS. 19A-19B. Summary of the calculated band gap values can be found in Table 4. The resulting HSE06 band gaps for CsSnBr₃ and CsSn₂Br₅ are 0.084 eV and 3.12 eV, respectively. These values are in good agreement with the observed properties of CsSnBr₃ and CsSn₂Br₅. Had the perovskite been pseudomorphic, it is predicted that the bandgap would decrease by ˜0.5 eV. For comparison, the PBE band structures, DOS and projected density of states (PDOS) of CsSnBr₃ and CsSn₂Br₅ are shown in FIG. 20. These calculations further confirm that the tetragonal phase is CsSn₂Br₅ with a large bandgap.

TABLE 4
Calculated band gaps of CsSnBr₃ and
CsSn₂Br₅ using the DFT-PBE and DRT-HSE06 methods.

| | PBE band | HSE06 band | Experimental |
|---|---|---|---|
| Materials | gaps (eV) | gaps (eV) | value (eV) |
| CsSnBr₃ | 0.40 | 0.84 | 1.83 ± 0.02 |
| CsSn₂Br₅ | 2.33 | 3.12 | 3.34 ± 0.04 |

C. Fabrication of CsSnBr₃ Quantum Well

Quantum wells with varying well thickness with 1:1 stoichiometry using vapor deposited NaCl as the well barrier were fabricated. In general, quantum well devices are important in a range of opto-electronic devices and provide critical insight into the physical properties of quantum confined charge carriers, two-dimensional electron gas, and tunable luminescence.

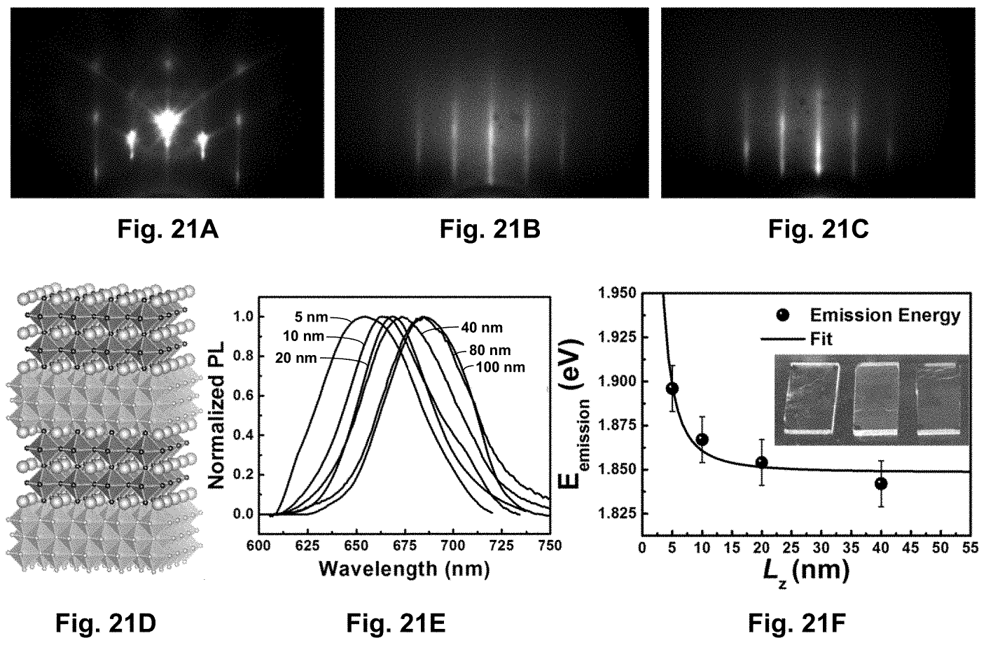

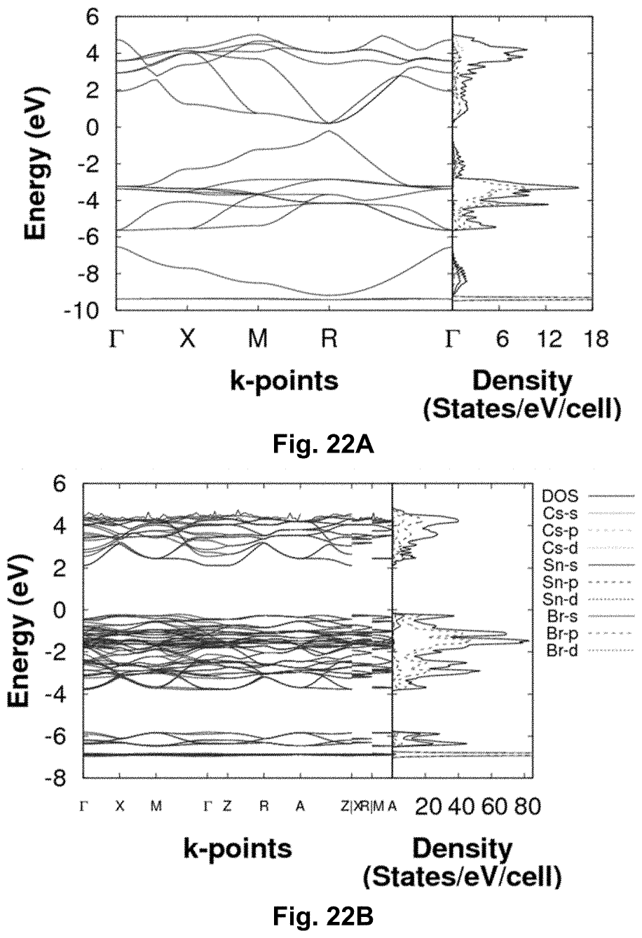

The growth process was analyzed by RHEED to confirm the formation of epitaxial multilayers as shown in FIGS. 21A-21C (and FIGS. 22A-22B for a greater number of layers) where NaCl was grown under similar conditions to homoepitaxial growth demonstrated previously. This data shows that no obvious change occurs after depositing NaCl epitaxially on the halide perovskite nor after depositing multiple quantum well layers. That is, the NaC epitaxial layer is pseudomorphic with the relaxed perovskite film. The PL spectrum of NaCl/CsSnBr₃/NaCl quantum wells were studied by adjusting the well thickness (shown schematically in FIG. 21D).

When the well thickness was reduced from 100 nm to 5 nm, the emission peak shifted from 685 nm to 654 nm (FIGS. 21E-21F), which is similar in magnitude to CsSnBr₃ colloidal nanocrystals. From fitting the size dependence of the bandgap, an effective reduced mass of m*=0.30 mₑ is estimated, where mₑ is the rest mass of the electron, and Bohr radius of CsSnBr₃ of about 0.5 nm that is similar to Si (5 nm). This indicates that for nearly all well sizes, CsSnBr₃ is in the weak confinement regime and explains why the shift of the emission is small until well thicknesses are below 10 nm. In moving from a weak to strong confinement regime, the bandgap of CsSnBr₃ can reach up to 3.0 eV when the well thickness is about 1 nm (about 2 unit cells thick). Fitting of quantum well data is now provided. The emission energy of a quantum well is described by the Brus equation as:

$${E}_{g}^{well} ( {L}_{z} ) = {E}_{g}^{0} + Δ E ( {L}_{z} ) = {E}_{g}^{0} + \frac{{\overline{h}}^{2} {π}^{2}}{2 {m}^{*} * {L}_{z}^{2}} - \frac{1.8 {q}^{2}}{4 {πɛ}_{r} {ɛ}_{o} {L}_{z}} \qquad ( 1 )$$

where E_{g} is the bulk band gap, ΔE is the confinement energy of both electrons and holes, h is reduced Planck constant, L_{z} is the thickness of the quantum well, and m* is the reduced mass that can be obtained from the effective masses of the electron (mₑ) and the hole (mₕ*) as

$$\frac{1}{{m}^{*}} = \frac{1}{{m}_{e}^{*}} + \frac{1}{{m}_{h}^{*}} ,$$

q is the charge of electron, εᵣ is the relative permittivity, and ε₀ is the vacuum permittivity. Because the exciton binding energy of CsSnBr₃ has been reported to be less than 1 meV, the size dependence of the quantum well bandgap can be expressed as:

$${E}_{total} = {E}_{g}^{0} + Δ E = {E}_{g}^{0} + \frac{{\overline{h}}^{2} {π}^{2}}{2 m * {L}_{z}^{2}} \qquad ( 2 )$$

where the value of m* obtained by fitting the PL data of quantum well PL data can be extracted and then used for calculation of Bohr radius of this material by using Equation (2):

$${a}_{B} = \frac{4 π {\overline{h}}^{2} {ɛɛ}_{o}}{{e}^{2}} ( \frac{1}{{m}_{e}^{*}} + \frac{1}{{m}_{h}^{*}}$$

where a_{B} is the Bohr radius, e is the electron charge, ε₀ is the vacuum permittivity, and ε is the dielectric constant of the semiconductor which has been reported for CsSnBr₃ to be 32.4. Emission energies of CsSnBr₃ quantum wells with various widths are shown in Table 5.

TABLE 5
Emission energy of CsSnBr₃ quantum
wells with various well widths.

| Quantum Well Width (nm) | Emission Peak (nm) | Emission Energy (eV) |
|---|---|---|
| 5 | 654 | 1.896 |
| 10 | 664 | 1.867 |
| 20 | 669 | 1.854 |
| 40 | 673 | 1.842 |
| 80 | 684 | 1.813 |
| 100 | 685 | 1.810 |

D. Doping Engineering of Epitaxial CsSnBr₃

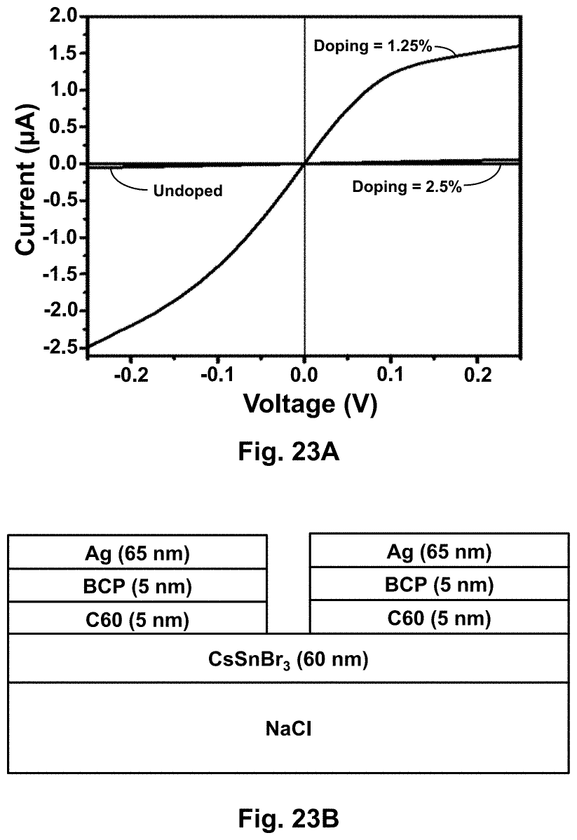

Doping engineering is a conventional method for controlling the semiconducting properties of epitaxial film. Here, we use BiBr₃ as the dopant to adjust the charge carrier concentration within the epitaxial film. I-V measurement was carried out to evaluate the property change along with varying dopant concentration from 0% to 2.5%, as shown in FIG. 23A. The structure scheme of devices is shown in FIG. 23B.

Cesium Tin Iodide

A. Epitaxial Growth

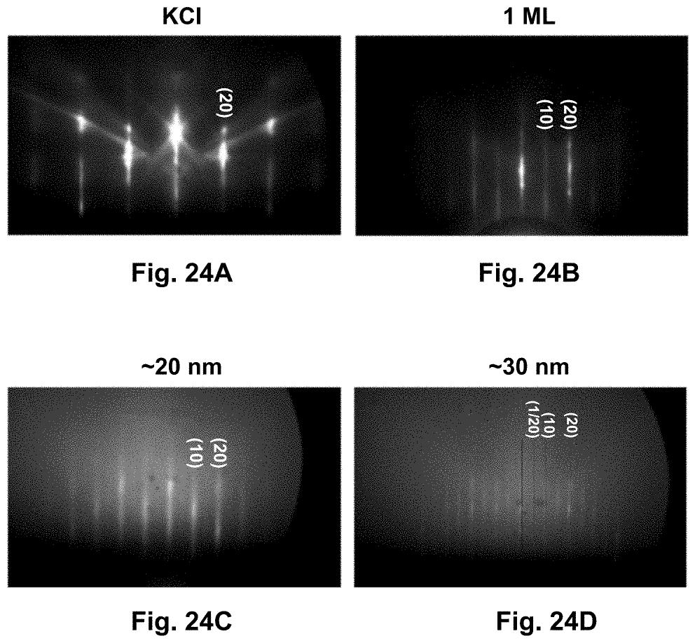

In situ RHEED patterns captured during epitaxial growth of the perovskite are shown in FIGS. 24A-24D. The initial RHEED patterns of a KCl(200) substrates with electron beam directed along KCl[200] is shown in FIG. 4. For CsSnI₃, the monolayer (ML) and bilayer (BL) thicknesses are defined as a/2 (3.1 Å) and a (6.2 Å), respectively. With co-deposition of CsI and SnI₂ in a ratio of 1:1 at lower deposition rate, the pattern remains streaky with the film thickness of ˜3.2 Å, which indicates the film morphology is very smooth. Meanwhile, there appear half-order streaks reflecting that the diffraction of crystal planes with an in-plane d-spacing doubling the original lattice constant of KCl (200), 6.29 Å. At 20 nm of growth, there is no obvious change in the streaky pattern showing that the film surface is still flat. Additional streaks emerge when the film thickness is around 30 nm, corresponding to quarter-order diffraction.

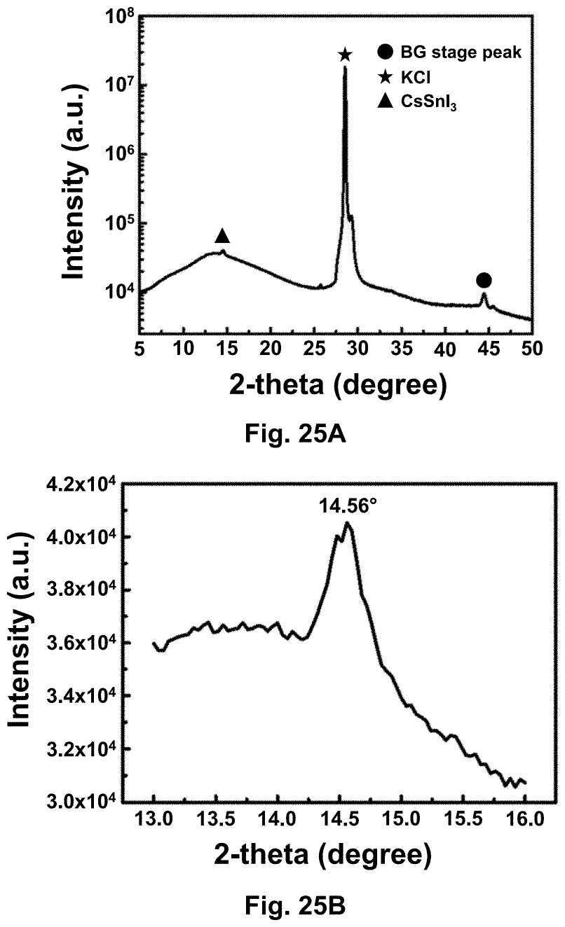

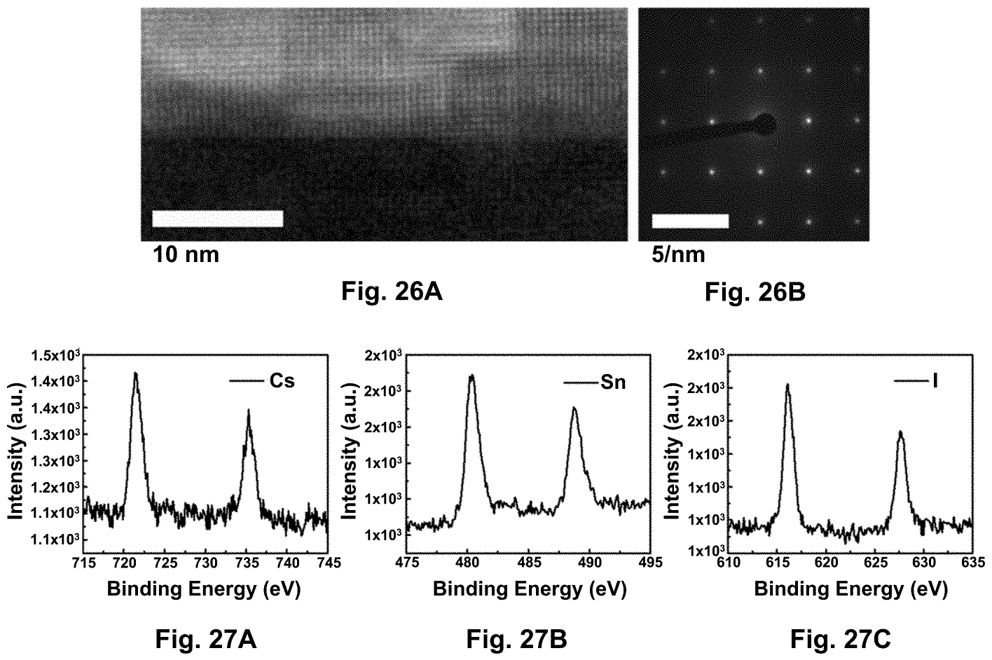

The out of plane XRD in FIGS. 25A-25B show that there is a peak at 14.56°, which can be assigned to the epitaxy film with d-spacing of 6.13 Å along [001] direction. The calculated d-spacing respectively from RHEED pattern and out of plan XRD coincide well. The atomic structure of the interface between the as-grown epitaxy and the KCl substrate has been investigated by cross-section high resolution transmission electron microscopy (HRTEM) as shown in FIGS. 26A-26B. The perovskite epitaxy has been colored to distinguish from the substrate. The atomic scale features at the interface imaged by HRTEM shows that there is little mismatch between the epitaxy and substrate, which highlights the high quality of epitaxial film. Meanwhile, SAED has been performed on the epitaxial film, which shows only one set of diffraction spots indicating the high ordering at the interface.

XPS was also performed to identify the real elemental ratios in the epitaxial film (shown in FIGS. 27A-27C). It shows that the ratios of Cs, Sn, I is close to the stoichiometry of CsSnI₃ as summarized in Table 6.

TABLE 6
Elemental ratio of as-deposited films obtained from XPS data.

| | Real Ratio | | |
|---|---|---|---|
| Precursor Ratio | Cs | Sn | I |
| 1:1 | 1.0 | 1.4 | 2.7 |

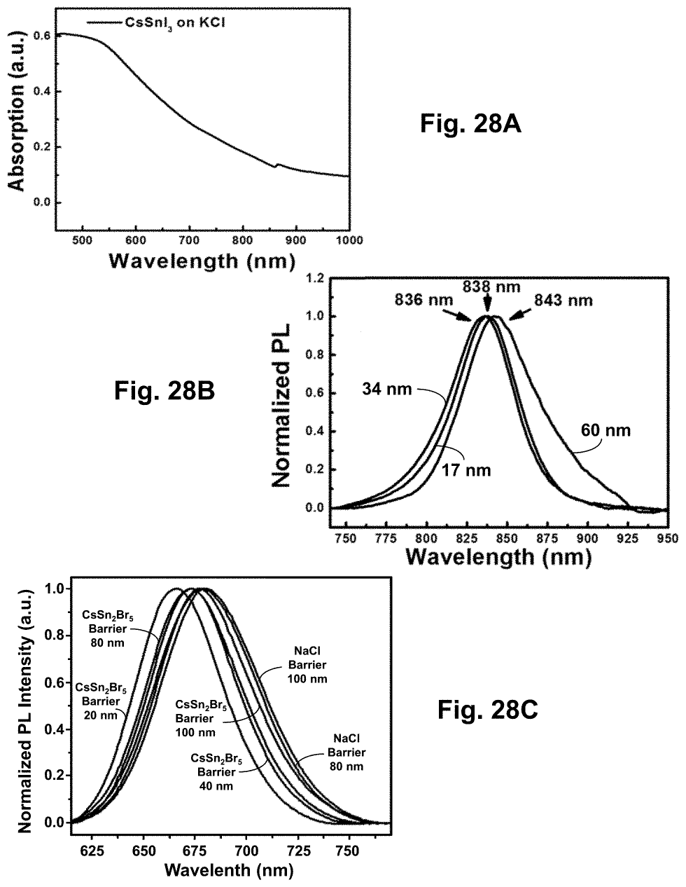

UV-Vis spectra in FIGS. 28A-28C show that the bandgap of the epitaxial film is about 1.35 eV. PL spectra of quantum wells of CsSn₃/KCl show a shift when the well width decreases.

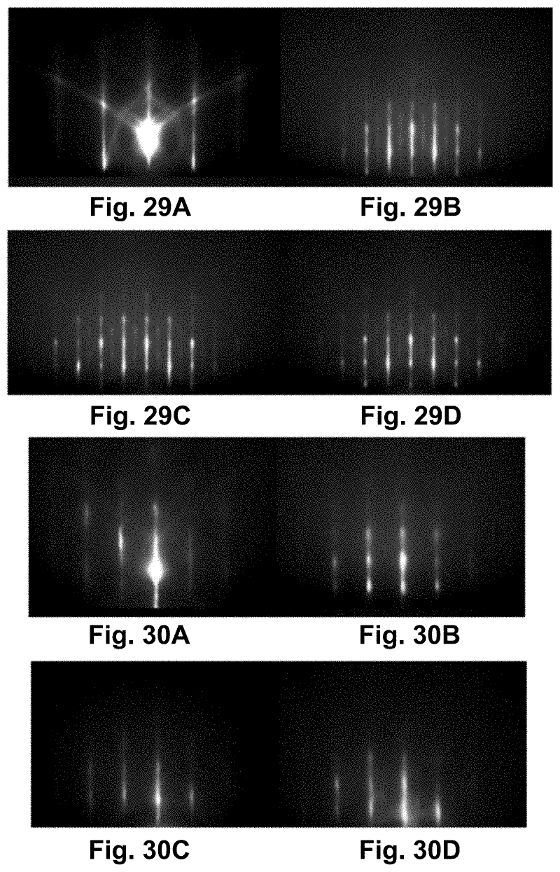

RHEED patterns (FIGS. 29A-29D and FIGS. 30A-30D) taken during the growth of quantum wells show that no obvious change occurs even after growing two pairs of CsSnI₃(˜10 nm)/KCl(1.5 nm). Therefore, the combination of inorganic halide perovskite and metal halide salts provides an opportunity for fabricating multilayer quantum wells.

A route to the epitaxial growth of an inorganic halide perovskites using metal halide crystals and show the emergence of different epitaxial phases of CsSnBr₃ (CsSnBr₃ and CsSn₂Br₅) and CsSnI₃ based on control over stoichiometry is demonstrated. Phase transitions between the cubic CsSnBr₃ and tetragonal CsSn₂Br₅ phases is observed in real-time. The epitaxial growth of CsSnBr₃ and CsSnI₃ is exploited to demonstrate multilayer epitaxial quantum wells of halide perovskites. These demonstrations unlock the epitaxial exploration to the full range of halide perovskites and help realize their full potential.

### Example 2

Epitaxial growth of inorganic halide perovskites is affected by various factors, such as, for example, substrate and temperature.

To obtain highly ordered epitaxial films, substrates can be chosen that have a lattice parameter close to that of an epitaxy to be grown on the substrate. Table 7 shows substrates that are most promising and less promising for CsSnBr₃ and Table 82 shows substrates that are most promising and less promising for CsSnI₃.

TABLE 7
Substrates for CsSnBr₃ epitaxy.

| | | | Lattice constant | | | | | |
|---|---|---|---|---|---|---|---|---|
| | | Space | a | b | c | α | β | γ |
| Name | Crystal system | group | (Å) | (Å) | (Å) | (degree) | (degree) | (degree) |

Most Promising For CsSnBr₃

| | | | | | | | | |
|---|---|---|---|---|---|---|---|---|
| NaCl | Cubic | Fm-3m | 5.64 | 5.64 | 5.64 | 90 | 90 | 90 |
| Ge | Cubic (Diamond) | Fd-3m | 5.646 | 5.646 | 5.646 | 90 | 90 | 90 |
| InP | Cubic (Zincblende) | F-43m | 5.869 | 5.869 | 5.869 | 90 | 90 | 90 |

Less Promising For CsSnBr₃

| | | | | | | | | |
|---|---|---|---|---|---|---|---|---|
| BaTiO₃* | Orthorhombic | Cmm | 4.031 | 5.647 | 5.649 | 90 | 90 | 90 |
| | (Barioperovskite) | | | | | | | |
| ZnSe | Cubic | F-43m | 5.668 | 5.668 | 5.668 | 90 | 90 | 90 |
| CdS | Cubic (Zincblende) | F-43m | 5.832 | 5.832 | 5.832 | 90 | 90 | 90 |
| NaBr | Cubic | Fm-3m | 5.98 | 5.98 | 5.98 | 90 | 90 | 90 |

*[100] oriented

TABLE 8
Substrates for CsSnI₃ epitaxy.

| | | | Lattice constant | | | | | |
|---|---|---|---|---|---|---|---|---|
| | | Space | a | b | c | α | β | γ |
| Name | Crystal system | group | (Å) | (Å) | (Å) | (degree) | (degree) | (degree) |

Most Promising For CsSnBr₃

| | | | | | | | | |
|---|---|---|---|---|---|---|---|---|
| NaCl | Cubic | Fm-3m | 5.64 | 5.64 | 5.64 | 90 | 90 | 90 |
| Ge | Cubic (Diamond) | Fd-3m | 5.646 | 5.646 | 5.646 | 90 | 90 | 90 |
| InP | Cubic (Zincblende) | F-43m | 5.869 | 5.869 | 5.869 | 90 | 90 | 90 |

Less Promising For CsSnBr₃

| | | | | | | | | |
|---|---|---|---|---|---|---|---|---|
| BaTiO₃* | Orthorhombic | Cmm | 4.031 | 5.647 | 5.649 | 90 | 90 | 90 |
| | (Barioperovskite) | | | | | | | |
| ZnSe | Cubic | F-43m | 5.668 | 5.668 | 5.668 | 90 | 90 | 90 |
| CdS | Cubic (Zincblende) | F-43m | 5.832 | 5.832 | 5.832 | 90 | 90 | 90 |
| NaBr | Cubic | Fm-3m | 5.98 | 5.98 | 5.98 | 90 | 90 | 90 |

*[100] oriented

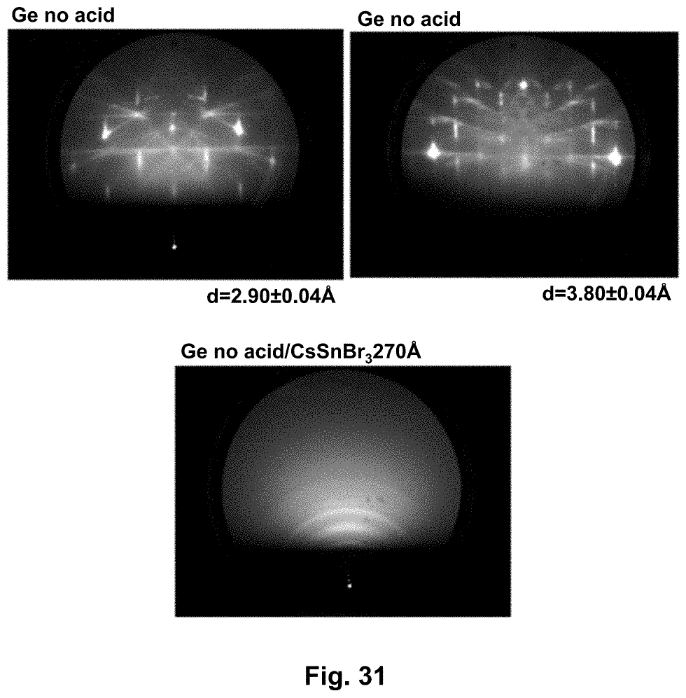

For example, and as shown in FIG. 31, although the misfit between Ge and CsSnBr₃ is similar to that between NaCl and CsSnBr₃, it leads to a polycrystalline CsSnBr₃ film because of the natural oxide formed on the surface of single crystalline Ge wafer.

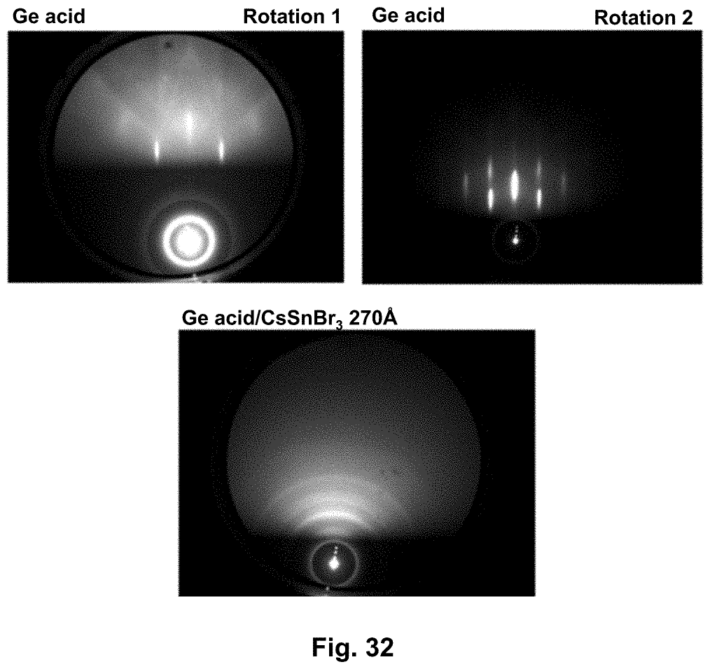

One of the most widely used methods to remove the natural oxide on the surface is acid-treatment, e.g., HCl treatment. However, after HCl treatment, the growth still results in the formation of polycrystalline CsSnBr₃. FIG. 32 shows growth of CsSnBr₃ on Ge with HCl treatment.

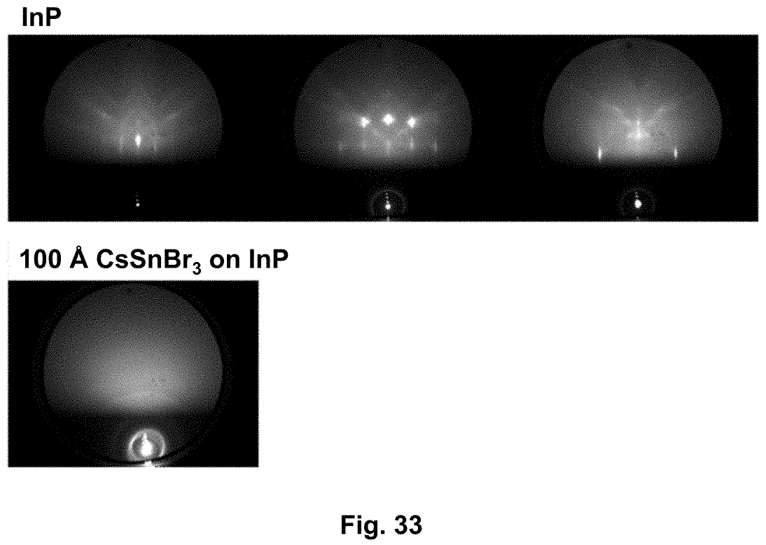

As shown in FIG. 33, the misfit between InP and CsSnBr₃ is only about 1.2%, which is very promising for epitaxial growth. However, with or without oxide removal treatment, the growth still results in the formation of polycrystalline CsSnBr₃.

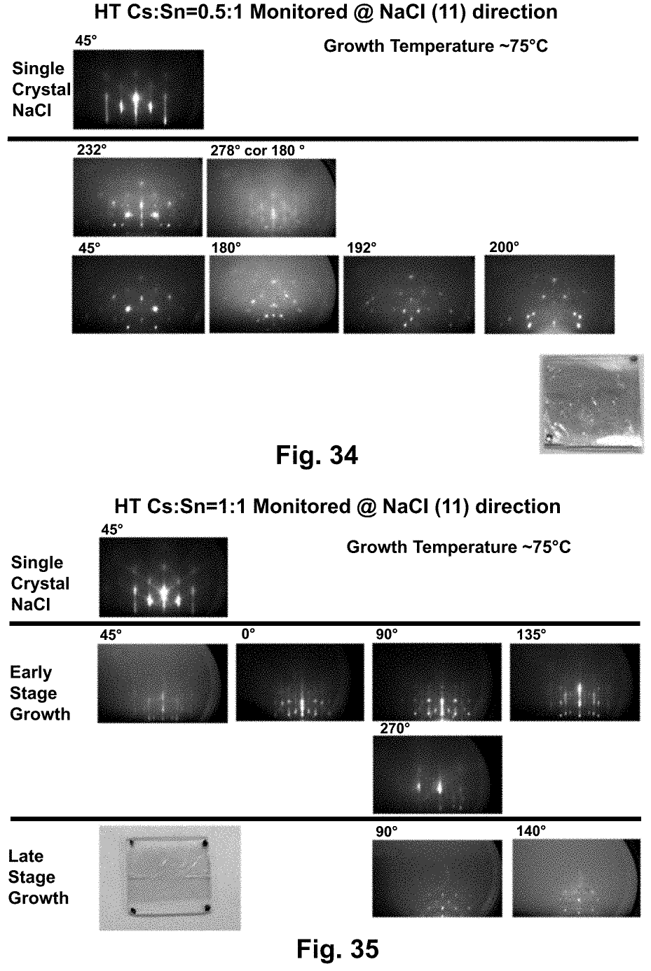

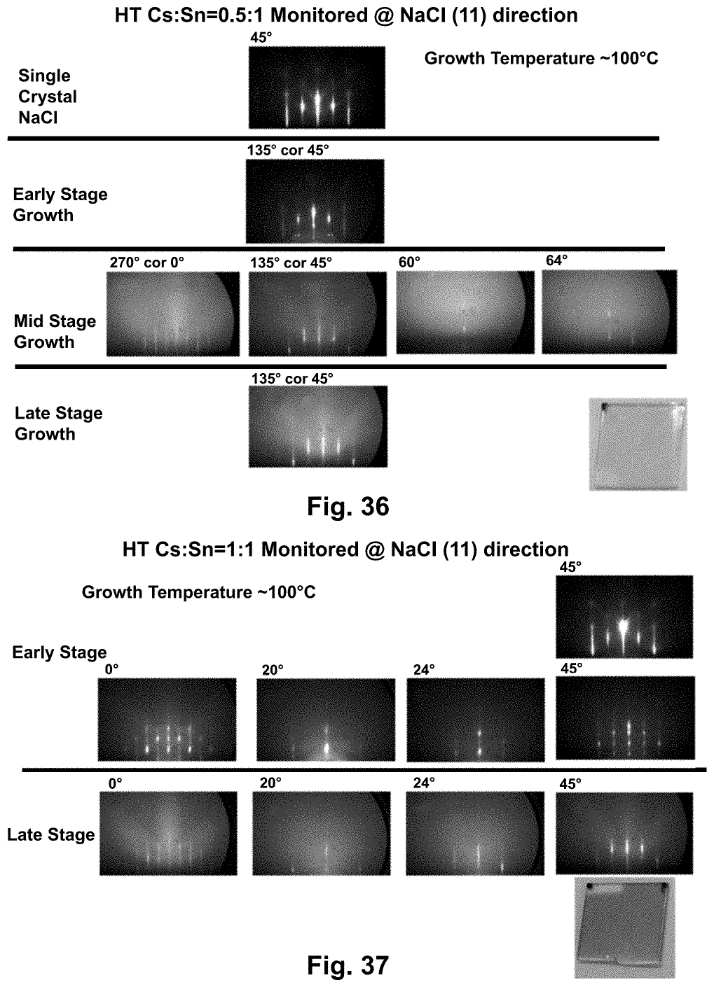

Growth temperature is another factor that can largely affect the quality of an epitaxial film. Growth at various temperatures was studied, which shows that at higher temperature, the epitaxial film can also be obtained. FIG. 34 shows that a polycrystalline film was obtained at about 75° C. with CsBr:SnBr₂=0.5:1. FIG. 35 shows that a polycrystalline film was obtained at about 75° C. with CsBr:SnBr₂=1:1. FIG. 36 shows that a highly ordered epitaxial film was obtained at about 100° C. with CsBr:SnBr₂=0.5:1. FIG. 37 shows that a highly ordered epitaxial film was obtained at about 100° C. with CsBr:SnBr₂=1:1. However, a benefit of metal halide salt substrates is the ability they provide to form single domain epitaxial layers of halide perovskites at room temperature.

### Example 3

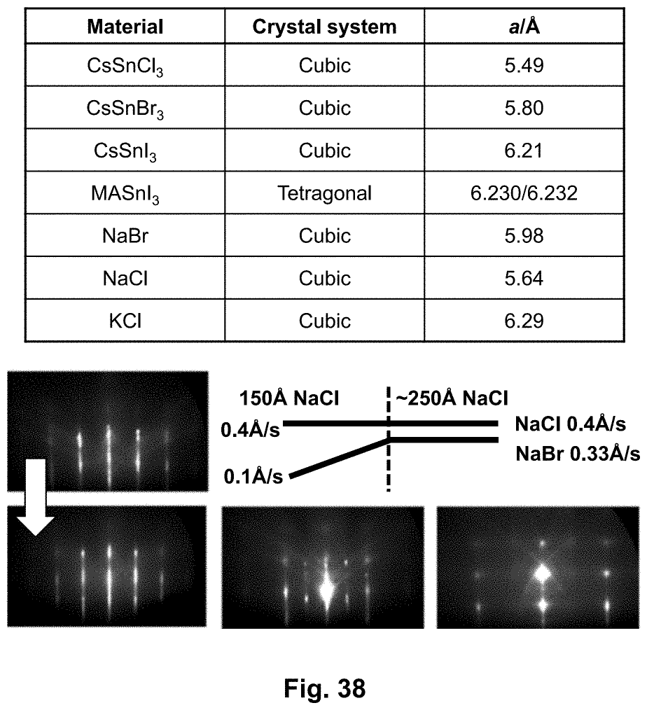

Lattice tuning is performed by epitaxial growth of alloyed salt layers prepared by co-deposition of different salt sources based on the principle of Vegard's rule. Such behavior is seen FIG. 38, where the RHEED streak patterns indicate that the lattice constant is linearly modulated in an epitaxial layer when NaBr is alloyed with NaCl. With appropriate deposition conditions and gradients of NaCl/NaBr through film thickness, this approach prevents unwanted island formation, allows precise strain engineering (tensile and compressive), allows pseudomorphic heteroepitaxial growth with controlled levels of defect/dislocation density, and leads to flat surfaces for perovskite film epitaxy. FIG. 38 also includes a summary of lattice constants of exemplary halide perovskites and single crystal substrates on which they were deposited.

### Example 4

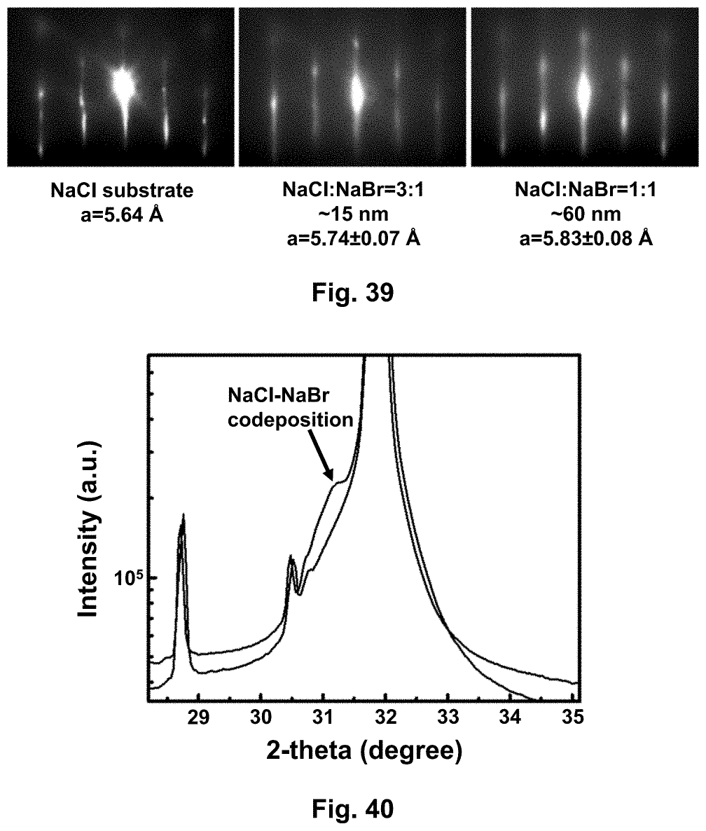

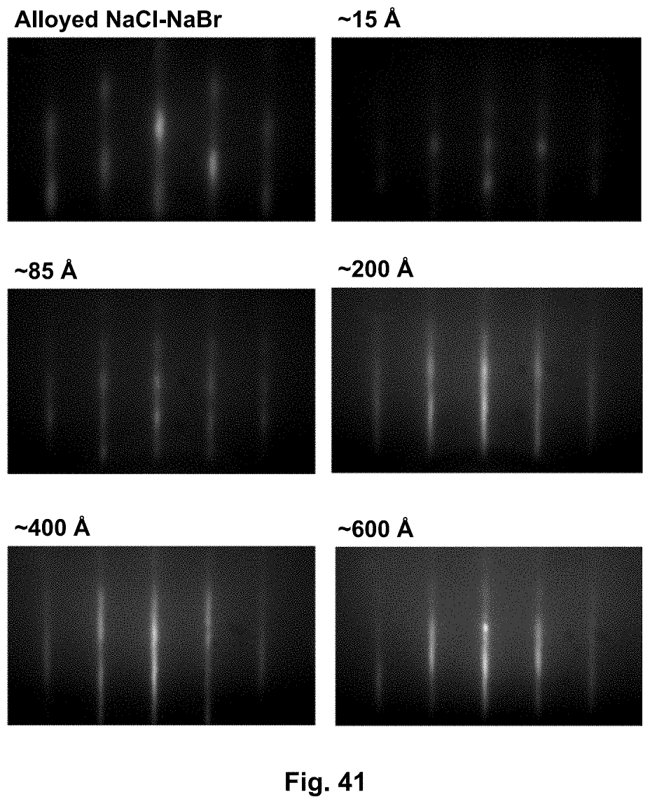

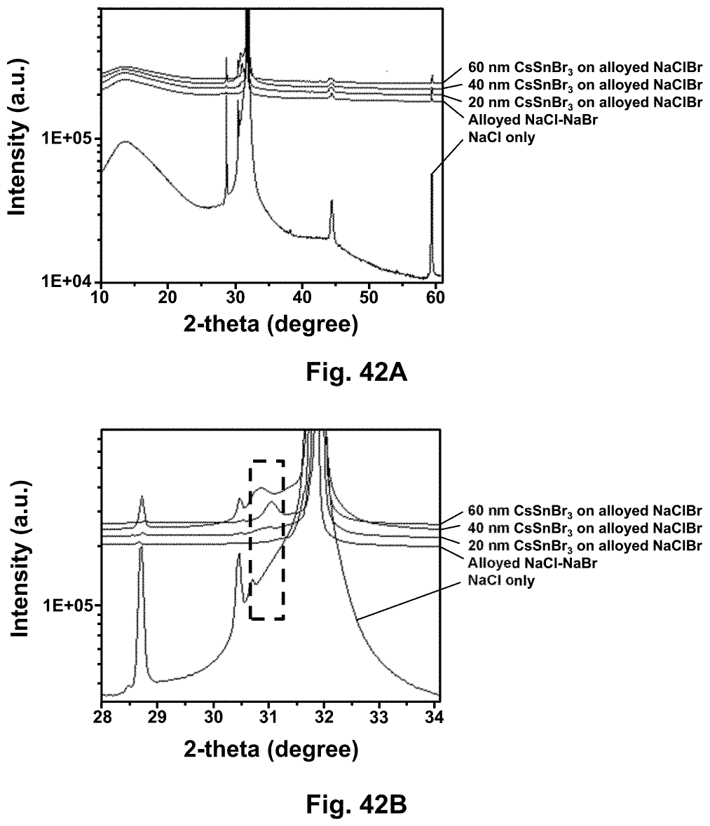

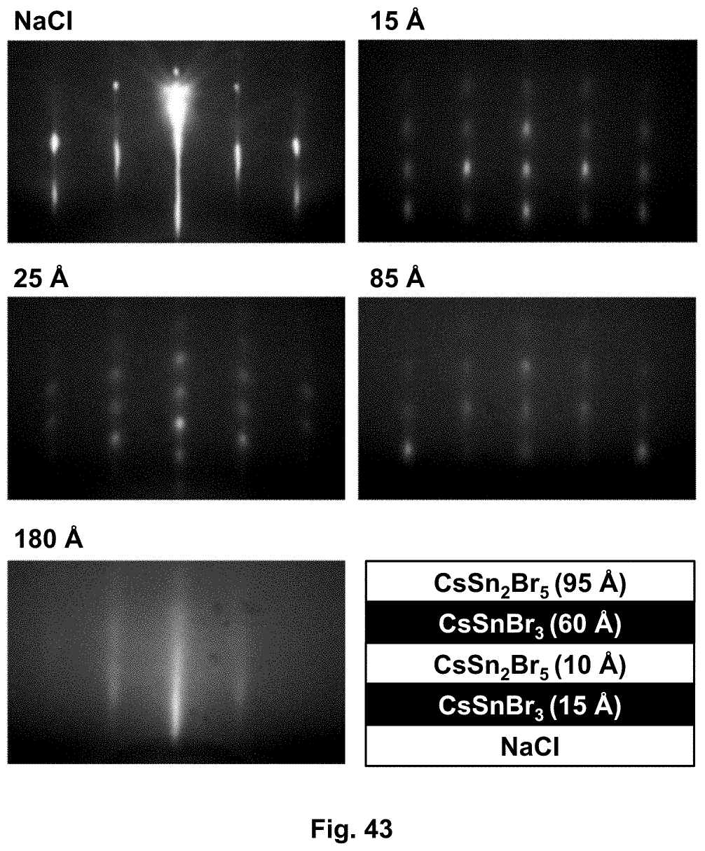

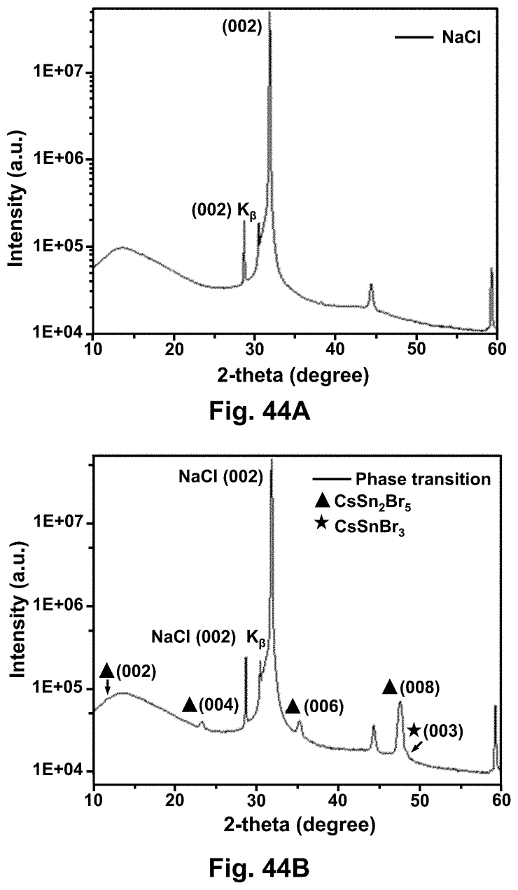

Alloyed NaCl—NaBr was epitaxially grown on NaCl to improve lattice matching and reduce dislocation density. FIG. 39 shows RHEED patterns of the NaC substrate (lattice constant of 5.64 Å), of a NaCl:NaBr 3:1 alloy (lattice constant of 5.74 Å), and of a NaCl:NaBr 1:1 alloy (lattice constant of 5.83 Å). FIG. 40 shows an XRD pattern for the NaCl—NaBr codeposition. CsSnBr₃ was then grown on alloyed NaCl—NaBr. FIG. 41 shows RHEED patterns of the epitaxially grown CsSnBr₃. XRD patterns were then recorded for a NaCl substrate, alloyed NaCl—NaBr, and 20 nm, 40 nm, and 60 nm CsSnBr₃ grown epitaxially on alloyed NaClBr. XRD patterns are shown in FIGS. 42A and 42B. FIG. 43 shows controllable phase transition via stoichiometry of CsBr:SnBr₂ from NaCl substrate, cubic CsSnBr₃, tetragonal CsSn₂Br₅, cubic CsSnBr₃, and tetragonal CsSn₂Br₅. The inset at the right bottom shows the architecture of a sample. FIG. 44A shows an XRD pattern of bare NaC substrate before phase-controlled growth and FIG. 44B shows an XRD pattern of a sample after phase-controlled growth as monitored by the RHEED shown in FIG. 43.

### Example 5

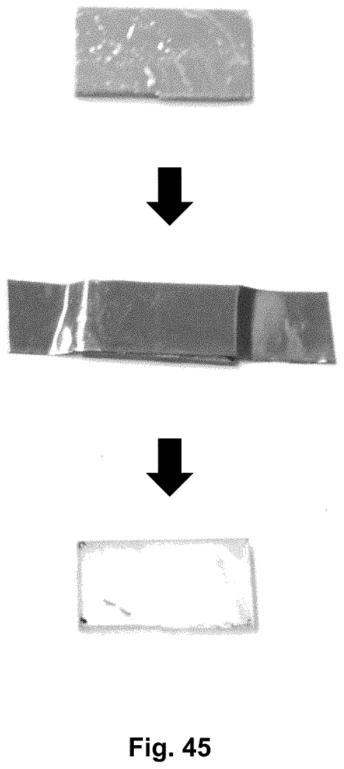

A sample comprises a CsSnBr₃ film epitaxially grown on a single crystal substrate. Tape (which may be conductive or non-conductive, transparent or non-transparent, polymer or metal) was adhered to the CsSnBr₃ film (which may or may not include a gold layer on top). The sample was immersed into liquid nitrogen for from about 5 seconds to about 30 seconds. The sample was removed from the liquid nitrogen and immediately immersed in diethyl ether (which could have been any other solvent that does not dissolve or destroy the sample at low boiling temperature). Diethyl ether was used to prevent the sample from adsorbing water when it is removed from the liquid nitrogen and subsequently slowly warms toward ambient temperature. The sample was removed from the diethyl ether and the tape was tapped onto the surface of the sample. The tape was then slowly peeled away. Photographs of the process are shown in FIG. 45.

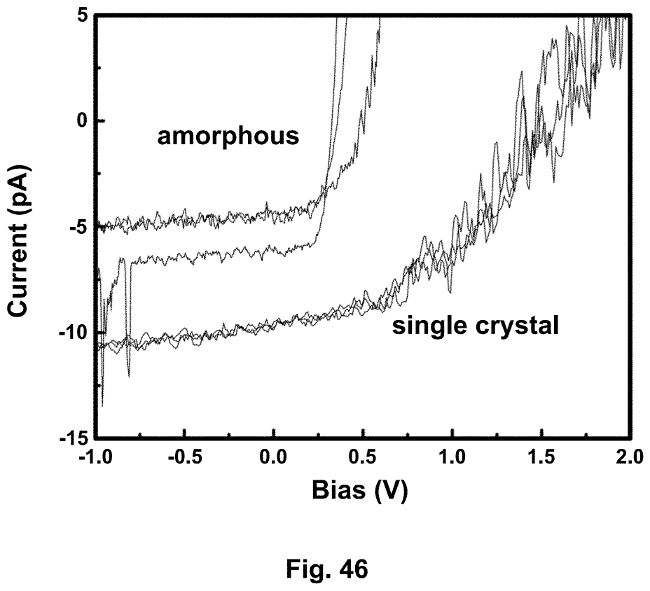

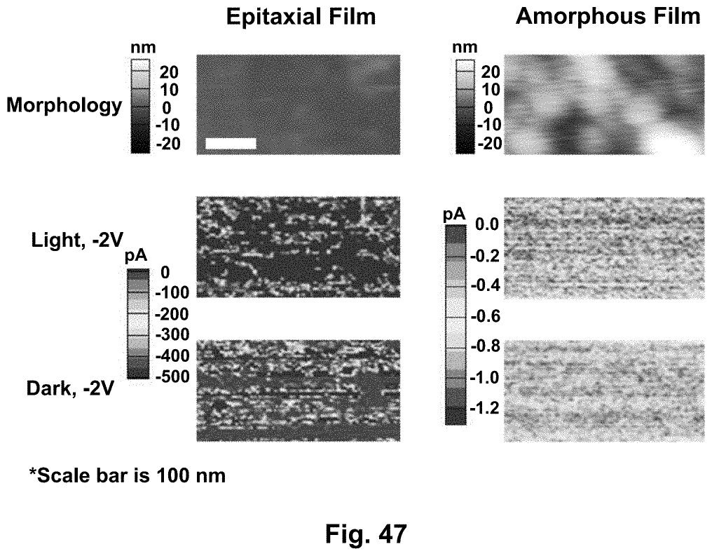

A photovoltaic (PV) device was fabricated by transferring the CsSnBr₃ crystalline film to coper tape. The procedure was: 1) depositing a layer of gold to make good contact and provide mechanical support during film transferring; 2) immersing the epitaxial film grown on the substrate (the “sample”) into liquid nitrogen for 5-30 s and then immersing the sample into diethyl ether or any other solvent which cannot dissolve or destroy the sample with low boiling temperature (to prevent the sample adsorbing water when it is taken out from the liquid nitrogen); 3) removing the sample from the solvent after it is warm and pressing tape onto the surface of the sample with or without gold layer on the top and where the tape is conductive or non-conductive, transparent or non-transparent, polymer or metal; and 4) slowly peeling the tape. After transferring, the CsSnBr₃ film was on the top and then the sample was coated with C₆₀ and bathocuproine (BCP). The measurement was done via conductive probe AFM and results are shown in FIG. 46 and FIG. 47.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

The invention claimed is:

1. A method of fabricating a semiconductor structure, the method comprising:
evaporating at least one precursor; and
depositing an epitaxial film comprising a halide perovskite derived from the at least one precursor on a single crystal substrate.

2. The method according to claim 1, wherein the evaporating and the depositing are performed by vapor deposition selected from the group consisting of molecular beam epitaxy, atomic layer deposition, thermal evaporation, evaporating, sputtering, pulsed laser deposition, electron beam evaporation, chemical vapor deposition, cathodic arc deposition, and electrohydrodynamic deposition.

3. The method according to claim 1, wherein the at least one precursor comprises a first precursor corresponding to the formula AX, A′X, A′X₂, or a combination thereof, and a second precursor corresponding to the formula BX₂, B′X₄, CX₃, DX, or a combination thereof, and the method further comprises:
reacting the first precursor with the second precursor to form the halide perovskite, the halide perovskite corresponding to the formula AₘBₙXₘ₊₂ₙ, A_{m′}B′_{n′}X_{m′+4n′}, A_{m″}B_{n″}B′_{n″*}X_{m″+2n″+4n″*}, AₘCₙXₘ₊₃ₙ, AₘCₙDₗXₘ₊₃ₙ₊ₗ, (A′X)ₘBₙXₘ₊₂ₙ, (A′X)_{m′}B′_{n′}X_{m′+4n′}, (A′X)_{m″}B_{n″}B′_{n″*}X_{m″+2n″+4n″*}, (A′X)ₘCₙXₘ₊₃ₙ, (A′X)ₘCₙDₗXₘ₊₃ₙ₊ₗ, or a combination thereof,
wherein:
A is a 1+alkali metal, a 1+transition metal, a 1+lanthanide, a 1+actinide, a 1+organic cation, or a 1+compound having the formula A′X, wherein A′ is an alkaline earth metal, a 2+transition metal, a 2+lanthanide, a 2+actinide, or a combination thereof;
B is a 2+alkaline earth metal, a 2+transition metal, a 2+crystallogen, a 2+lanthanide, a 2+actinide, or a combination thereof;
B′ is a 4+metal or a combination of 4+metals;
C is a 3+pnictogen, a 3+icosagen, a 3+transition metal, or a combination thereof;
D is silver (Ag), copper (Cu), gold (Au), indium (In I), thallium (Tl I), or a combination thereof
X is an inorganic anion, an organic anion, or a combination thereof; and
m, m′, m″, n, n′, n″, n″*, and l are individually integers having a value of 0 or greater.

4. The method according to claim 3, wherein:
A is cesium (Cs), rubidium (Rb), potassium (K), sodium (Na), lithium (Li), copper (Cu I), methylammonium (MA), formamidinium (FA), organic cation, or a combination thereof;
A′ is beryllium (Be), magnesium (Mg), calcium (Ca), strontium (Sr), barium (Ba), iron (Fe II), chromium (Cr II), cobalt (Co II), nickel (Ni II), manganese (Mn II), lead (Pb II), copper (Cu II), vanadium (V II), zinc (Zn II) or a combination thereof;
B is tin (Sn), lead (Pb), copper (Cu II), germanium (Ge), or a combination thereof;
B′ is tin (Sn), germanium (Ge), lead (Pb), or a combination thereof;
C is bismuth (Bi), antimony (Sb), indium (In Ill), iron (Fe), aluminum (Al), or a combination thereof; and
X is an inorganic anion selected from the group consisting of a halogen, an oxalate, a hydroxide, a chlorate, an iodate, a nitrite, a sulfate, a thiosulfate, a phosphate, an antimonite, or a combination thereof, or an organic anion selected from the group consisting of acetate, formate, borate, carborane, phenyl borate, and combinations thereof, or a combination of inorganic anions and organic ions.

5. The method according to claim 3, wherein the halide perovskite is CsSiCl₃, CsSiBr₃, CsSiI₃, RbSiCl₃, RbSiBr₃, KSiCl₃, KSiBr₃, KSiI₃, MASiCl₃, MASiBr₃, MASiI₃, Cs₂SiCl₄, Cs₂SiBr₄, Cs₂SiI₄, MA₂SiCl₄, MA₂SiBr₄, MA₂SiI₄, Rb₂SiCl₄, Rb₂SiBr₄, Rb₂SiI₄, CsSiI₂Cl₅, Cs₂SiCl₆, Cs₂Si(II)Si(IV)Cl₈, CsSiI₂Br₅, Cs₂SiBr₆, Cs₂Si(II)Si(IV)Br₈, CsSiI₂I₅, Cs₂SiI₆, Cs₂Si(II)Si(IV)I₈, RbSi₂Cl₅, Rb₂SiCl₆, Rb₂Si(II)Si(IV)Cl₈, RbSi₂Br₅, Rb₂SiBr₆, Rb₂Si(II)Si(IV)Br₈, RbSi₂I₅, Rb₂SiI₆, Rb₂Si(II)Si(IV)I₈, KSi₂Cl₅, K₂SiCl₆, K₂Si(II)Si(IV)Cl₈, KSi₂Br₅, K₂SiBr₆, K₂Si(II)Si(IV)Br₈, KSi₂I₅, K₂SiI₆, K₂Si(II)Si(IV)I₈, MASi₂Cl₅, MA₂SiCl₆, MA₂Si(II)Si(IV)Cl₈, MASi₂Br₅, MA₂SiBr₆, MA₂Si(II)Si(IV)Br₈, MASi₂I₅, MA₂SiI₆, MA₂Si(II)Si(IV)Cl₈; CsGeCl₃, CsGeBr₃, CsGeI₃, RbGeCl₃, RbGeBr₃, KGeCl₃, KGeBr₃, KGeI₃, MAGeCl₃, MAGeBr₃, MAGeI₃, Cs₂GeCl₄, Cs₂GeBr₄, Cs₂GeI₄, MA₂GeCl₄, MA₂GeBr₄, MA₂GeI₄, Rb₂GeCl₄, Rb₂GeBr₄, Rb₂GeI₄, CsGe₂Cl₅, Cs₂GeCl₆, Cs₂Ge(II)Ge(IV)Cl₈, CsGe₂Br₅, Cs₂GeBr₆, Cs₂Ge(II)Ge(IV)Br₈, CsGe₂I₅, Cs₂GeI₆, Cs₂Ge(II)Ge(IV)I₈, RbGe₂Cl₅, Rb₂GeCl₆, Rb₂Ge(II)Ge(IV)Cl₈, RbGe₂Br₅, Rb₂GeBr₆, Rb₂Ge(II)Ge(IV)Br₈, RbGe₂I₅, Rb₂GeI₆, Rb₂Ge(II)Ge(IV)I₈, KGe₂Cl₅, K₂GeCl₆, K₂Ge(II)Ge(IV)Cl₈, KGe₂Br₅, K₂GeBr₆, K₂Ge(II)Ge(IV)Br₈, KGe₂I₅, K₂GeI₆, K₂Ge(II)Ge(IV)I₈, MAGe₂Cl₅, MA₂GeCl₆, MA₂Ge(II)Ge(IV)Cl₈, MAGe₂Br₅, MA₂GeBr₆, MA₂Ge(II)Ge(IV)Br₈, MAGe₂I₅, MA₂GeI₆, MA₂Ge(II)Ge(IV)I₈; CsSnCl₃, CsSnBr₃, CsSnI₃, RbSnCl₃, RbSnBr₃, KSnCl₃, KSnBr₃, KSn₃, MASnCl₃, MASnBr₃, MASn₃, Cs₂SnCl₄, Cs₂SnBr₄, Cs₂SnI₄, MA₂SnCl₄, MA₂SnBr₄, MA₂SnI₄, Rb₂SnCl₄, Rb₂SnBr₄, Rb₂SnI₄, CsSn₂Cl₅, Cs₂SnCl₆, Cs₂Sn(II)Sn(IV)Cl₈, CsSn₂Br₅, Cs₂SnBr₆, Cs₂Sn(II)Sn(IV)Br₈, CsSn₂I₅, Cs₂SnI₆, Cs₂Sn(II)Sn(IV)I₈, RbSn₂Cl₅, Rb₂SnCl₆, Rb₂Sn(II)Sn(IV)Cl₈, RbSn₂Br₅, Rb₂SnBr₆, Rb₂Sn(II)Sn(IV)Br₈, RbSn₂I₅, Rb₂SnI₆, Rb₂Sn(II)Sn(IV)I₈, KSn₂Cl₅, K₂SnCl₆, K₂Sn(II)Sn(IV)Cl₈, KSn₂Br₅, K₂SnBr₆, K₂Sn(II)Sn(IV)Br₈, KSn₂I₅, K₂SnI₆, K₂Sn(II)Sn(IV)I₈, MASn₂Cl₅, MA₂SnCl₆, MA₂Sn(II)Sn(IV)Cl₈, MASn₂Br₅, MA₂SnBr₆, MA₂Sn(II)Sn(IV)Br₈, MASn₂I₅, MA₂SnI₆, MA₂Sn(II)Sn(IV)I₈, Cs₃Bi₂Cl₉, Cs₃Bi₂Br₉, Cs₃Bi₂I₉, Cs₃Sb₂Cl₉, Cs₃Sb₂Br₉, Cs₃Sb₂I₉; CsPbCl₃, CsPbBr₃, CsPbI₃, RbPbCl₃, RbPbBr₃, KPbCl₃, KPbBr₃, KPbI₃, MAPbCl₃, MAPbBr₃, MAPbI₃, Cs₂PbCl₄, Cs₂PbBr₄, Cs₂PbI₄, MA₂PbCl₄, MA₂PbBr₄, MA₂PbI₄, Rb₂PbCl₄, Rb₂PbBr₄, Rb₂PbI₄, CsPb₂Cl₅, Cs₂PbCl₆, Cs₂Pb(II)Pb(IV)Cl₈, CsPb₂Br₅, Cs₂PbBr₆, Cs₂Pb(II)Pb(IV)Br₈, CsPb₂I₅, Cs₂PbI₆, Cs₂Pb(II)Pb(IV)I₈, RbPb₂Cl₅, Rb₂PbCl₆, Rb₂Pb(II)Pb(IV)Cl₈, RbPb₂Br₅, Rb₂PbBr₆, Rb₂Pb(II)Pb(IV)Br₈, RbPb₂I₅, Rb₂PbI₆, Rb₂Pb(II)Pb(IV)I₈, KPb₂Cl₅, K₂PbCl₆, K₂Pb(II)Pb(IV)Cl₈, KPb₂Br₅, K₂PbBr₆, K₂Pb(II)Pb(IV)Br₈, KPb₂I₅, K₂PbI₆, K₂Pb(II)Pb(IV)I₈, MAPb₂Cl₅, MA₂PbCl₆, MA₂Pb(II)Pb(IV)Cl₈, MAPb₂Br₅, MA₂PbBr₆, MA₂Pb(II)Pb(IV)Br₈, MAPb₂I₅, MA₂PbI₆, MA₂Pb(II)Pb(IV)I₈; Cs₂AgBiCl₆, Cs₂CuBiCl₆, Cs₂InAgCl₆, Cs₂InCuCl₆, Cs₂AgSbCl₆, Cs₂CuSbCl₆, Cs₂AgBiBr₆, Cs₂CuBiBr₆, Cs₂InAgBr₆, Cs₂InCuBr₆, Cs₂AgBiI₆, Cs₂CuBiI₆, Cs₂AgSbBr₆, Cs₂CuSbBr₆, Cs₂AgSbI₆, Cs₂CuSbI₆, Cs₂InAgI₆, CS₂InCuI₆, Cs₃Bi₂Cl₉, Cs₃Bi₂Br₉, Cs₃Bi₂I₉, Cs₃Sb₂Cl₉, Cs₃Sb₂Br₉, Cs₃Sb₂I₉, Cs₃In₂Cl₉, Cs₃In₂Br₉, Cs₃In₂I₉; K₂AgBiCl₆, K₂CuBiCl₆, K₂InAgCl₆, K₂InCuCl₆, K₂AgSbCl₆, K₂CuSbCl₆, K₂AgBiBr₆, K₂CuBiBr₆, K₂InAgBr₆, K₂InCuBr₆, K₂AgBiI₆, K₂CuBiI₆, K₂AgSbBr₆, K₂CuSbBr₆, K₂AgSbI₆, K₂CuSbI₆, K₂InAgI₆, K₂InCuI₆, K₃Bi₂Cl₉, K₃Bi₂Br₉, K₃Bi₂I₉, K₃Sb₂Cl₉, K₃Sb₂Br₉, K₃Sb₂I₉, K₃In₂Cl₉, K₃In₂Br₉, K₃In₂I₉; Na₂AgBiCl₆, Na₂CuBiCl₆, Na₂InAgCl₆, Na₂InCuCl₆, Na₂AgSbCl₆, Na₂CuSbCl₆, Na₂AgBiBr₆, Na₂CuBiBr₆, Na₂InAgBr₆, Na₂InCuBr₆, Na₂AgBiI₆, Na₂CuBiI₆, Na₂AgSbBr₆, Na₂CuSbBr₆, Na₂AgSbI₆, Na₂CuSbI₆, Na₂InAgI₆, Na₂InCuI₆, Na₃Bi₂Cl₉, Na₃Bi₂Br₉, Na₃Bi₂I₉, Na₃Sb₂Cl₉, Na₃Sb₂Br₉, Na₃Sb₂I₉, Na₃In₂Cl₉, Na₃In₂Br₉, Na₃In₂I₉; Li₂AgBiCl₆, Li₂CuBiCl₆, Li₂InAgCl₆, Li₂InCuCl₆, Li₂AgSbCl₆, Li₂CuSbCl₆, Li₂AgBiBr₆, Li₂CuBiBr₆, Li₂InAgBr₆, Li₂InCuBr₆, Li₂AgBiI₆, Li₂CuBiI₆, Li₂AgSbBr₆, Li₂CuSbBr₆, Li₂AgSbI₆, Li₂CuSbI₆, Li₂InAgI₆, Li₂InCuI₆, Li₃Bi₂Cl₉, Li₃Bi₂Br₉, Li₃Bi₂I₉, Li₃Sb₂Cl₉, Li₃Sb₂Br₉, Li₃Sb₂I₉, Li₃In₂Cl₉, Li₃In₂Br₉, Li₃In₂I₉, (BaF)₂PbCl₄, (BaF)₂PbBr₄, (BaF)₂PbI₄, (BaF)₂SnCl₄, (BaF)₂SnBr₄, (BaF)₂SnI₄, and (BaF)₂PbCl₆, (BaF)₂PbBr₆, (BaF)₂PbI₆, (BaF)₂SnCl₆, (BaF)₂SnBr₆, (BaF)₂SnI₆, or a combination thereof.

6. The method according to claim 1, wherein the at least one precursor comprises the halide perovskite, and the evaporating and depositing are performed by evaporating or sputtering of a target comprising the halide perovskite.

7. The method according to claim 1, wherein there is a lattice misfit of less than or equal to about 10% between the single crystal substrate and the halide perovskite of the film.

8. The method according to claim 1, wherein the at least one precursor comprises a dopant.

9. The method according to claim 1, wherein the single crystal substrate comprises a halide salt, a halide perovskite, an oxide perovskite, a metal, or a semiconductor.

10. The method according to claim 1, wherein single crystal substrate comprises ionic crystals.

11. The method according to claim 1, wherein the single crystal substrate comprises a halide salt selected from the group consisting of a metal halide salt, an alkali metal halide salt, an alkaline earth metal halide salt, a transition metal halide salt, and combinations thereof.

12. The method according to claim 1, wherein the single crystal substrate comprises a halide perovskite selected from the group consisting of CsSiCl₃, CsSiBr₃, CsSiI₃, RbSiCl₃, RbSiBr₃, KSiCl₃, KSiBr₃, KSiI₃, MASiCl₃, MASiBr₃, MASiI₃, Cs₂SiCl₄, Cs₂SiBr₄, Cs₂SiI₄, MA₂SiCl₄, MA₂SiBr₄, MA₂SiI₄, Rb₂SiCl₄, Rb₂SiBr₄, Rb₂SiI₄, Cs₂Si₂Cl₅, Cs₂SiCl₆, Cs₂Si(II)Si(IV)Cl₈, CsSiI₂Br₅, Cs₂SiBr₆, Cs₂Si(II)Si(IV)Br₈, CsSi₂I₅, Cs₂SiI₆, Cs₂Si(II)Si(IV)I₈, RbSi₂Cl₅, Rb₂SiCl₆, Rb₂Si(II)Si(IV)Cl₈, RbSi₂Br₅, Rb₂SiBr₆, Rb₂Si(II)Si(IV)Br₈, RbSi₂I₅, Rb₂SiI₆, Rb₂Si(II)Si(IV)I₈, KSi₂Cl₅, K₂SiCl₆, K₂Si(II)Si(IV)Cl₈, KSi₂Br₅, K₂SiBr₆, K₂Si(II)Si(IV)Br₈, KSi₂I₅, K₂SiI₆, K₂Si(II)Si(IV)I₈, MASi₂Cl₅, MA₂SiCl₆, MA₂Si(II)Si(IV)Cl₈, MASi₂Br₅, MA₂SiBr₆, MA₂Si(II)Si(IV)Br₈, MASi₂I₅, MA₂SiI₆, MA₂Si(II)Si(IV)I₈; CsGeCl₃, CsGeBr₃, CsGeI₃, RbGeCl₃, RbGeBr₃, KGeCl₃, KGeBr₃, KGeI₃, MAGeCl₃, MAGeBr₃, MAGeI₃, Cs₂GeCl₄, Cs₂GeBr₄, Cs₂GeI₄, MA₂GeCl₄, MA₂GeBr₄, MA₂GeI₄, Rb₂GeCl₄, Rb₂GeBr₄, Rb₂GeI₄, CsGe₂Cl₅, Cs₂GeCl₆, Cs₂Ge(II)Ge(IV)Cl₈, CsGe₂Br₅, Cs₂GeBr₆, Cs₂Ge(II)Ge(IV)Br₈, CsGe₂I₅, Cs₂GeI₆, Cs₂Ge(II)Ge(IV)I₈, RbGe₂Cl₅, Rb₂GeCl₆, Rb₂Ge(II)Ge(IV)Cl₈, RbGe₂Br₅, Rb₂GeBr₆, Rb₂Ge(II)Ge(IV)Br₈, RbGe₂I₅, Rb₂GeI₆, Rb₂Ge(II)Ge(IV)I₈, KGe₂Cl₅, K₂GeCl₆, K₂Ge(II)Ge(IV)Cl₈, KGe₂Br₅, K₂GeBr₆, K₂Ge(II)Ge(IV)Br₈, KGe₂I₅, K₂GeI₆, K₂Ge(II)Ge(IV)I₈, MAGe₂Cl₅, MA₂GeCl₆, MA₂Ge(II)Ge(IV)Cl₈, MAGe₂Br₅, MA₂GeBr₆, MA₂Ge(II)Ge(IV)Br₈, MAGe₂I₅, MA₂GeI₆, MA₂Ge(II)Ge(IV)I₈; CsSnCl₃, CsSnBr₃, CsSnI₃, RbSnCl₃, RbSnBr₃, KSnCl₃, KSnBr₃, KSn₃, MASnCl₃, MASnBr₃, MASn₃, Cs₂SnCl₄, Cs₂SnBr₄, Cs₂SnI₄, MA₂SnCl₄, MA₂SnBr₄, MA₂SnI₄, Rb₂SnCl₄, Rb₂SnBr₄, Rb₂SnI₄, CsSn₂Cl₅, Cs₂SnCl₆, Cs₂Sn(II)Sn(IV)Cl₈, CsSn₂Br₅, Cs₂SnBr₆, Cs₂Sn(II)Sn(IV)Br₈, CsSn₂I₅, Cs₂SnI₆, Cs₂Sn(II)Sn(IV)I₈, RbSn₂Cl₅, Rb₂SnCl₆, Rb₂Sn(II)Sn(IV)Cl₈, RbSn₂Br₅, Rb₂SnBr₆, Rb₂Sn(II)Sn(IV)Br₈, RbSn₂I₅, Rb₂SnI₆, Rb₂Sn(II)Sn(IV)I₈, KSn₂Cl₅, K₂SnCl₆, K₂Sn(II)Sn(IV)Cl₈, KSn₂Br₅, K₂SnBr₆, K₂Sn(II)Sn(IV)Br₈, KSn₂I₅, K₂SnI₆, K₂Sn(II)Sn(IV)I₈, MASn₂Cl₅, MA₂SnCl₆, MA₂Sn(II)Sn(IV)Cl₈, MASn₂Br₅, MA₂SnBr₆, MA₂Sn(II)Sn(IV)Br₈, MASn₂I₅, MA₂SnI₆, MA₂Sn(II)Sn(IV)I₈, Cs₃Bi₂Cl₉, Cs₃Bi₂Br₉, Cs₃Bi₂I₉, Cs₃Sb₂Cl₉, Cs₃Sb₂Br₉, Cs₃Sb₂I₉; CsPbCl₃, CsPbBr₃, CsPbI₃, RbPbCl₃, RbPbBr₃, KPbCl₃, KPbBr₃, KPbI₃, MAPbCl₃, MAPbBr₃, MAPbI₃, Cs₂PbCl₄, Cs₂PbBr₄, Cs₂PbI₄, MA₂PbCl₄, MA₂PbBr₄, MA₂PbI₄, Rb₂PbCl₄, Rb₂PbBr₄, Rb₂PbI₄, CsPb₂Cl₅, Cs₂PbCl₆, Cs₂Pb(II)Pb(IV)Cl₈, CsPb₂Br₅, Cs₂PbBr₆, Cs₂Pb(II)Pb(IV)Br₈, CsPb₂I₅, Cs₂PbI₆, Cs₂Pb(II)Pb(IV)I₈, RbPb₂Cl₅, Rb₂PbCl₆, Rb₂Pb(II)Pb(IV)Cl₈, RbPb₂Br₅, Rb₂PbBr₆, Rb₂Pb(II)Pb(IV)Br₈, RbPb₂I₅, Rb₂PbI₆, Rb₂Pb(II)Pb(IV)I₈, KPb₂Cl₅, K₂PbCl₆, K₂Pb(II)Pb(IV)Cl₈, KPb₂Br₅, K₂PbBr₆, K₂Pb(II)Pb(IV)Br₈, KPb₂I₅, K₂PbI₆, K₂Pb(II)Pb(IV)I₈, MAPb₂Cl₅, MA₂PbCl₆, MA₂Pb(II)Pb(IV)Cl₈, MAPb₂Br₅, MA₂PbBr₆, MA₂Pb(II)Pb(IV)Br₈, MAPb₂I₅, MA₂PbI₆, MA₂Pb(II)Pb(IV)I₈; Cs₂AgBiCl₆, Cs₂CuBiCl₆, Cs₂InAgCl₆, Cs₂InCuCl₆, Cs₂AgSbCl₆, Cs₂CuSbCl₆, Cs₂AgBiBr₆, Cs₂CuBiBr₆, Cs₂InAgBr₆, Cs₂InCuBr₆, Cs₂AgBiI₆, Cs₂CuBiI₆, Cs₂AgSbBr₆, Cs₂CuSbBr₆, Cs₂AgSbI₆, Cs₂CuSbI₆, Cs₂InAgI₆, CS₂InCuI₆, Cs₃Bi₂Cl₉, Cs₃Bi₂Br, Cs₃Bi₂I₉, Cs₃Sb₂Cl₉, Cs₃Sb₂Br, Cs₃Sb₂I₉, Cs₃In₂Cl₉, Cs₃In₂Br₉, Cs₃In₂I₉; K₂AgBiCl₆, K₂CuBiCl₆, K₂InAgCl₆, K₂InCuCl₆, K₂AgSbCl₆, K₂CuSbCl₆, K₂AgBiBr₆, K₂CuBiBr₆, K₂InAgBr₆, K₂InCuBr₆, K₂AgBiI₆, K₂CuBiI₆, K₂AgSbBr₆, K₂CuSbBr₆, K₂AgSbI₆, K₂CuSbI₆, K₂InAgI₆, K₂InCuI₆, K₃Bi₂Cl₉, K₃Bi₂Br₉, K₃Bi₂I₉, K₃Sb₂Cl₉, K₃Sb₂Br₉, K₃Sb₂I₉, K₃In₂Cl₉, K₃In₂Br₉, K₃In₂I₉; Na₂AgBiCl₆, Na₂CuBiCl₆, Na₂InAgCl₆, Na₂InCuCl₆, Na₂AgSbCl₆, Na₂CuSbCl₆, Na₂AgBiBr₆, Na₂CuBiBr₆, Na₂InAgBr₆, Na₂InCuBr₆, Na₂AgBiI₆, Na₂CuBiI₆, Na₂AgSbBr₆, Na₂CuSbBr₆, Na₂AgSbI₆, Na₂CuSbI₆, Na₂InAgI₆, Na₂InCuI₆, Na₃Bi₂Cl₉, Na₃Bi₂Br₉, Na₃Bi₂I₉, Na₃Sb₂Cl₉, Na₃Sb₂Br₉, Na₃Sb₂I₉, Na₃In₂Cl₉, Na₃In₂Br₉, Na₃In₂I₉; Li₂AgBiCl₆, Li₂CuBiCl₆, Li₂InAgCl₆, Li₂InCuCl₆, Li₂AgSbCl₆, Li₂CuSbCl₆, Li₂AgBiBr₆, Li₂CuBiBr₆, Li₂InAgBr₆, Li₂InCuBr₆, Li₂AgBiI₆, Li₂CuBiI₆, Li₂AgSbBr₆, Li₂CuSbBr₆, Li₂AgSbI₆, Li₂CuSbI₆, Li₂InAgI₆, Li₂InCuI₆, Li₃Bi₂Cl₉, Li₃Bi₂Br₉, Li₃Bi₂I₉, Li₃Sb₂Cl₉, Li₃Sb₂Br₉, Li₃Sb₂I₉, Li₃In₂Cl₉, Li₃In₂Br₉, Li₃In₂I₉, and combinations thereof.

13. The method according to claim 1, wherein the single crystal substrate comprises an oxide perovskite selected from the group consisting of SrTiO₃, LiNbO₃, LiTaO₃, CaTiO₃, BaTiO₃, MgTiO₃, PbTiO₃, EuTiO₃, CdTiO₃, MnTiO₃, FeTiO₃, ZnTiO₃, CoTiO₃, NiTiO₃, BaSnO₃, PbSnO₃, SrSnO₃, CaSnO₃, CdSnO₃, MnSnO₃, ZnSnO₃, CoSnO₃, NiSnO₃, MgSnO₃, BeSnO₃, PbHfO₃, SrHfO₃, CaHfO₃, BaZrO₃, PbZrO₃, SrZrO₃, CaZrO₃, CdZrO₃, MgZrO₃, MnZrO₃, CoZrO₃, NiZrO₃, TiZrO₃, BeZrO₃, BaCeO₃, PbCeO₃, SrCeO₃, CaCeO₃, CdCeO₃, MgCeO₃, MnCeO₃, CoCeO₃, NiCeO₃, BeCeO₃, BaUO₃, SrUO₃, CaUO₃, MgUO₃, BeUO3, BaVO₃, SrVO₃, CaVO₃, MgVO₃, BeVO₃, BaThO₃, LaAlO₃, CeAlO₃, NdAlO₃, SmAlO₃, BiAlO₃, YAlO₃, InAlO₃, FeAlO₃, CrAlO₃, GaAlO₃, LaGaO₃, CeGaO₃, NdGaO₃, SmGaO₃, YGaO₃, LaCrO₃, CeCrO₃, NdCrO₃, SmCrO₃, YCrO₃, FeCrO₃, LaFeO₃, CeFeO₃, NdFeO₃, SmFeO₃, GdFeO₃, YFeO₃, InFeO₃, LaScO₃, CeScO₃, NdScO₃, YScO₃, InScO₃, LaInO₃, NdInO₃, YInO₃, LaYO₃, LaSmO₃, and combinations thereof.

14. The method according to claim 1, wherein the single crystal substrate comprises a metal selected from the group consisting of gold (Au), silver (Ag), copper (Cu), platinum (Pt), tin (Sn), aluminum (Al), gallium (Ga), indium (In), thallium (Tl), antimony (Sb), bismuth (Bi), titanium (Ti), molybdenum (Mo), niobium (Nb), nickel (Ni), chromium (Cr), magnesium (Mg), and combinations thereof.

15. The method according to claim 1, wherein the single crystal substrate comprises a semiconductor selected from the group consisting of silicon (Si), germanium (Ge), indium phosphide (InP), indium antiminide (InSb), indium arsenide (InAs), cadmium telluride (CdTe), cadmium sulfide (CdS), cadmium selenide (CdSe), gallium arsenide (GaAs), aluminum arsenide (AlAs), aluminum antimonide (AlSb), lead sulfide (PbS), lead selenide (PbSe), lead telluride (PbTe), zinc sulfide (ZnS), zinc oxide (ZnO), indium oxide (In₂O₃), titanium oxide (TiO₂), tin oxide (SnO₂), and combinations thereof.

16. The method according to claim 1, further comprising:
disposing a buffer layer on the substrate prior to the depositing an halide perovskite on the substrate, wherein the buffer layer comprises a halide salt alloy.

17. The method according to claim 1, further comprising:
removing the film comprising a halide perovskite from the single crystal substrate by wet etching or epitaxial lift off.

18. The method according to claim 17, further comprising:
transferring the film comprising a halide perovskite to a device.

19. A method of fabricating a semiconductor structure, the method comprising:
evaporating a first precursor corresponding to the formula AX, A′X, A′X₂, or a combination thereof;
evaporating a second precursor corresponding to a formula BX₂, B′X₄, CX₃, DX, or a combination thereof;
reacting the evaporated first precursor with the evaporated second precursor to form a halide perovskite corresponding to the formula AₘBₙX₃₊₂ₙ, A_{m′}B′_{n′}X_{m′+4n′}, A_{m″}B_{n″}B′_{n″*}X_{m″+2n″+4n″*}, AₘCₙXₘ₊₃ₙ, AₘCₙDₗXₘ₊₃ₙ₊ₗ, (A′X)ₘBₙXₘ₊₂ₙ, (A′X)ₘB′_{n′}X_{m′+4n′}, (A′X)_{m″}B_{n″}B′_{n″*}X_{m″+2n″+4n″*}, (A′X)ₘCₙXₘ₊₃ₙ, (A′X)ₘCₙDₗXₘ₊₃ₙ₊ₗ, or a combination thereof;
and epitaxially growing a single domain film comprising the halide perovskite on a single crystal comprising a halide salt,
wherein
A is a 1+alkali metal, a 1+transition metal, a 1+lanthanide, a 1+actinide, a 1+organic cation, or a 1+compound having the formula A′X, wherein A′ is an alkaline earth metal, a 2+transition metal, a 2+lanthanide, a 2+actinide, or a combination thereof;
B is a 2+alkaline earth metal, a 2+transition metal, a 2+crystallogen, a 2+lanthanide, a 2+actinide, or a combination thereof;
B′ is a 4+metal or a combination of 4+metals;
C is a 3+pnictogen, a 3+icosagen, a 3+transition metal, or a combination thereof;
D is silver (Ag), copper (Cu), gold (Au), indium (In I), thallium (Tl I), or a combination thereof;
X is an inorganic anion, an organic anion, or a combination thereof; and
m, m′, m″, n, n′, n″, n″*, and l are individually integers having a value of 0 or greater.

20. The method according to claim 19, further comprising:
disposing a first lattice matched layer on the film comprising the halide perovskite to generate a quantum well with a type I heterojunction, a type II heterojunction, or a type III heterojunction.

21. The method according to claim 20, further comprising:
disposing at least one additional bilayer comprising a second film comprising a halide perovskite and a second lattice matched layer on the first lattice matched layer, such that a heterojunction is formed between the second film and the first lattice matched layer to generate a semiconductor structure comprising at least one quantum well.

22. The method according to claim 20, wherein the film comprising the halide perovskite has a thickness of a monolayer of the halide perovskite to less than or equal to about 3× the exciton Bohr radius of the halide perovskite.

23. A semiconductor structure made by the method according to claim 19.

24. A semiconductor structure comprising:
a single crystal substrate; and
a single-domain epitaxial film comprising a halide perovskite disposed on the single crystal substrate.

25. The semiconductor structure according to claim 24, wherein the structure has a lattice misfit of less than about 10% between the single crystal substrate and the film comprising a halide perovskite.

26. The semiconductor structure according to claim 24, wherein the structure has a lattice misfit of less than about 5% between the single crystal substrate and the film comprising a halide perovskite.

27. The semiconductor structure according to claim 24, wherein the single crystal substrate is a halide salt, a halide perovskite, an oxide perovskite, a metal, or a semiconductor.

28. The semiconductor structure according to claim 24, wherein the single crystal substrate is a halide salt selected from the group consisting of a metal halide salt, an alkali metal halide salt, an alkaline earth metal halide salt, a transition metal halide salt, and combinations thereof.

29. The semiconductor structure according to claim 24, wherein the halide perovskite corresponds to the formula AₘB′ₙXₘ₊₂ₙ, AₘB_{n′}X_{m′+4n′}, A_{m″}B_{n″}B′_{n″*}X_{m″+2n″+4n″*}, AₘCₙXₘ₊₃ₙ, AₘCₙDₗXₘ₊₃ₙ₊ₗ, (A′X)ₘBₙXₘ₊₂ₙ, (A′X)_{m′}B′_{n′}X_{m′+4n′}, (A′X)_{m″}B_{n″}B′_{n″*}X_{m″+2n″+4n″*}, (A′X)ₘCₙXₘ₊₃ₙ, (A′X)ₘCₙDₗXₘ₊₃ₙ₊ₗ, or a combination thereof, wherein:
A is a 1+alkali metal, a 1+transition metal, a 1+lanthanide, a 1+actinide, a 1+organic cation, or a 1+compound having he formula A′X, wherein A′ is an alkaline earth metal, a 2+transition metal, a 2+lanthanide, a 2+actinide, or a combination thereof;
A′ is an alkaline earth metal, a 2+transition metal, a 2+lanthanide, a 2+actinide, or a combination thereof;
B is a 2+alkaline earth metal, a 2+transition metal, a 2+crystallogen, a 2+lanthanide, a 2+actinide, or a combination thereof;
B′ is a 4+metal or a combination of 4+metals;
C is a 3+pnictogen, a 3+icosagen, a 3+transition metal, or a combination thereof;
D is silver (Ag), copper (Cu), gold (Au), indium (In I), thallium (Tl I), or a combination thereof;
X is an inorganic anion, an organic anion, or a combination thereof; and
m, m′, m″, n, n′, n″, n″*, and l are individually integers having a value of 0 or greater.

30. The semiconductor structure according to claim 24, wherein the single crystal substrate comprises an epitaxial buffer layer and the film comprising a halide perovskite is disposed on the epitaxial buffer layer.

31. The semiconductor structure according to claim 24, wherein the single crystal substrate comprises an epitaxial intermetallic layer and the film comprising a halide perovskite is disposed on the epitaxial intermetallic layer.

32. The semiconductor structure according to claim 24, wherein the film comprising a halide perovskite further comprises a dopant.

33. The semiconductor structure according to claim 24, further comprising:
a lattice matched layer disposed on the film comprising a halide perovskite,
wherein the film comprising a halide perovskite is located between the substrate and the lattice matched layer to define a heterojunction or a quantum well.

34. The semiconductor structure according to claim 24, wherein the semiconductor structure comprises a plurality of quantum wells.

35. A device comprising the semiconductor structure according to claim 24, wherein the device is a diode, a circuit, a sensor, a rectifier, a photocoupler, a photocatalyst, a catalyst, a photovoltaic cell, a photodetector, a photoconductor, a light emitting diode (LED), a laser, a memory, or a transistor.
